(19) United States
(12) Patent Application Publication
(10) Pub. No.: US 2006/0234508 A1
(43) Pub. Date: Oct. 19, 2006

(54) Substrate processing apparatus and substrate processing method

(76) Inventors: Mitsuhiko Shirakashi, Tokyo (JP); Hozumi Yasuda, Tokyo (JP); Masayuki Kumekawa, Tokyo (JP); Itsuki Kobata, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/513,399

(22) PCT Filed: May 16, 2003
(86) PCT No.: PCT/JP03/06130

§ 371 Date: Feb. 9, 2006

(30) Foreign Application Priority Data
May 17, 2002 (JP) 2002-143725
Jun. 11, 2002 (JP) 2002-170588
Dec. 27, 2002 (JP) 2002-382128

(51) Int. Cl. H01L 21/302; H01L 21/461

(52) U.S. Cl. 438/691; 438/692

(57) ABSTRACT

There is provided a substrate processing apparatus which can process a substrate by using an electrolytic processing method, while reducing a load upon a CMP processing to the least possible extent. The substrate processing apparatus of the present invention includes: an electrolytic processing unit (36) for electrolytically removing the surface of the substrate W having a to-be-processed film formed in said surface, said unit including a feeding section (373) that comes into contact with said surface of the substrate W; a bevel-etching unit (48) for etching away the to-be-processed film remaining unprocessed at the portion of the substrate that has been in contact with the feeding section (373) in the electrolytic processing unit (36); a chemical mechanical polishing unit (34) for chemically and mechanically polishing the surface of the substrate.

### TECHNICAL FIELD

The present invention relates to a substrate processing apparatus and a substrate processing method, and more particularly to a substrate processing apparatus and a substrate processing method useful for processing a conductive material formed in the surface of a substrate, especially a semiconductor wafer.

The present invention also relates to a substrate processing apparatus and a substrate processing method which are useful for forming an embedded interconnect structure by embedding a metal, such as copper or silver, into fine trenches for interconnects provided in the surface of a substrate, such as a semiconductor wafer. Further, the present invention relates to a substrate processing method which comprises forming a protective film on the surface of the thus-formed embedded interconnects to protect the interconnects, and to a semiconductor device processed by the method.

### BACKGROUND ART

In recent years, instead of using aluminum or aluminum alloys as a material for forming interconnection circuits on a substrate such as a semiconductor wafer, there is an eminent movement towards using copper (Cu) which has a low electric resistivity and high electromigration endurance. Copper interconnects are generally formed by filling copper into fine trenches formed in the surface of a substrate. There are known various techniques for forming such copper interconnects, including CVD, sputtering, and plating. According to any such technique, a copper film is formed in the substantially entire surface of a substrate, followed by removal of unnecessary copper by chemical mechanical polishing (CMP).

In the case of interconnects formed by such a process, the embedded interconnects have an exposed surface after the flattening processing. When an additional embedded interconnect structure is formed on such an interconnects-exposed surface of a semiconductor substrate, the following problems may be encountered. For example, during the formation of a new SiO₂ insulating interlayer in the next process for forming an interlevel dielectric film, the exposed surface of the pre-formed interconnects is likely to be oxidized. Further, upon etching of the SiO₂ layer for formation of via holes, the pre-formed interconnects exposed on the bottoms of the via holes can be contaminated with an etchant, a peeled resist, etc.

In order to avoid such problems, it has conventionally been conducted to form a protective film of silicon nitride or the like not only on the circuit-formed region of a semiconductor substrate where the surfaces of the interconnects are exposed, but on the whole surface of the substrate, thereby preventing the contamination of the exposed interconnects with an etchant, etc.

However, the provision of a protective film of SiN or the like on the whole surface of a semiconductor substrate, in a semiconductor device having an embedded interconnect structure, increases the dielectric constant of the interlevel dielectric film, thus increasing interconnection delay even when a low-resistivity material such as copper or silver is employed for interconnects, whereby the performance of the semiconductor device may be impaired.

In view of this, it has been proposed to cover the surface of the exposed interconnects selectively with a protective film of Co (Cobalt), a Co alloy, Ni (Nickel) or a Ni alloy, having a good adhesion to an interconnect material such as copper or silver and having a low resistivity (ρ), for example, an alloy film which is obtained by electroless plating.

FIGS. 1A through 1F illustrate, in sequence of process steps, an example of forming such a semiconductor device having copper interconnects. As shown in FIG. 1A, an insulating film 2a, such as an oxide film of SiO₂ or a film of low-k material, is deposited on a conductive layer 1a in which semiconductor devices are formed, which is formed on a semiconductor base 1. Contact holes 3 and interconnect trenches 4 are formed in the insulating film 2a by the lithography/etching technique. Thereafter, a barrier layer 5 of TaN or the like is formed on the entire surface, and a seed layer 6 as an electric supply layer for electroplating is formed on the barrier layer 5 by sputtering or the like.

Then, as shown in FIG. 1B, copper plating is performed onto the surface of the substrate W to fill the contact holes 3 and the interconnect trenches 4 with copper and, at the same time, deposit a copper film 7 on the insulating film 2a. Thereafter, the barrier layer 5, the seed layer 6 and the copper film 7 on the insulating film 2a are removed by chemical mechanical polishing (CMP) so as to make the surface of the copper film 7 filled in the contact holes 3 and the interconnect trenches 4, and the surface of the insulating film 2a lie substantially on the same plane. Interconnects (copper interconnects) 8 composed of the seed layer 6 and the copper film 7 as shown in FIG. 1C is thus formed.

Then, as shown in FIG. 1D, electroless plating is performed onto the surface of the substrate to form a protective layer 9 of e.g. a Co alloy or a Ni alloy on the surface of interconnects 8 selectively, thereby covering and protecting the exposed surface of interconnects 8 with the protective film 9. Thereafter, an insulating film 2b, such as SiO₂ or SiOF, is superimposed on the surface of the substrate W, as shown in FIG. 1E. Then, the surface of the insulating film 2b is flattened to form a multi-layer interconnect structure, as shown in FIG. 1F.

Components in various types of equipments have recently become finer and have required higher accuracy. As sub-micro manufacturing technology has commonly been used, the properties of materials are largely influenced by the processing method. Under these circumstances, in such a conventional machining method that a desired portion in a workpiece is physically destroyed and removed from the surface thereof by a tool, a large number of defects may be produced to deteriorate the properties of the workpiece. Therefore, it becomes important to perform processing without deteriorating the properties of the materials.

Some processing methods, such as chemical polishing, electrolytic processing, and electrolytic polishing, have been developed in order to solve this problem. In contrast with the conventional physical processing, these methods perform removal processing or the like through chemical dissolution reaction. Therefore, these methods do not suffer from defects, such as formation of an altered layer and dislocation, due to plastic deformation, so that processing can be performed without deteriorating the properties of the materials.

Chemical mechanical polishing (CMP), for example, generally necessitates a complicated operation and control, and needs a considerably long processing time. In addition, a sufficient cleaning of a substrate must be conducted after the polishing treatment. This also imposes a considerable load on the slurry or cleaning liquid waste disposal. Accordingly, there is a strong demand for omitting CMP entirely or reducing a load upon CMP. Also in this connection, it is to be pointed out that though a low-k material, which has a low dielectric constant, is expected to be predominantly used in the future as a material for the insulating film, the low-k material has a low mechanical strength and therefore is hard to endure the stress applied during CMP processing. Thus, also from this standpoint, there is a demand for a process that enables the flattering of a substrate without giving any stress thereto.

Further, a method has been reported which performs CMP processing simultaneously with plating, viz. chemical mechanical electrolytic polishing. According to this method, the mechanical processing is carried out to the growing surface of a plating film, causing the problem of denaturing of the resulting film.

On the other hand, when the protective film 9 is selectively formed on the surface of the interconnects 8, which have been formed by removing the extra metal deposited on the surface of the substrate W to flatten the surface by chemical mechanical polishing (CMP) or the like, as described above, the protective film 9 protrudes from the flattened surface. Upon the later deposition of the insulating film 2b, irregularities that follow the protective film 9 are formed in the surface of the insulating film 2b, which worsens the surface flatness. This can cause, for example, out-of-focus in a photolithography process for the formation of interconnects in the upper layer, and can therefore cause disconnection or short circuit of the interconnects, adversely affecting the performance of LSI, etc. fabricated in the surface of the substrate, such as a semiconductor wafer. An additional flattening process is therefore needed to secure a sufficient flatness of the surface of the insulating film 2b.

By the way, as shown in FIG. 2, when the copper film 7 is formed by plating onto the surface of the substrate W in which fine holes 3a with a diameter d₁, e.g., of the order of 0.2 μm, and broad trenches 4b with a interconnect width d₂, e.g., of the order of 100 μm are present, the growth of plating is likely to be promoted at the portion above the fine holes 3a whereby the copper film 7 is raised at that portion, even when the effect of a plating solution or an additive contained in the plating solution is optimized, whereas the growth of plating with an adequately high leveling property cannot be made within the broad trenches 4b. This results in a difference (hump) “a+b” in the level of the copper film 7 deposited on the substrate W, i.e. the height “a” of the raised portion above the fine holes 3a plus the depth “b” of the depressed portion above the broad trenches 4b. Thus, in order to obtain the desired flat surface of substrate W with the fine holes 3a and the broad trenches 4b being fully filled with copper, it is necessary to provide the copper film 7 having a sufficiently large thickness beforehand, and remove by CMP the extra portion corresponding to the above difference “a+b” in the level.

In the CMP processing of a plated film, however, the larger thickness of the plated film requires a larger polishing amount, leading to a prolonged processing time. An increase in the CMP rate to avoid the processing prolongation can cause the increase of dishing in the broad trenches during the CMP processing. Further, since CMP uses the slurry for polishing, cross-contamination between the slurry and a plating solution may become a problem. Moreover, since a polishing pad having elasticity is contacted with a substrate in CMP processing, it is not possible to selectively remove the raised portions of the substrate.

In order to solve these problems, it is necessary to make the thickness of a plated film as thin as possible, and eliminate the raised portions and recesses even when fine holes and broad trenches are co-present in the surface of a substrate to thereby enhance the flatness. At present, however, when carrying out electrolytic plating using e.g. a copper sulfate plating bath, it is not possible to concurrently attain a decrease in the raised portions and a decrease in the recesses solely by the action of the plating solution or an additive. It is possible to reduce the raised portions by using a temporary reverse power source or a PR pulse power source as a plating power source during film deposition. This method, however, is not effective in decreasing the recesses and, in addition, deteriorates the quality of a surface of the film.

### DISCLOSURE OF INVENTION

The present invention has been made in view of the above problems in the prior art. It is therefore a first object of the present invention to provide a substrate processing apparatus and a substrate processing method which process a substrate by using an electrolytic processing method which, while reducing a load upon a CMP processing to the least possible extent, can process a conductive material provided in the surface of a substrate into a flat surface and remove (clean) extraneous matter adhering to the surface of the substrate.

It is a second object of the present invention to provide a substrate processing method which can selectively form a protective film on the surface of interconnects to protect the interconnects, and can secure a sufficient flatness of an insulating film, etc. deposited on the surface of the substrate in which the protective film is formed, thereby eliminating the need for an additional process of flattening the surface of the insulating film, etc., and provide a semiconductor device processed by the processing method.

It is a further object of the present invention to provide a substrate processing apparatus and a substrate processing method which can provide a processed substrate with a good surface flatness even when fine holes, broad trenches, etc., as recesses for interconnects, are co-present in the surface of the substrate.

In order to achieve the above object, the present invention provides a substrate processing apparatus, comprising: a loading/unloading section for carrying in and carrying out a substrate; an electrolytic processing unit for electrolytically removing a surface of the substrate having a to-be-processed film formed therein, said electrolytic processing unit including a feeding section that comes into contact with the surface of the substrate; an etching unit for etching away the to-be-processed film remaining unprocessed at the portion of the substrate that has been in contact with the feeding section in the electrolytic processing unit; a chemical mechanical polishing unit for chemically and mechanically polishing the surface of the substrate from which the to-be-processed film has been etched away; and a transfer device for transferring the substrate within the substrate processing apparatus.

FIGS. 3 and 4 illustrate the principle of the electrolytic processing according to the present invention. FIG. 3 shows the ionic state when an ion exchanger 12a mounted on a processing electrode 14 and an ion exchanger 12b mounted on a feeding electrode 16 are brought into contact with or close to a surface of a workpiece 10, while a voltage is applied via a power source 17 between the processing electrode 14 and the feeding electrode 16, and a liquid 18, e.g. ultrapure water, is supplied from a liquid supply section 19 between the processing electrode 14, the feeding electrode 16 and the workpiece 10. FIG. 4 shows the ionic state when the ion exchanger 12a mounted on the processing electrode 14 is brought into contact with or close to the surface of the workpiece 10 and the feeding electrode 16 is directly contacted with the workpiece 10, while a voltage is applied via the power source 17 between the processing electrode 14 and the feeding electrode 16, and the liquid 18, such as ultrapure water, is supplied from the liquid supply section 19 between the processing electrode 14 and the workpiece 10.

When a liquid like ultrapure water that in itself has a large resistivity is used, it is preferred to bring the ion exchanger 12a into contact with the surface of the workpiece 10. This can lower the electric resistance, lower the requisite voltage and reduce the power consumption. The “contact” in the present electrolytic processing does not imply “press” for giving a physical energy (stress) to a workpiece as in CMP.

Water molecules 20 in the liquid 18 such as ultrapure water are dissociated efficiently by using the ion exchangers 12a, 12b into hydroxide ions 22 and hydrogen ions 24. The hydroxide ions 22 thus produced, for example, are carried, by the electric field between the workpiece 10 and the processing electrode 14 and by the flow of the liquid 18, to the surface of the workpiece 10 opposite to the processing electrode 14 whereby the density of the hydroxide ions 22 in the vicinity of the workpiece 10 is enhanced, and the hydroxide ions 22 are reacted with the atoms 10a of the workpiece 10. The reaction product 26 produced by this reaction is dissolved in the liquid 18, and removed from the workpiece 10 by the flow of the liquid 18 along the surface of the workpiece 10. Removal processing of the surface of the workpiece 10 is thus effected.

As will be appreciated from the above, the removal processing according to this processing method is effected purely by the electrochemical interaction between the reactant ions and the workpiece. This electrolytic processing thus clearly differs in the processing principle from CMP according to which processing is effected by the combination of the physical interaction between an abrasive and a workpiece, and the chemical interaction between a chemical species in a polishing liquid and the workpiece. According to the above-described method, the portion of the workpiece 10 facing the processing electrode 14 is processed. Therefore, by moving the processing electrode 14, the workpiece 10 can be processed into a desired surface configuration.

As described above, the removal processing of the electrolytic processing is effected solely by the dissolution reaction due to the electrochemical interaction, and is clearly distinct in the processing principle from CMP in which processing is effected by the combination of the physical interaction between an abrasive and a workpiece, and the chemical interaction between a chemical species in a polishing liquid and the workpiece. Accordingly, the electrolytic processing can conduct removal processing of the surface of a workpiece without impairing the properties of the material of the workpiece. Even when the material of a workpiece is of a low mechanical strength, such as the above-described low-k material, removal processing of the surface of the workpiece can be effected without any physical damage to the workpiece. Further, compared to the conventional electrolytic processing which use electrolytic solution as a processing liquid, by using a liquid having an electric conductivity of not more than 500 μS/cm, preferably pure water, more preferably ultrapure water, as a processing liquid, it is possible to reduce remarkably contamination of the surface of a workpiece, and dispose easily of waste liquid after the processing.

In the case where the feeding electrode 16 is directly contacted with the workpiece 10 (see FIG. 4), it is not possible physically to bring the processing electrode 14 into close to the portion of the workpiece in contact with the feeding electrode 16. Accordingly, that portion of the workpiece 10 cannot be processed. In view of this, it may be considered to dispose the processing electrode 14 and the feeding electrode 16 opposite to the workpiece 10 (see FIG. 3), and allow the feeding electrode 16 and the workpiece 10 to make a relative movement so that the workpiece 10 can be processed over the entire surface. In this case, however, the feeding electrode 16 must always be in contact with the surface of the workpiece 10, which necessitates a complicated construction of an apparatus. According to the substrate processing apparatus of the present invention, with the provision of the etching unit for etching away a to-be-processed film remaining unprocessed on the surface of a substrate, a to-be-processed film (on the workpiece 10) remaining unprocessed can be etched away even in the case of contacting the feeding electrode 16 directly with the workpiece 10. The freedom of the manner of feeding electricity to the workpiece 10 can therefore be increased. It is preferred that the feeding electrode 16 contact an area of the workpiece 10 other than the device-formed area, for example, the peripheral area of the workpiece 10.

In a preferred embodiment of the present invention, the electrolytic processing unit comprises: a processing electrode that can come close to or into contact with the substrate; a feeding electrode as the feeding section for feeding electricity to the substrate; an ion exchanger disposed between the substrate and at least one of the processing electrode and the feeding electrode; a power source for applying a voltage between the processing electrode and the feeding electrode; and a fluid supply section for supplying a fluid between the substrate and at least one of the processing electrode and the feeding electrode in which the ion exchanger is disposed.

The substrate processing apparatus may further comprise a film-forming unit for forming the to-be-processed film on the surface of the substrate. The film-forming unit, for example, is a plating unit for plating the surface of the substrate.

The substrate processing apparatus may further comprise an annealing unit for annealing the substrate after the processing in the film-forming unit, and a cleaning unit for cleaning the substrate.

The present invention provides another substrate processing apparatus, comprising: a loading/unloading section for carrying in and carrying out a substrate; an electrolytic processing unit for electrolytically removing a surface of the substrate having a to-be-processed film formed therein, said electrolytic processing unit including a feeding section that comes into contact with the surface of the substrate; an etching unit for etching away the to-be-processed film remaining unprocessed at the portion of the substrate that has been in contact with the feeding section in the electrolytic processing unit; and a transfer device for transferring the substrate within the substrate processing apparatus, wherein the electrolytic processing unit comprises: (i) a processing electrode that can come close to or into contact with the substrate; (ii) a feeding electrode as the feeding section for feeding electricity to the substrate; (iii) an ion exchanger disposed between the substrate and at least one of the processing electrode and the feeding electrode; (iv) a power source for applying a voltage between the processing electrode and the feeding electrode; and (v) a fluid supply section for supplying pure water or a liquid having an electric conductivity of not more than 500 μS/cm between the substrate and at least one of the processing electrode and the feeding electrode in which the ion exchanger is disposed.

The substrate processing apparatus may further comprise a chemical mechanical polishing unit for chemically and mechanically polishing the surface of the substrate from which the to-be-processed film has been etched away.

The present invention provides a substrate processing method, comprising: electrolytically processing a surface of a substrate having a to-be-processed film formed therein while allowing a feeding member to be in contact with the surface of the substrate; etching away the to-be-processed film remaining unprocessed at the portion of the substrate that has been in contact with the feeding member; and chemically and mechanically polishing the surface of the substrate after the etching.

In a preferred embodiment of the present invention, the electrolytic processing comprises: allowing a processing electrode to be close to or in contact with the substrate while feeding electricity to the substrate by a feeding electrode as the feeding member; disposing an ion exchanger between the substrate and at least one of the processing electrode and the feeding electrode; supplying a fluid between the substrate and at least one of the processing electrode and the feeding electrode in which the ion exchanger is disposed; and applying a voltage between the processing electrode and the feeding electrode.

The to-be-processed film may be formed an the surface of the substrate prior to the electrolytic processing.

The present invention provides another substrate processing method, comprising: electrolytically processing a surface of a substrate having a to-be-processed film formed therein; and etching away the to-be-processed film remaining unprocessed at the portion of the substrate that has been in contact with the feeding member, wherein the electrolytic processing comprises: allowing a processing electrode to be close to or in contact with the substrate while feeding electricity to the substrate by a feeding electrode as a feeding member; disposing an ion exchanger between the substrate and at least one of the processing electrode and the feeding electrode; supplying pure water or a liquid having an electric conductivity of not more than 500 μS/cm between the substrate and at least one of the processing electrode and the feeding electrode in which the ion exchanger is disposed; and applying a voltage between the processing electrode and the feeding electrode.

The surface of the substrate after the etching may be chemically and mechanically polished. The to-be-processed film may be formed on the surface of the substrate prior to the electrolytic processing.

The invention provides another substrate processing method, comprising: embedding an interconnect material into fine trenches for interconnects formed in a surface of a substrate; removing an unnecessary interconnect material and flattening the surface of the substrate; further removing the interconnect material to thereby form recesses for filling in an upper portion of said fine trenches; and forming a protective film selectively in the recesses for filling.

According to this method, when the protective film is formed selectively in the trenches for filling to protect the surface of the interconnects, the surface of the protective film can be made flush with the surface of a non-interconnect area, e.g. an insulating film. This can prevent protrusion of the protective film from the flattened surface, thereby securing a sufficient surface flatness of an insulating film, etc. that is later deposited on the substrate surface.

The protective film is preferably a multi-layer laminated film. The laminated film may be comprised of layers having different physical properties, i.e., performing different functions. For example, a combination of an oxidation preventing layer that prevents oxidation of interconnects and a thermal diffusion preventing layer that prevents thermal diffusion of interconnects may be employed. The use of such a laminated layer as the protective film can effectively prevent both of the oxidation and the thermal diffusion of interconnects. In this case, the thermal diffusion preventing layer may be composed of Co or a Co alloy having excellent heat resistance and the oxidation preventing layer may be composed of Ni or a Ni alloy having excellent oxidation resistance. Further, it is preferred that the oxidation preventing layer be superimposed on the surface of the thermal diffusion preventing layer. By thus covering the surface of the thermal diffusion preventing layer with the oxidation preventing layer, oxidation of the interconnects, for example, upon deposition of an insulating film (oxide film) in an oxidizing atmosphere for the formation of a semiconductor device having a multi-layer interconnect structure, can be prevented without lowing of the oxidation preventing effect.

The protective film may be formed by electroless plating. The removal of the interconnect material may be carried out by chemical mechanical polishing, chemical etching or electrolytic processing.

In a preferred embodiment of the present invention, the electrolytic processing comprises: allowing a processing electrode to be close to or in contact with the substrate while feeding electricity to the substrate by a feeding electrode; disposing an ion exchanger between the substrate and at least one of the processing electrode and the feeding electrode; supplying a fluid between the substrate and at least one of the processing electrode and the feeding electrode in which the ion exchanger is disposed; and applying a voltage between the processing electrode and the feeding electrode.

Water molecules in the liquid such as ultrapure water are dissociated efficiently by using the ion exchanger into hydroxide ions and hydrogen ions. The hydroxide ions thus produced, for example, are carried, by the electric field between the substrate and the processing electrode and by the flow of the liquid, to the surface of the substrate opposite to the processing electrode whereby the density of the hydroxide ions in the vicinity of the substrate is enhanced, and the hydroxide ions are reacted with the atoms of the substrate. Removal processing of the surface of the substrate is thus effected.

The liquid is preferably pure water or a liquid having an electric conductivity of not more than 500 μS/cm.

Pure water herein refers to a water having an electric conductivity of not more than 10 μS/cm. The electric conductivity value herein refers to the corresponding value at 1 atm, 25° C. The use of pure water in electrolytic processing enables a clean processing without leaving impurities on the processed surface of a workpiece, whereby a cleaning step after the electrolytic processing can be simplified. Specifically, one or two-stages of cleaning may suffice after the electrolytic processing.

Further, it is also possible to use, instead of pure water or ultrapure water, a liquid obtained by adding a surfactant or the like to pure water or ultrapure water, for example, and having an electric conductivity of not more than 500 μS/cm, preferably not more than 50 μS/cm, more preferably not more than 0.1 μS/cm. Due to the presence of a surfactant in pure water or ultrapure water, the liquid can form a layer, which functions to inhibit ion migration evenly, at the interface between the substrate W and the ion exchanger, thereby moderating concentration of ion exchange (metal dissolution) to enhance the flatness of the processed surface.

In a preferred embodiment of the present invention, the electrolytic processing comprises: allowing a processing electrode to be close to or in contact with the substrate while feeding electricity to the substrate by means of a feeding electrode; supplying pure water or a liquid having an electric conductivity of not more than 500 μS/cm between the substrate and the processing electrode; and applying a voltage between the processing electrode and the feeding electrode.

The hydroxide ions are carried, by the electric field between the substrate and the processing electrode and by the flow of the liquid, to the surface of the substrate opposite to the processing electrode whereby the density of the hydroxide ions in the vicinity of the substrate is enhanced, and the hydroxide ions are reacted with the atoms of the substrate. The reaction product produced by this reaction is dissolved in the liquid, and removed from the substrate by the flow of the liquid along the surface of the substrate. Removal processing of the interconnect material is thus effected.

The present invention provides a semiconductor device comprising a substrate having fine trenches for interconnects formed in the surface, said fine trenches being filled with an interconnect material and with a protective film formed on the surface of the interconnect material.

The protective film is preferably a multi-layer laminated film.

The present invention provides still another substrate processing apparatus, comprising: a head section for holding a substrate; a plating section for electroplating the surface of the substrate to form a plated metal film; a cleaning section for cleaning the substrate after the plating; and an electrolytic processing section for carrying out electrolytic removal processing of at least said metal film on the substrate by allowing an ion exchanger to be present between the substrate after the cleaning and an electrode, and applying a voltage between the substrate and the electrode in the presence of a liquid; wherein the head section is capable of moving between the plating section, the cleaning section and the electrolytic section while holding the substrate.

According to the substrate processing apparatus, the plating, the cleaning and the electrolytic processing can be carried out sequentially. It is possible to carry out these processes repeatedly. By carrying out the plating process and the electrolytic processing process at different places, the processing time and other processing conditions of the respective processes can be predetermined desirably, making it possible to optimize the respective processes. Further, by providing the plating section and the electrolytic processing section separately, different liquids can be employed in the two sections without cross-contamination.

Preferably, the cleaning section is disposed between the plating section and the electrolytic processing section. This can prevent a liquid having a relatively high electric conductivity such as an aqueous solution of copper sulfate, which is used in the plating section, from being brought to the electrolytic processing section.

The cleaning section may be provided with a cleaning liquid jet nozzle, and also with a drying mechanism for drying the substrate after cleaning. The provision of the drying mechanism enables the substrate after plating or electrolytic processing to be returned to a cassette when the substrate is in a dried state.

In a preferred embodiment of the present invention, the electrolytic processing section performs electrolytic processing by supplying pure water, ultrapure water, or a liquid having an electric conductivity of not more than 500 μS/cm to between the substrate after plating and the electrode.

Further, it is possible to carry out the plating in the plating section and the electrolytic processing in the electrolytic processing section repeatedly at least two times.

In a preferred embodiment of the present invention, the plating section comprises an anode, an ion exchanger disposed between the anode and the substrate, and a plating solution supply section for supplying a plating solution between the ion exchanger and the substrate. By thus disposing the ion exchanger between the anode of the plating section and the substrate, the plating solution from the plating solution supply section can be prevented from directly hitting on the surface of the anode, thereby preventing a black film formed on the surface of the anode from being curled up by the plating solution and flowing out. It is desirable that the ion exchanger have water permeability. For example, a woven or nonwoven fabric made of ion exchange fibers, or a porous film can permit a liquid to permeate therethrough.

In a preferred embodiment of the present invention, the head section includes an openable/closable feeding contact member for holding a peripheral portion of the substrate held on the lower surface of the head section and feeding electricity to the substrate. Preferably, the feeding contact member is comprised of a plurality of members disposed at regular intervals along the circumferential direction of the head section, so that feeding of electricity to the substrate can be effected while holding the substrate stably in the head section.

It is preferred that the feeding contact member be provided with a feeding member composed of a metal which is noble to the metal film on the substrate. By the use of such a feeding member, a decrease in the conductivity due to its oxidation can be prevented.

It is preferred that the electrolytic processing section be provided with a sensor for detecting the thickness of the metal film in the surface of the substrate. This makes it possible to monitor the progress of electrolytic processing.

The plating section and the electrolytic plating section may each have a power source.

In a preferred embodiment of the present invention, the head section, the plating section, the cleaning section and the electrolytic processing section are installed in a processing unit. The processing unit is preferably provided with an inert gas supply section for supplying an inert gas into the processing unit. The supply of an inert gas is preferably carried out by enclosure of an inert gas, such as nitrogen gas, in the processing unit. The expression “enclosure of an inert gas” herein refers to filling of the processing unit with a clean gas with decreased particles. In particular, by making the internal pressure of the processing unit slightly higher than the external pressure, particles can be prevented from flowing from the outside into the processing unit, leading to a decrease of particles that adhere to the substrate surface. Further, the enclosure of inert gas can prevent an increase in the dissolved oxygen concentration of pure water during electrolytic processing. This will stabilize the quality of pure water and suppress generation of gas bubbles from pure water during electrolytic processing, thereby stabilizing the performance of electrolytic processing.

In a preferred embodiment of the present invention, the electrolytic processing section and the plating section are connected to a mutual power source, and the power source is switchably connected to the electrolytic processing section or to the plating section by means of a power source selector switch.

The present invention provides still another substrate processing method, comprising; plating a surface of a substrate; cleaning the substrate after the plating; and carrying out electrolytic removal processing by allowing an ion exchanger to be present between the substrate after the cleaning and an electrode, and supplying a liquid having an electric conductivity of not more than 500 μS/cm between the substrate and the electrode; wherein the plating, the cleaning and the electrolytic processing are carried out repeatedly at least two times.

By thus carrying out electrolytic processing, after the plating of the substrate, by supplying a liquid having an electric conductivity of not more than 500 μS/cm between the plated substrate and the electrode, the raised portions of the substrate formed in the plating can be effectively removed, whereby the flatness of the surface of the substrate can be improved. Thus, the liquid having an electric conductivity of not more than 500 μS/cm is not fully dissociated electrolytically and, due to a difference in the electric resistance, the ion current concentrates at the raised portions of the substrate which are close to or in contact with the ion exchanger, and the ions act on the metal film (humps) on the substrate. Accordingly, the raised portions closed to or in contact with the ion exchange can be removed effectively, whereby the flatness of the substrate can be improved. Especially when the liquid is pure water, which has an electric conductivity of not more than 10 μS/cm, or ultrapure water, which has an electric conductivity of not more than 0.1 μS/cm, good electrolytic processing can be effected with enhanced raised portion removing effect.

Further, by cleaning the substrate after plating, a plating solution, which is a highly conductive liquid, can be completely removed and replaced with pure water, making it possible to carry out the electrolytic processing (electrolytic polishing) in an atmosphere of pure water, ultrapure water, or the like, which has a low electric conductivity. Especially, by using pure water or ultrapure water in the electrolytic processing, mainly the raised portions in the substrate surface can be removed with a high selectivity. Further, by carrying out plating again to the substrate after electrolytic processing, an excessive formation of raised portions upon plating can be prevented, and a plated metal film having a good surface flatness can be obtained even when fine holes and large holes (broad trenches) are co-present in the substrate surface.

The present invention provides still another substrate processing apparatus, comprising: a head section for holding a substrate; a plating section for electroplating the surface of the substrate to form a plated metal film; a cleaning section for cleaning the substrate after the plating; and an electrolytic processing section, which has a processing electrode, for carrying out electrolytic removal processing of at least said metal film on the substrate by applying a voltage between the substrate after the cleaning and the processing electrode in the presence of a liquid; wherein the head section is capable of moving between the plating section, the cleaning section and the electrolytic section while holding the substrate.

In a preferred embodiment of the present invention, the electrolytic processing section carries out the electrolytic processing by supplying an acid solution between the substrate after the plating and the processing electrode. As the processing liquid, an acid solution of about 0.01 to about 0.1 wt. %, for example, such as dilute sulfate acid solution or dilute phosphoric acid solution may be used.

The present invention provides still another substrate processing method, comprising: plating a surface of a substrate; cleaning the surface of the substrate after the plating; and electrolytically processing the surface of the substrate after the cleaning by applying a voltage between the substrate and a processing electrode in the presence of a liquid; wherein the plating, the cleaning and the electrolytic processing are carried out repeatedly at lease two times.

An ion exchanger is preferably allowed to be present between the substrate and the processing electrode. The liquid is preferably pure water, ultrapure water or a liquid having an electric conductivity of not more than 500 μS/cm or an electrolyte solution.

### BRIEF DESCRIPTION OF DRAWINGS

FIGS. 1A through 1F are diagrams illustrating, in sequence of process steps, an example of the formation of copper interconnects;

FIG. 2 is a diagram illustrating the formation of a difference in level upon plating of a semiconductor substrate;

FIG. 3 is a diagram illustrating the principle of electrolytic processing according to the present invention as carried out by allowing a processing electrode and a feeding electrode to be closed to a substrate (workpiece), and supplying pure water or a liquid having an electric conductivity of not more than 500 μS/cm between the processing electrode, the feeding electrode and the substrate (workpiece);

FIG. 4 is a diagram illustrating the principle of electrolytic processing according to the present invention as carried out by mounting an ion exchanger only on the processing electrode and supplying the liquid between the processing electrode and the substrate (workpiece);

FIG. 5 is a plan view schematically showing the construction of a substrate processing apparatus according to an embodiment of the present invention;

FIG. 6 is a vertical sectional view schematically showing the plating unit shown in FIG. 5;

FIG. 7 is a vertical sectional view schematically showing the annealing unit shown in FIG. 5;

FIG. 8 is a horizontal sectional view schematically showing the annealing unit shown in FIG. 5;

FIG. 9 is a schematic view showing the construction of the electrolytic processing unit shown in FIG. 5;

FIG. 10 is a plan view of the electrolytic processing unit shown in FIG. 9;

FIG. 11 is a diagram illustrating the principle of regeneration of a cation exchanger as carried out in the regeneration section shown in FIG. 10;

FIG. 12 is a vertical sectional view schematically showing the bevel-etching unit shown in FIG. 5;

FIG. 13 is a vertical sectional view schematically showing the CMP unit shown in FIG. 5;

FIG. 14A is a graph showing the relationship between electric current and time, as observed in electrolytic processing of the surface of a substrate having a film of two different materials formed in the surface;

FIG. 14B is a graph showing the relationship between voltage and time, as observed in electrolytic processing of the surface of a substrate having a film of two different materials formed in the surface;

FIGS. 15A through 15F are diagrams illustrating, in sequence of process steps, an example of the formation of copper interconnects by a substrate processing method according to an embodiment of the present invention;

FIG. 16 is a plan view schematically showing a substrate processing apparatus that carries out the substrate processing method illustrated in FIGS. 15A through 15F;

FIG. 17 is a cross-sectional view schematically showing the electroless plating unit of FIG. 16;

FIG. 18 is a cross-sectional view schematically showing another electroless plating unit;

FIG. 19 is a vertical sectional front view schematically showing an electrolytic processing unit which is usable in place of the CMP unit shown in FIG. 16;

FIG. 20 is a plan view of FIG. 19;

FIG. 21 is a vertical sectional front view schematically showing another electrolytic processing unit;

FIG. 22 is a plan view of FIG. 21;

FIG. 23 is a vertical sectional front view schematically showing yet another electrolytic processing unit;

FIG. 24 is a plan view of FIG. 23;

FIG. 25 is a vertical sectional front view schematically showing yet another electrolytic processing unit;

FIG. 26 is a plan view of FIG. 25;

FIG. 27 is a plan view schematically showing the construction of a substrate processing apparatus according to another embodiment of the present invention;

FIG. 28 is a plan view showing the substrate processing unit installed in the substrate processing apparatus of FIG. 27;

FIG. 29 is a vertical sectional front view of FIG. 28;

FIG. 30 is a vertical sectional side view of FIG. 28;

FIG. 31 is a vertical sectional view showing the main portion of the pivot arm and the head section of the substrate processing unit of FIG. 28;

FIG. 32 is an enlarged view of a portion of FIG. 31;

FIG. 33 is a plan view of the substrate holder of the head section;

FIG. 34 is a bottom plan view of the substrate holder of the head section;

FIG. 35 is a vertical sectional view showing the plating section of the substrate processing unit of FIG. 28;

FIG. 36 is a vertical sectional view showing the electrolytic processing section of the substrate processing unit of FIG. 28;

FIG. 37 is a plan view showing a substrate processing unit according to another embodiment of the present invention;

FIG. 38 is a vertical sectional front view of FIG. 37;

FIG. 39 is a vertical sectional view showing the main portion of the head section and the electrode section of the substrate processing unit of FIG. 37;

FIG. 40 is a plan view illustrating the relationship between the head section and the electrode section of the electrolytic processing section of FIG. 39;

FIG. 41 is a flow chart of a substrate processing process according to another substrate processing method of the present invention;

FIGS. 42A through 42F are diagrams illustrating the substrate processing process of FIG. 41, which comprises a repetition of plating and electrolytic processing;

FIG. 43 is a diagram of a variation of the substrate processing unit, schematically showing the electrolytic processing section which is provided with an ion exchanger regeneration section and in which different types of liquids are supplied to the electrolytic processing section and to the regeneration section;

FIG. 44 is a vertical sectional view showing a cleaning section provided in the substrate processing unit of FIG. 28; and

FIG. 45 is a plan view showing another variation of the substrate processing unit.

### BEST MODE FOR CARRYING OUT THE INVENTION

Preferred embodiment of the present invention will now be described in detail with reference to the drawings. In the following description, the same or corresponding members or elements are given the same reference numerals, and a redundant description will be omitted. The below-described embodiments use a semiconductor wafer as a substrate and process a semiconductor wafer by means of a substrate processing apparatus. It is however noted that the present invention is of course applicable to a substrate other than a semiconductor wafer.

FIG. 5 is a plan view schematically showing the construction of a substrate processing apparatus according to an embodiment of the present invention. As shown in FIG. 5, the substrate processing apparatus includes a pair of loading/unloading sections 30 as a carry-in-and-out section for carrying in and out a cassette housing substrates, such as semiconductor wafers, and a movable transfer robot 32 as a transfer device for transferring the substrate within the apparatus. A chemical mechanical polishing unit (CMP unit) 34 and an electrolytic processing unit 36 are disposed on the opposite side of the transfer robot 32 from the loading/unloading sections 30. Pushers 34a, 36a are disposed respectively in the CMP unit 34 and in the electrolytic processing unit 36 at locations within reach of the transfer robot 32.

On both sides of the traveling axis 32a of the transfer robot 32, there are provided four units on each side. On one side, a plating unit 38 as a film forming unit for forming a to-be-processed film on the surface of the substrate, a cleaning unit 40 for cleaning the substrate after plating, an annealing unit 42 for annealing the substrate after plating, and a reversing machine 44 for reversing the substrate, are disposed in this order from the loading/unloading sections 30 side. On the other side, a cleaning unit 46 for cleaning the substrate after CMP, a bevel-etching unit 48 for etching away the to-be-processed film formed on or adhering to the peripheral portion (bevel portion and edge portion) of the substrate, a cleaning unit 50 for cleaning the substrate after etching, and a reversing machine 52 for reversing the substrate, are disposed in this order from the loading/unloading sections 30 side. Further, a monitor section 54 for monitoring the voltage applied between the below-described processing electrode and feeding electrode or the electric current flowing therebetween during electrolytic processing carried out by the electrolytic processing unit 36 is disposed beside the loading/unloading sections 30.

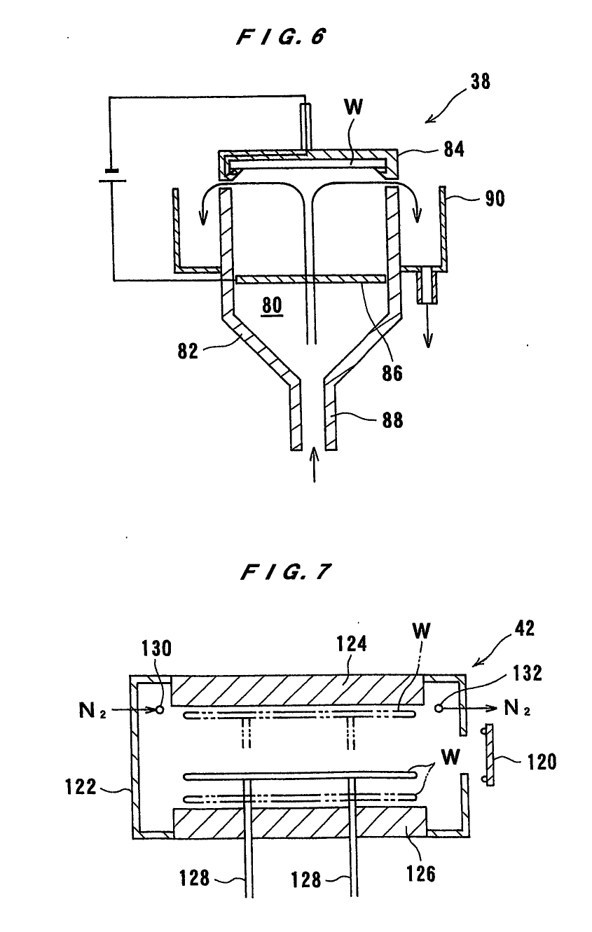

Next, a plating unit 38 in the substrate processing apparatus will be described. FIG. 6 is a vertical sectional view schematically showing an example of the plating unit 38. The plating unit 38 is adapted to form a to-be-processed film as a workpiece by plating onto a surface of the substrate. As shown in FIG. 6, the plating unit 38 includes a top-opened cylindrical plating tank 82 for containing a plating solution 80, and a substrate holder 84 for detachably holding the substrate W with its front surface facing downward in such a position that the substrate W covers the top opening of the plating tank 82. In the inside of the plating tank 82, an anode plate 86 in a flat plate shape, which becomes an anode electrode when immersed in the plating solution 80 with the substrate as a cathode, is disposed horizontally. The center portion of the bottom of the plating tank 82 communicates with a plating solution ejecting pipe 88 for forming an ejecting flow of the plating solution upwardly. Further, a plating solution receiver 90 is provided around the upper outer periphery of the plating tank 82.

In operation of the plating unit 38, the substrate W held with its front surface facing downward by the substrate holder 84 is positioned above the plating tank 82 and a given voltage is applied between the anode plate (anode) 86 and the substrate (cathode) W while the plating solution 80 is ejected upwardly from the plating solution ejecting pipe 88 so that the ejecting flow of the plating solution 80 hits against the lower surface (surface to be plated) of the substrate W, whereby a plating current is allowed to flow between the anode plate 86 and the substrate W, and a plated film is thus formed on the lower surface of the substrate W.

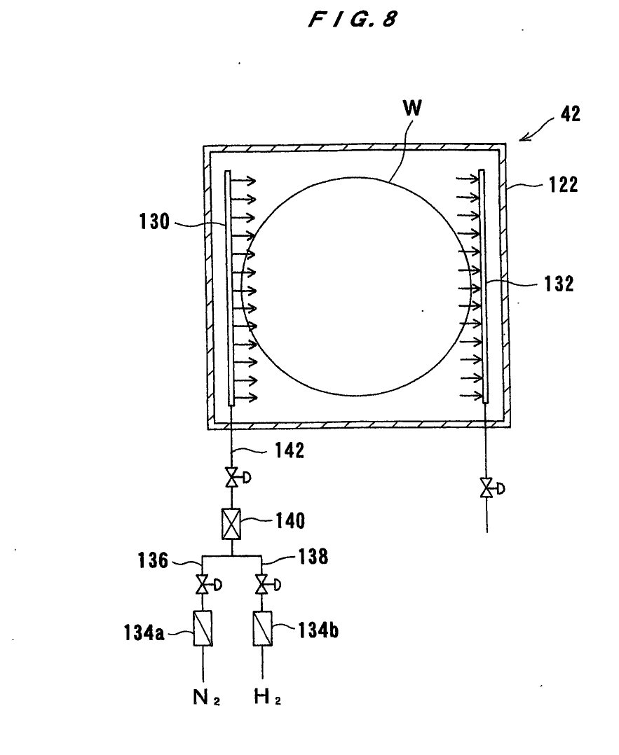

Next, an annealing unit 42 in the substrate processing apparatus will be described. FIG. 7 is a vertical sectional view schematically showing the annealing unit 42, and FIG. 8 is a horizontal sectional view schematically showing the annealing unit 42. As shown in FIGS. 7 and 8, the annealing unit 42 comprises a chamber 122 having a gate 120 for carrying in and carrying out the substrate W, a hot plate 124 disposed in the chamber 122 for heating the substrate W to e.g. 400° C., and a cool plate 126 disposed beneath the hot plate 124 in the chamber 122 for cooling the substrate W by, for example, flowing a cooling water inside the hot plate 124.

The annealing unit 42 also has a plurality of vertically movable elevating pins 128 penetrating the cool plate 126 and extending upward and downward therefrom for placing and holding the substrate W on the upper ends thereof. The annealing unit 42 further includes a gas introduction pipe 130 for introducing an antioxidant gas between the substrate W and the hot plate 124 during annealing, and a gas discharge pipe 132 for discharging the gas that has been introduced from the gas introduction pipe 130 and flowed between the substrate W and the hot plate 124. The pipes 130 and 132 are disposed on the opposite sides across the hot plate 124.

As shown in FIG. 8, the gas introduction pipe 130 is connected to a mixed gas introduction line 142 which in turn is connected to a mixer 140 where a N₂ gas introduced through a N₂ gas introduction line 136 containing a filter 134a, and a H₂ gas introduced through a H₂ gas introduction line 138 containing a filter 134b, are mixed to form a mixed gas which flows through the mixed gas introduction line 142 into the gas introduction pipe 130.

In operation, the substrate W, which has been formed a plated film in the surface of the substrate by plating unit 38 and carried in the chamber 122 through the gate 120, is held on the lifting pins 128 and the lifting pins 128 are raised up to a position at which the distance between the substrate W held on the lifting pins 128 and the hot plate 124 becomes e.g. 0.1-1.0 mm. The substrate W is then heated to e.g. 400° C. through the hot plate 124 and, at the same time, the antioxidant gas is introduced from the gas introduction pipe 130 and the gas is allowed to flow between the substrate W and the hot plate 124 while the gas is discharged from the gas discharge pipe 132, thereby annealing the substrate W while preventing its oxidation. The annealing treatment may be completed in about several tens of seconds to 60 seconds. The heating temperature of the substrate W may arbitrarily be selected in the range of 100-600° C.

After completion of the annealing, the lifting pins 128 are lowered down to a position at which the distance between the substrate W held on the lifting pins 128 and the cool plate 126 becomes e.g. 0-0.5 mm. By introducing a cooling water into the cool plate 126, the substrate W is cooled by the cool plate 126 to a temperature of 100° C. or lower in e.g. 10-60 seconds. The cooled substrate W is sent to the next step. Though in this embodiment a mixed gas of N₂ gas with several % of H₂ gas is used as the above antioxidant gas, N₂ gas may be used singly.

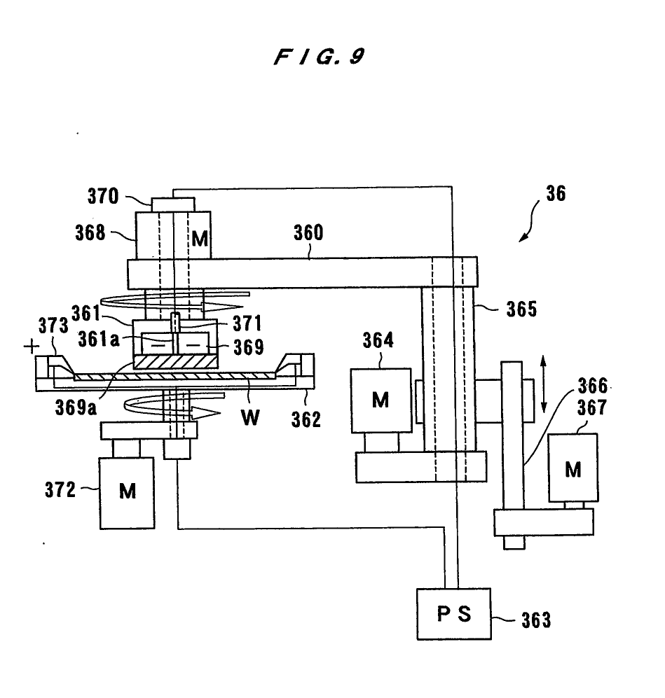

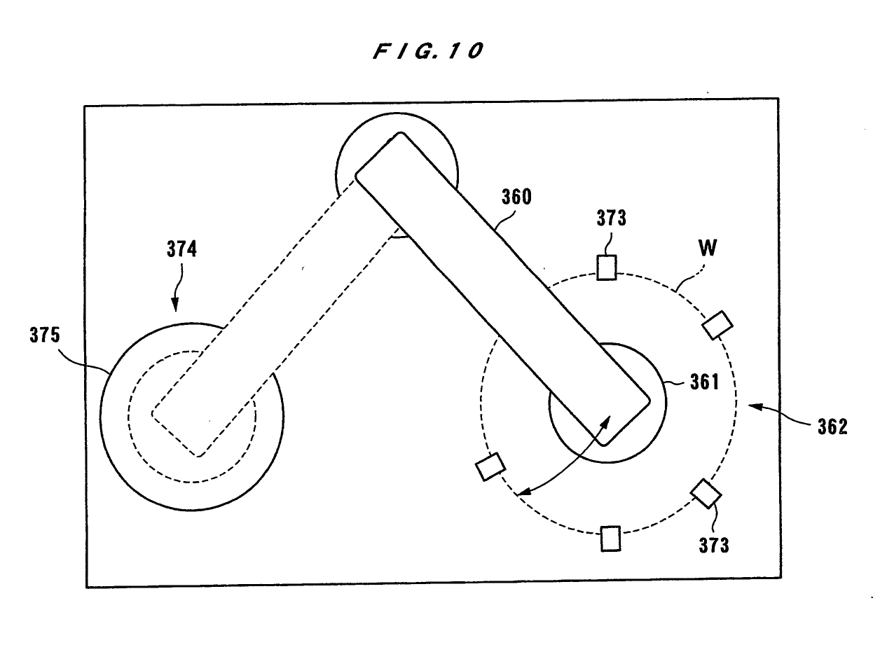

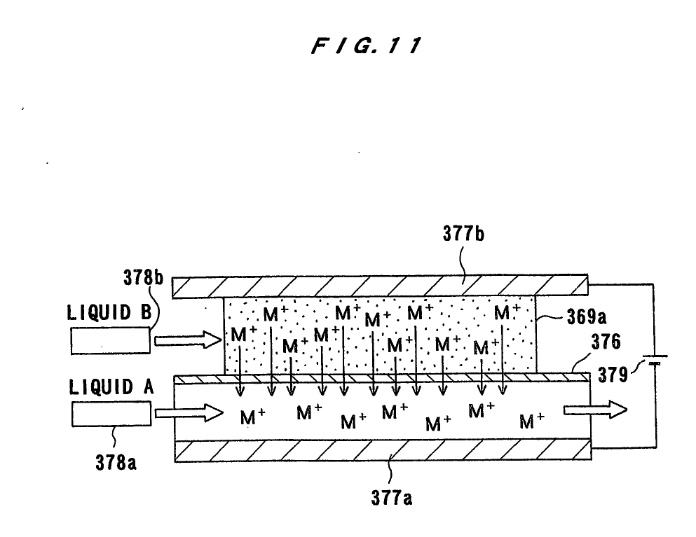

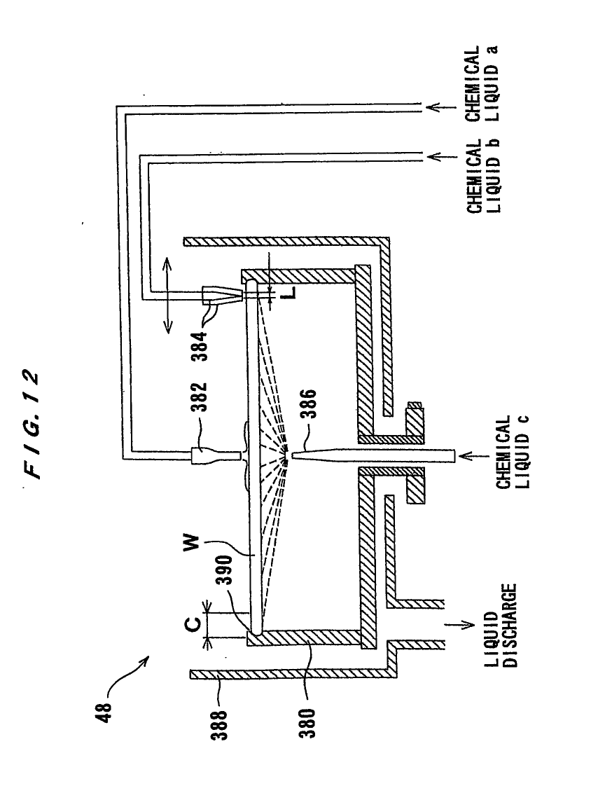

Next, an electrolytic processing unit 36 in the substrate processing apparatus will be described. FIG. 9 is a schematic view showing the electrolytic processing unit 36 in the substrate processing apparatus. FIG. 10 is a plan view of FIG. 9. As shown in FIGS. 9 and 10, the electrolytic processing unit 36 comprises an arm 360, which is movable vertically and pivotable horizontally, a disc-shaped electrode section 361 supported at the free end of the arm 360, a substrate holder 362 disposed beneath the electrode section 361, and a power source 363 for supplying a voltage between below-described processing electrode 369 and feeding electrodes (feeding sections) 373.

The arm 360, which is allowed to pivot horizontally by the actuation of a pivot motor 364, is connected to the upper end of a pivot shaft 365 that is coupled to the pivot motor 364. The pivot shaft 365, which is allowed to move vertically by the actuation of a motor 367 for vertical movement, which is connected to a ball screw 366, with the arm 360, is connected to a ball screw 366 extending vertically.

The electrode section 361, which is allowed to rotate by the actuation of a hollow motor 368, is coupled to the hollow motor 368 for making a relative movement between the substrate W held by substrate holder 362 and the electrode section 369. As described above, the arm 360 is adapted to move vertically and pivot horizontally, the electrode section 361 is capable of moving vertically and pivoting horizontally with the arm 360.

A processing electrode 369 is attached to the lower part of the electrode section 361 with its surface facing downward. The processing electrode 369 is connected to a cathode extending from the power source 363 through the hollow portion formed in the pivot shaft 365 to the slip ring 370, and further extending from the slip ring 365 through the hollow portion of the hollow motor 368. An ion exchanger 369a is mounted on the surface (lower surface) of the processing electrode 369. The ion exchanger 369a may be composed of a nonwoven fabric which has an anion-exchange group or a cation-exchange group. A cation exchanger preferably carries a strongly acidic cation-exchange group (sulfonic acid group); however, a cation exchanger carrying a weakly acidic cation-exchange group (carboxyl group) may also be used. Though an anion exchanger preferably carries a strongly basic anion-exchange group (quaternary ammonium group), an anion exchanger carrying a weakly basic anion-exchange group (tertiary or lower amino group) may also be used.

The nonwoven fabric carrying a strongly basic anion-exchange group can be prepared by, for example, the following method: A polyolefin nonwoven fabric having a fiber diameter of 20-50 μm and a porosity of about 90% is subjected to the so-called radiation graft polymerization, comprising γ-ray irradiation onto the nonwoven fabric and the subsequent graft polymerization, thereby introducing graft chains; and the graft chains thus introduced are then aminated to introduce quaternary ammonium groups thereinto. The capacity of the ion-exchange groups introduced can be determined by the amount of the graft chains introduced. The graft polymerization may be conducted by the use of a monomer such as acrylic acid, styrene, glicidyl methacrylate, sodium styrenesulfonate or chloromethylstyrene. The amount of the graft chains can be controlled by adjusting the monomer concentration, the reaction temperature and the reaction time. Thus, the degree of grafting, i.e. the ratio of the weight of the nonwoven fabric after graft polymerization to the weight of the nonwoven fabric before graft polymerization, can be made 500% at its maximum. Consequently, the capacity of the ion-exchange groups introduced after graft polymerization can be made 5 meq/g at its maximum.

The nonwoven fabric carrying a strongly acidic cation-exchange group can be prepared by the following method: As in the case of the nonwoven fabric carrying a strongly basic anion-exchange group, a polyolefin nonwoven fabric having a fiber diameter of 20-50 μm and a porosity of about 90% is subjected to the so-called radiation graft polymerization comprising γ-ray irradiation onto the nonwoven fabric and the subsequent graft polymerization, thereby introducing graft chains; and the graft chains thus introduced are then treated with a heated sulfuric acid to introduce sulfonic acid groups thereinto. If the graft chains are treated with a heated phosphoric acid, phosphate groups can be introduced. The degree of grafting can reach 500% at its maximum, and the capacity of the ion-exchange groups thus introduced after graft polymerization can reach 5 meq/g at its maximum.

The base material of the ion exchanger 369a may be a polyolefin such as polyethylene or polypropylene, or any other organic polymer. Further, besides the form of a nonwoven fabric, the ion-exchanger may be in the form of a woven fabric, a sheet, a porous material, net or short fibers, etc. When polyethylene or polypropylene is used as the base material, graft polymerization can be effected by first irradiating radioactive rays (γ-rays or electron beam) onto the base material (pre-irradiation) to thereby generate a radical, and then reacting the radical with a monomer, whereby uniform graft chains with few impurities can be obtained. When an organic polymer other than polyolefin is used as the base material, on the other hand, radical polymerization can be effected by impregnating the base material with a monomer and irradiating radioactive rays (γ-rays, electron beam or UV-rays) onto the base material (simultaneous irradiation). Though this method fails to provide uniform graft chains, it is applicable to a wide variety of base materials.

By using a nonwoven fabric having an anion-exchange group or a cation-exchange group as the ion exchanger 369a, it becomes possible that pure water or ultrapure water, or a liquid such as an electrolytic solution can freely move within the nonwoven fabric and easily arrive at the active points in the nonwoven fabric having a catalytic activity for water dissociation, so that many water molecules are dissociated into hydrogen ions and hydroxide ions. Further, by the movement of pure water or ultrapure water, or a liquid such as an electrolytic solution, the hydroxide ions produced by the water dissociation can be efficiently carried to the surface of the substrate W, whereby a high electric current can be obtained even with a low voltage applied.

When the ion exchanger 369a have only one of anion-exchange groups and cation-exchange groups, a limitation is imposed on electrolytically processible materials and, in addition, impurities are likely to form due to the polarity. In order to solve this problem, the anion exchanger and the cation exchanger may be superimposed, or the ion exchanger 369a may carry both of an anion-exchange group and a cation-exchange group per se, whereby a range of materials to be processed can be broadened and the formation of impurities can be restrained.

With respect to the electrode, its oxidation or dissolution by the electrolytic reaction usually is a problem. It is therefore preferred to use as an electrode material carbon, a relatively inactive noble metal, a conductive oxide or a conductive ceramic. An electrode, when oxidized, increases its electric resistance and incurs a rise of the applied voltage. By protecting the surface of an electrode with a hardly oxidative material, such as platinum, or with a conductive oxide, such as iridium oxide, a lowing of the conductivity due to oxidation of the electrode material can be prevented.

A through-hole 361a is formed in the central portion of the electrode section 361. The through-hole 361a is connected to a pure water supply pipe 371 as a pure water supply section for supplying pure water, preferably ultrapure water, which vertically extends inside the hollow motor 368. Pure water or ultrapure water is supplied through the pure water supply pipe 371 and the through-hole 361a to the surface (upper surface) of the substrate W from above the substrate.

The substrate W is detachably held with its surface facing upward (face-up) by the substrate holder 362 disposed beneath the electrode section 361. A substrate rotating motor 372 for making a relative movement between the substrate W and the electrode portion 372 is disposed beneath the substrate holder 362. The substrate holder 362 is coupled to the substrate rotating motor 372 so that the substrate holder 362 is allowed to rotate by the actuation of the substrate rotating motor 372.

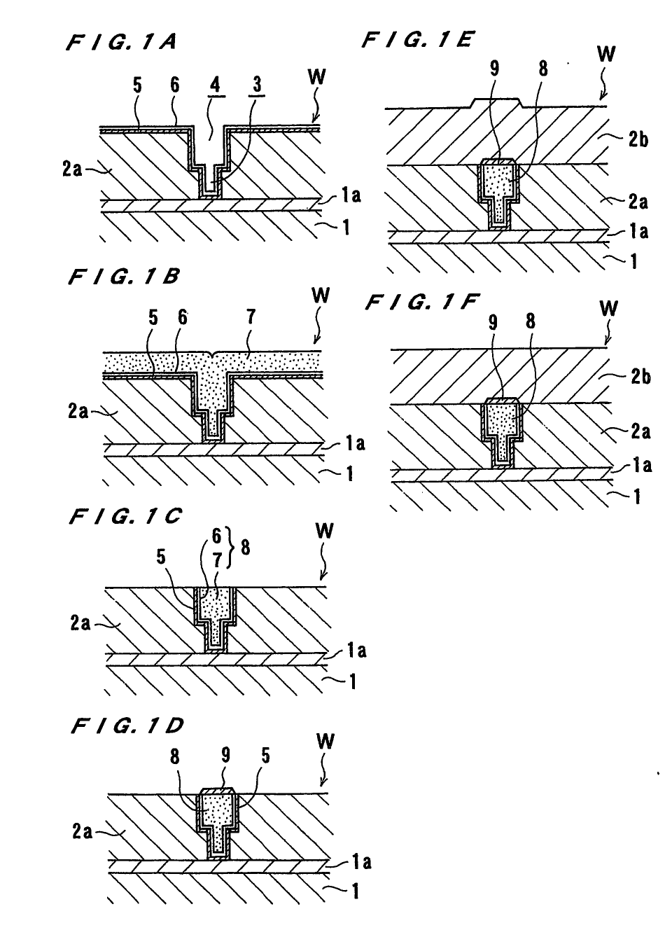

As shown in FIG. 10, there are provided with a plurality of feeding electrodes (feeding sections) 373 at the determined positions along the circumstantial direction of the substrate holder 362. When the substrate W is held by the substrate holder 362, the feeding electrodes 373 contact with the periphery of the substrate W, whereby passing the electricity to copper film (see FIG. 1B). These feeding electrodes are connected to the anode of the power source 363. Although, the electrolytic processing unit 36 according to the embodiment is adapted to bring the feeding electrodes 373 into contact with the periphery (bevel portion) of the substrate W, the feeding electrodes 373 may be contacted with the surface of the substrate other than the periphery of the substrate W.

According to the embodiment, as shown in FIG. 9, the electrolytic processing unit apparatus 36 employs, as the electrode section 361, such one that has a sufficiently smaller diameter than that of the substrate W held by the substrate holder 362 so that the surface of the substrate may not be entirely covered with the electrode section 361. The size of the electrode section 361 is not limited to the above-described embodiment.

According to the embodiment, the processing electrode 369 is connected to the cathode of the power source 363 and the feeding electrodes (feeding sections) 373 are connected to the anode of the power source 363. Depending upon a material to be processed, the electrode connected to the cathode of the power source 363 can be a feeding electrode and the electrode connected to the anode of power source 363 can be a processing electrode. More specifically, when the material to be processed is copper, molybdenum, iron or the like, electrolytic processing proceeds on the cathode side, and therefore the electrode connected to the cathode of the power source 363 should be the processing electrode and the electrode connected to the anode should be the feeding electrode. In the case of aluminum, silicon or the like, on the other hand, electrolytic processing proceeds on the anode side. Accordingly, the electrode connected to the anode of the power source 363 should be the processing electrode and the electrode connected to the cathode should be the feeding electrode.

As shown in FIG. 10, a regeneration section 374 for regenerating the ion exchanger 369a mounted on the electrode section 361 is disposed beside the substrate holder 362. In the case of the ion exchanger 369a is a cation exchanger, only cations (positive ion) can move or migrate electrically within the cation exchanger. When regenerating a cation exchanger, as shown in FIG. 11, a pair of a regeneration electrode 377a and a counter electrode 377b, a partition 376 disposed between the electrodes, and a cation exchanger 369a as an ion exchanger to be regenerated, disposed between the counter electrode 377b and the partition 376, are provided. A liquid A is supplied from a first liquid supply section 378a to between the partition 376 and the regeneration electrode 377a and a liquid B is supplied from a second liquid supply section 378b to between the partition 376 and the counter electrode 377b and, at the same time, a voltage is applied from a regeneration power source 379 to between the regeneration electrode 377a as a cathode and the counter electrode 377b as an anode. Dissolved ions M⁺ of a to-be-processed material, which have been taken in the cation exchanger (ion exchanger to be regenerated) 369a during processing of the material, then move from the counter electrode (anode) 377b side toward the regeneration electrode (cathode) 377a side and pass through the partition 376. The ions M⁺ that have passed through the partition 376 are discharged out of the system by the flow of liquid A supplied between the partition 376 and the regeneration electrode 377a. The cation exchanger 369a is thus regenerated. In the case of the ion exchanger 369a is an anion exchanger, the positive and negative of the voltage applied from the regeneration power source 379 may be reversed.

It is desired that the partition 376 not hinder the migration therethrough of impurity ions removed from the ion exchanger 369a to be regenerated and inhibit permeation therethrough of the liquid (including ions in the liquid) flowing between the partition 376 and the regeneration electrode 377a into the ion exchanger 369a side. In this regard, ion exchangers permit selective permeation therethrough of cations or anions and can prevent intrusion of the liquid flowing between the partition 376 and the regeneration electrode 377a into the to-be-regenerated ion exchanger 369a side. Thus, a suitably selected ion exchanger can meet the above requirements for the partition. An ion exchange having the same ion-exchange group as the ion exchanger to be regenerated may be suitable for the partition 376.

It is desired that the liquid to be supplied to between the partition 376 and the regeneration electrode 377a be a liquid, such as an electrolytic solution, which has a high electric conductivity and does not form a hardly soluble or insoluble compound through a reaction with ions removed from the ion exchanger 369a to be processed. Thus, the liquid is for discharging those ions, which have moved from the ion exchanger 369a to be regenerated and passed through the partition 376, out of the system by the flow of the liquid. The above liquid having a high conductivity, because of its low electric resistance, can reduce the power consumption in the regeneration section. Further the above liquid, which does not form an insoluble compound (by-product) through a reaction with the impurity ions, can prevent adhesion of a solid matter to the partition 376. A suitable liquid may be chosen depending upon the kind of the impurity ion to be discharged. For example, when regenerating an ion exchanger that was used in electrolytic polishing of copper, sulfuric acid with a concentration of 1 wt % or higher may be used.

The regeneration section 374 and the ion exchanger 369a to be regenerated may be made a relative movement during the regeneration process. Instead of the partition 376, an ion exchange nonwoven fabric may be disposed between the ion exchanger 369a to be regenerated and the regeneration electrode 377a. In this case, above-described voltage is applied to between the regeneration electrode 377a and the counter electrode 377b while supplying a liquid (pure water) between the two ion exchangers, whereby the ions accumulated in the ion exchanger 369a is moved into the ion exchange nonwoven fabric.

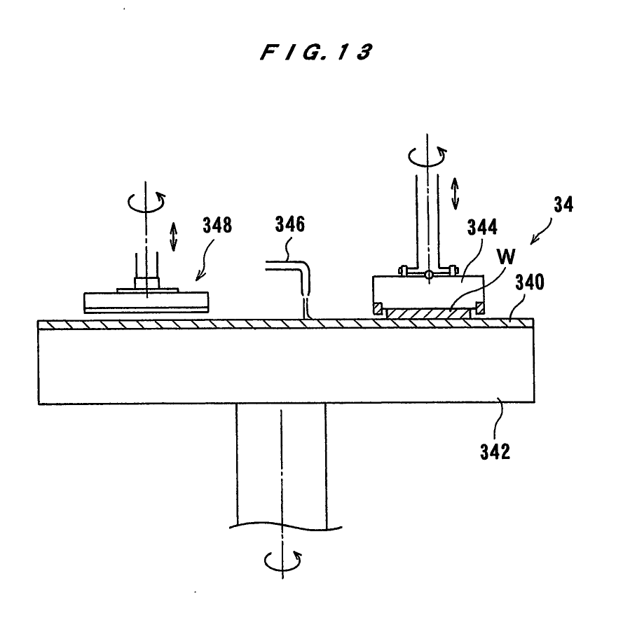

Next, the bevel-etching unit 48 in the substrate processing apparatus will be described. FIG. 12 is a vertical sectional view schematically showing the bevel-etching unit 48. As shown in FIG. 12, the bevel-etching unit 48 according to the embodiment comprises a substrate holding portion 380 adapted to rotate a substrate W at a high speed, while holding the substrate W horizontally, a center nozzle 382 placed above a nearly central portion of the face of the substrate W held by the substrate holding portion 380, an edge nozzle 384 placed above the peripheral edge portion of the substrate W, and a back nozzle 386 positioned below a nearly central portion of the backside of the substrate W.

The substrate holding portion 380 is positioned inside a bottomed cylindrical waterproof cover 388 and adapted to hold the substrate W by spin chucks 390 at a plurality of locations along a circumferential direction of a peripheral edge portion of the substrate W in such a state that the face of the substrate W faces upwardly. The center nozzle 382 and the edge nozzle 384 are directed downward, respectively, and the back nozzle 386 is directed upward.

An acid solution is supplied from the center nozzle 382 to the central portion of the surface of the substrate W, and spreads over the entire surface of the substrate W under centrifugal forces. Any natural oxide film of copper formed on the circuit area on the surface of the substrate W is immediately removed by the acid solution, and hence prevented from growing on the surface of the substrate W. The acid solution may comprise hydrochloric acid, hydrofluoric acid, sulfuric acid, citric acid, oxalic acid, or a combination thereof which is generally used in a cleaning process in a semiconductor fabrication process. The acid solution may comprise any acid insofar as it is a non-oxidizing acid. The acid solution of hydrofluoric acid is preferable because it can also be used to clean the reverse side of the substrate W and reduce the number of chemical used. Further, in case of hydrofluoric acid, the hydrofluoric acid concentration is preferably 5% or less by weight in order not to roughen the surface of copper.

An oxidizing agent solution is continuously or intermittently supplied from the edge nozzle 384 to the periphery of the substrate W. A copper film grown on the upper and outer peripheral surfaces of the periphery of the substrate W is quickly oxidized by the oxidizing agent solution, and at the same time etched and dissolved away by the acid solution which is supplied from the center nozzle 382 and spreads over the entire surface of the substrate W. Because the copper film is etched at a point other than where the oxidizing agent solution is supplied, the concentration and the amount of the oxidizing agent solution do not need to be high. The oxidizing agent solution may comprise ozone, hydrogen peroxide, nitric acid, hypochlorous acid, or a combination thereof which is generally used in a cleaning process in a semiconductor fabrication process. If ozone water is used, then ozone should preferably be contained in 20 ppm or more and 200 ppm or less. If hydrogen preoxide is used, then it should preferably be contained in 10% or more by weight and 80% or less by weight. If hypochlorous acid is used, then it should preferably be contained in 1% or more by weight and 50% or less by weight.

An oxidizing agent solution and an etchant for silicon oxide film are simultaneously or alternately supplied from the back nozzle 386 to the central portion of the reverse side of the substrate W. Copper attached to the reverse side of the substrate W, together with silicon of the substrate W, is oxidized by the oxidizing agent solution and etched away by the etchant for silicon oxide film. The oxidizing agent solution may comprise ozone, hydrogen peroxide, nitric acid, hypochlorous acid, or a combination thereof. It is preferable for the back nozzle 386 to supply the same oxidizing agent solution as the oxidizing agent solution supplied to the periphery of the substrate W because the number of chemicals used is reduced. It is possible to use nitric acid as the etchant for silicon oxide film. The use of nitric acid for cleaning the surface of the substrate makes it possible to reduce the number of chemicals.

The edge nozzle 384 is adapted to be movable in a diametrical direction of the substrate W. The width of movement L of the edge nozzle 384 is set such that the edge nozzle 384 can be arbitrarily positioned in a direction toward the center from the outer peripheral end surface of the substrate, and a set value for L is inputted according to the size, usage, or the like of the substrate W. Normally, an edge cut width C is set in the range of 2 mm to 5 mm. In the case where a rotational speed of the substrate is a certain value or higher at which the amount of liquid migration from the backside to the face is not problematic, the film to be processed (copper film) within the edge cut width C can be removed.

An example of usage of the bevel-etching unit 48 will be described below. The edge nozzle 384 is positionally adjusted so that the edge cutting width C is set depending on the size of the substrate W and the purpose for which the substrate W will be used. The substrate W is then held horizontally by the substrate holder 380, and rotated with the substrate holder 380 in the horizontal plane. DHF (diluted fluoroboric acid), for example, is continuously supplied from the central nozzle 382 to the central portion of the surface of the substrate W, and H₂O₂, for example, is continuously or intermittently supplied from the edge nozzle 384 to the periphery of the substrate W.

Within an area (edge and beveled surface) in the edge cutting width C on the periphery of the substrate W, a mixed solution of HF and H₂O₂ is produced, rapidly etching away copper on the surface of the substrate W. A mixed solution of HF and H₂O₂ may be supplied from the edge nozzle 384 to the periphery of the substrate W for thereby etching copper on the periphery of the substrate W. The concentration of DHF and H₂O₂ determines an etching rate for copper.

Simultaneously, chemical solution, H₂O₂ and DHF, for example, are separately supplied from the back nozzle 386 in the order of H₂O₂ and DHF. Hence, copper attached to the reverse side of the substrate W is oxidized by H₂O₂ and etched away by DHF, so that copper contamination on the reverse side of the substrate W can be removed.

The substrate W is then rinsed with pure water and spin-dried, whereupon the process of the substrate W is completed. The copper film present in the edge cutting width C on the periphery (edge and beveled surface) of the surface of the substrate W, and copper contamination on the reverse side of the substrate W can simultaneously be removed within 80 seconds, for example.

Next, the CMP unit 34 in the substrate processing apparatus will be described. FIG. 13 is a vertical sectional view schematically showing the CMP unit 34. As shown in FIG. 13, the CMP unit 34 comprises a polishing table 342 with a polishing cloth (polishing pad) 340, which acts as a polishing surface, attached thereto, and a top ring 344 for holding a substrate W to be polished. The top ring 344 which holds a substrate W to be polished presses the substrate W against the polishing cloth 340 on the polishing table 342. In operation, the substrate W is held on the top ring 344, and pressed against the polishing pad 340 by the top ring 344. The polishing table 342 and the top ring 344 are rotated about their own axes relatively to each other, thereby polishing the surface of the substrate W. At this time, the abrasive liquid is supplied from the abrasive liquid supply nozzle 346 to the polishing cloth 340. The abrasive liquid comprises, for example, an alkaline solution with fine abrasive grain particles of silica or the like suspended therein. Therefore, the substrate W is polished by both a chemical action of the alkaline solution and a mechanical action of the fine abrasive grain particles.

With the progress of the polishing, the polishing liquid and the ground-off particles are likely to attach to the polishing cloth 340, whereby the polishing rate of the CMP unit 34 is lowered, and the polished substrates tend to suffer polishing irregularities. Therefore, the CMP unit 34 is provided with a dresser 348 for recovering the surface of the polishing cloth 340 before, or after, or during polishing. In operation, the dressing surface of the dresser 348 is pressed against the polishing surface of the polishing cloth 340 on the polishing table 342, and the dresser 348 and the polishing table 342 are rotated relatively to each other for thereby bringing the dressing surface in sliding contact with the polishing surface. Thus, the polishing liquid and the ground-off particles attached to the polishing surface are removed, and planalization and regeneration of the polishing surface are conducted.

A description will now be given of a series of processings carried out by the substrate processing apparatus of this embodiment.

A cassette housing e.g. substrates W as shown in FIG. 1A, having a seed layer 6 formed in the surface, is set in the loading/unloading sections 30, and one substrate W is taken out of the cassette by the transfer robot 32. As necessary, the transfer robot 32 transfers the substrate W to the reversing machine 44 or 52 to reverse the substrate W so that the front surface having the seed layer 6 faces downward. The reversed substrate W is again taken by the transfer robot 32 and transferred to the plating unit 38.

In the plating unit 38, copper electroplating, for example, is carried out to form e.g. a copper film 7 (see FIG. 1B) as a conductive film (to-be-processed material) on the surface of the substrate W. After completion of the plating, the substrate W is transferred by the transfer robot 32 to the cleaning unit 40, where the substrate is cleaned. The substrate W after the cleaning is transferred by the transfer robot 32 to the annealing unit 42.

In the annealing unit 42, heat treatment is carried out to anneal the substrate W. The transport robot 32 transfers the annealed substrate W to the reversing machine 44 to reverse the substrate W so that the front surface faces upward. The reversed substrate W is again taken by the transfer robot 32, and transferred by the transport robot 32 to the pusher 36a in the electrolytic processing unit 36 and placed on the pusher 36a. The substrate W on the pusher 36a is then transferred to the substrate holder 362 of the electrolytic processing unit 36, and the substrate W is placed and held on the substrate holder 362.

In the electrolytic processing unit 36, the electrode section 361 is lowered so as to bring the ion exchanger 369a close to or into contact with the surface of the substrate W held on the substrate holder 362. While supplying pure water or ultrapure water onto the upper surface of the substrate W, a given voltage is applied between the processing electrode 369 and the feeding electrodes 373, and the substrate holder 362 and the electrode section 361 are rotated and, at the same time, the arm 360 is pivoted to move the electrode section 361 over the upper surface of the substrate W. By the action of hydrogen ions and hydroxide ion produced by the ion exchanger 369a, unnecessary copper film 7 formed in the surface of the substrate W is processed away at the processing electrode (cathode) 369, whereby interconnects (copper interconnects) 8 comprised of copper film 7 and seed layer 6 are formed (see FIG. 1C).

Pure water, which is supplied between the substrate W and the ion exchanger 369a during electrolytic processing, herein refers to a water having an electric conductivity of not more than 10 μS/cm, and ultrapure water refers to a water having an electric conductivity of not more than 0.1 μS/cm. The use of pure water or ultrapure water containing no electrolyte upon electrolytic processing can prevent impurities such as an electrolyte from adhering to and remaining on the surface of the substrate W. Further, copper ions or the like dissolved during electrolytic processing are immediately caught by the ion exchanger 369a through the ion-exchange reaction. This can prevent the dissolved copper ions or the like from re-precipitating on the other portions of the substrate W, or from being oxidized to become fine particles which contaminate the surface of the substrate W.

It is possible to use, instead of pure water or ultrapure water, a liquid having an electric conductivity of not more than 500 μS/cm, for example, an electrolytic solution obtained by adding an electrolyte to pure water or ultrapure water. The use of such an electrolytic solution can further lower the electric resistance and reduce the power consumption. A solution of a neutral salt such as NaCl or Na₂SO₄, a solution of an acid such as HCl or H₂SO₄, or a solution of an alkali such as ammonia, may be used as the electrolytic solution, and these solutions may be selectively used according to the properties of the workpiece.

Further, it is also possible to use, instead of pure water or ultrapure water, a liquid obtained by adding a surfactant or the like to pure water or ultrapure water, and having an electric conductivity of not more than 500 μS/cm, preferably not more than 50 μS/cm, more preferably not more than 0.1 μS/cm (resistivity of not less than 10 MΩ cm). Due to the presence of a surfactant in pure water or ultrapure water, the liquid can form a layer, which functions to inhibit ion migration evenly, at the interface between the substrate W and the ion exchanger 369a, thereby moderating concentration of ion exchange (metal dissolution) to enhance the flatness of the processed surface. The surfactant concentration is desirably not more than 100 ppm. When the value of the electric conductivity is too high, the current efficiency is lowered and the processing rate is decreased. The use of the liquid having an electric conductivity of not more than 500 μS/cm, preferably not more than 50 μS/cm, more preferably not more than 0.1 μS/cm, can attain a desired processing regeneration rate.

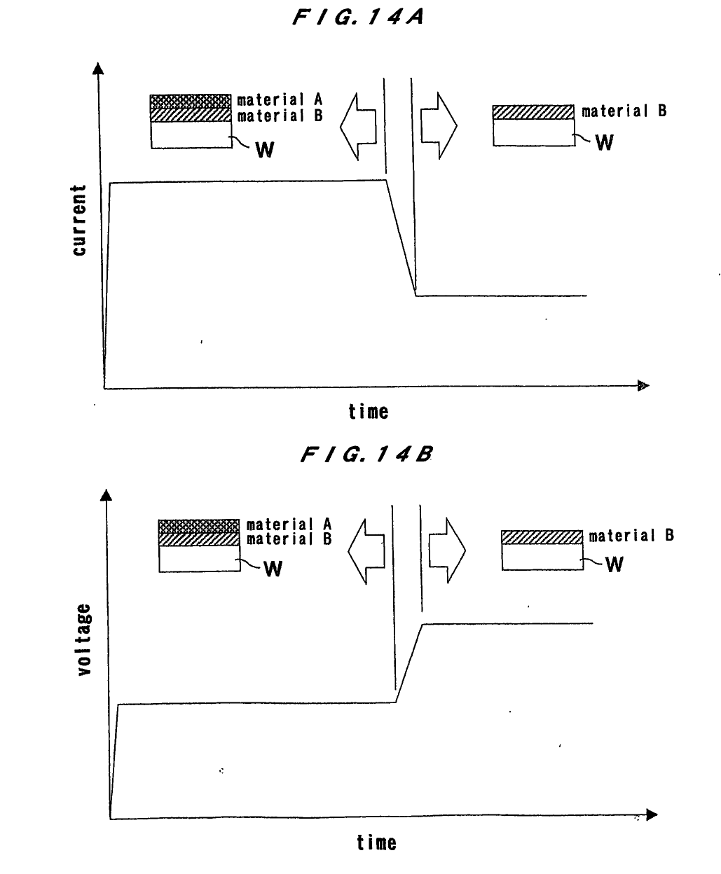

The monitor 54 monitors the voltage applied between the processing electrode 369 and the feeding electrodes 373 or the electric current flowing therebetween to detect the end point (terminal of processing) during electrolyte processing. It is noted in this connection that in electrolytic processing an electric current (applied voltage) varies, depending upon the material to be processed, even with the same voltage (electric current). For example, as shown in FIG. 14A, when an electric current is monitored in electrolytic processing of the surface of a substrate W to which a film of material B and a film of material A are laminated in this order, a constant electric current is observed during the processing of material A, but it changes upon the shift to the processing of the different material B. Likewise, as shown in FIG. 14B, though a constant voltage is applied between the processing electrode and the feeding electrode during the processing of material A, the voltage applied changes upon the shift to the processing of the different material B. FIG. 14A illustrates, by way of example, a case in which an electric current is harder to flow in electrolytic processing of material B compared to electrolytic processing of material A, and FIG. 14B illustrates a case in which the applied voltage becomes higher in electrolytic processing of material B compared to electrolytic processing of material A. As will be appreciated from the above-described example, the monitoring of changes in electric current or in voltage can surely detect the end point.

Though this embodiment shows the case where the monitor 54 monitors the voltage applied between the processing electrode and the feeding electrode, or the electric current flowing therebetween to detect the end point of processing, it is also possible to allow the monitor 54 to monitor a change in the state of the substrate being processed to detect an arbitrarily set end point of processing. In this case, “the end point of processing” refers to a point at which a desired processing amount is attained for a specified region in a surface to be processed, or a point at which an amount corresponding to a desired processing amount is attained in terms of a parameter correlated with a processing amount for a specified region in a surface to be processed. By thus arbitrarily setting and detecting the end point of processing even in the middle of processing, it becomes possible to conduct a multi-step electrolytic processing.

For example, the processing amount may be determined by detecting the change of frictional force due to a difference of friction coefficient produced when the processing surface reaches a different material, or the change of frictional force produced by removal of irregularities in the surface of the substrate. The end point of processing may be detected based on the processing amount thus determined. During electrolytic processing, heat is generated by the electric resistance of the to-be-processed surface, or by collision between water molecules and ions that migrate in the liquid (pure water) between the processing surface and the to-be-processed surface. When processing e.g. a copper film deposited on the surface of a substrate under a controlled constant voltage, with the progress of electrolytic processing and a barrier layer and an insulating film becoming exposed, the electric resistance increases and the current value decreases, and the heat value gradually decreases. Accordingly, the processing amount may be determined by detecting the change of the heat value. The end point of processing may therefore be detected. Alternatively, the film thickness of a to-be-processed film on a substrate may be determined by detecting the change in the intensity of reflected light due to a difference of reflectance produced when the processing surface reaches a different material. The end point of processing may be detected based on the film thickness thus determined. The film thickness of a to-be-processed film on a substrate may also be determined by generating an eddy current within a to-be-processed conductive film, e.g. a copper film, and monitoring the eddy current flowing within the substrate to detect change of e.g. the frequency or the circuit resistance. The end point of processing may thus be detected. Further, in electrolytic processing, the processing rate depends on the value of the electric current flowing between the processing electrode and the feeding electrode, and the processing amount is proportional to the quantity of electricity, determined as the product of the current value and the processing time. Accordingly, the processing amount may be determined by integrating the quantity of electricity, determined as the product of the current value and the processing time, and detecting that the integrated value reaches a predetermined value. The end point of processing may thus be detected.

After completion of the electrolytic processing, the power source 363 is disconnected, and the rotations of the electrode section 361 and the substrate holder 362 are stopped. Thereafter, the substrate W on the substrate holder 362 is moved onto the pusher 36a, and the substrate on the pusher 36a is taken by the transfer robot 32 and transferred to the bevel-etching unit 48. According to this embodiment, the feeding electrodes 373 are contacted directly with the substrate W in the electrolytic processing. It is therefore not possible physically to bring the processing electrode 369 close to the portion of the substrate in contact with the feeding electrodes 373. Accordingly, that portion cannot be processed, that is, the conduction film remains unprocessed at the portion of the substrate W that has been in contact with the feeding electrodes 373. According to this embodiment, after the electrolytic processing, the conductive film remaining unprocessed is etched away by the bevel-etching unit 48.

In the bevel-etching unit 48, the unnecessary copper film in the surface of the substrate W, i.e. the copper film remaining unprocessed at the portion of the substrate W that has been in contact with the feeding electrodes (feeding sections) 373 in the electrolytic processing unit 36, is etched away with a chemical liquid. After completion of the etching, the substrate W is transferred by the transfer robot 32 to the cleaning unit 50, where the substrate is cleaned. The transfer robot 32 transfers the cleaned substrate W to the reversing machine 52, where the substrate W is reversed so that the front surface faces downward. The reversed substrate W is again taken by the transfer robot 32, and transferred by the transfer robot 32 to the pusher 34a in the CMP unit 34 and placed on the pusher 34a. The substrate W on the pusher 34a is then transferred to the top ring 344 of the CMP unit 34, and the substrate W is held by the top ring 344.

In the CMP unit 34, the surface of the substrate W is polished through chemical mechanical polishing into a flat mirror-like surface. In the above-described electrolytic processing, there is a case where a barrier layer 5 (see FIG. 1A) remains unprocessed in the surface of the substrate W after the electrolytic processing. Such a barrier layer 5 can be removed by the polishing in the CMP unit 34. The polishing by the CMP unit 34 is also effective when it is desired to further polish away an insulating film 2a (see FIG. 1A) such as an oxide film. The substrate W after the polishing is transferred by the transfer robot 32 to the cleaning unit 46, where the substrate is cleaned. Thereafter, after reversing the substrate W by the reversing machine 44 or 52 according to necessity, the substrate W is returned by the transfer robot 32 to the cassette in the loading/unloading sections 30.

Though in the above-described embodiment the plating unit 38 and the electrolytic processing unit 36 are provided separately, it is possible to integrate these units into a single unit. Further, the plating unit 38, the CMP unit 34 and the annealing unit 42 are provided optionally according to necessity. Thus, one or more of these units may be eliminated, as the case may be, in constituting the substrate processing apparatus.

As described hereinabove, according to the present invention, unlike a CMP processing, electrolytic processing of a workpiece, such as a substrate, can be effected through an electrochemical action without causing any physical defects in the workpiece that would impair the properties of the workpiece. Further, the present electrolytic processing apparatus and method can effectively remove (clean) matter adhering to the surface of the workpiece. Accordingly, the present invention can omit a CMP processing entirely or at least reduce a load upon CMP. Furthermore, the electrolytic processing of a substrate can be effected even by solely using pure water or ultrapure water. This obviates the possibility that impurities such as an electrolyte will adhere to or remain on the surface of the substrate, can simplify a cleaning process after the removal processing, and can remarkably reduce a load upon waste liquid disposal.

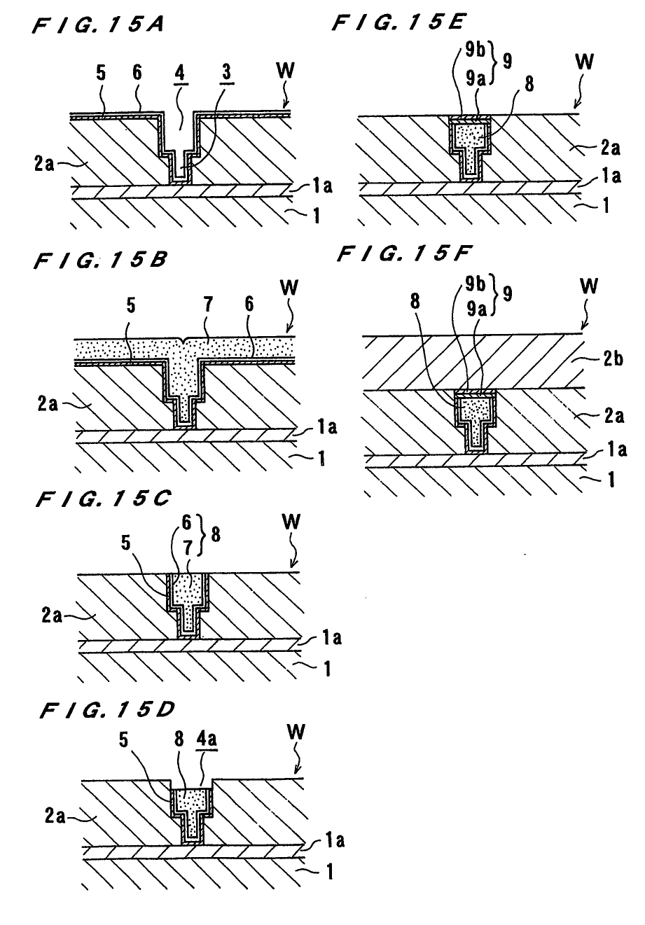

FIGS. 15A through 15F are diagrams illustrating, in sequence of process steps, an example of the formation of copper interconnects by a substrate processing method according to an embodiment of the present invention. As shown in FIG. 15A, an insulating film 2a, such as an oxide film of SiO₂ or a film of low-k material, is deposited on a conductive layer 1a in which semiconductor devices are formed, which is formed on a semiconductor base 1. Contact holes 3 and interconnect trenches 4 as fine trenches for interconnects are formed in the insulating film 2a by the lithography/etching technique. Thereafter, a barrier layer 5 of TaN or the like is formed on the entire surface, and a seed layer 6 as an electric supply layer for electroplating is formed on the barrier layer 5 by sputtering or the like.

Then, as shown in FIG. 15B, copper plating is performed onto the surface of the substrate W to fill the contact holes 3 and the interconnect trenches 4 with copper and, at the same time, deposit a copper film 7 on the insulating film 2a. Thereafter, the barrier layer 5, the seed layer 6 and the copper film 7 on the insulating film 2a are removed by chemical mechanical polishing (CMP) so as to make the surface of the copper film 7 filled in the contact holes 3 and the interconnect trenches 4, and the surface of the insulating film 2a lie substantially on the same plane. Interconnects (copper interconnects) 8 composed of the seed layer 6 and the copper film 7 as shown in FIG. 15C is thus formed.

Further, removal of the barrier layer 5, the seed layer 6 and the copper film 7 in the interconnect trench 4 by the chemical mechanical polishing, etc. is continued, thereby forming a recess 4a for filling, having a predetermined depth, in the upper portion of the interconnect trench 4, as shown in FIG. 15D. Thus, the removal of the barrier layer 5, the seed layer 6 and the copper film 7 by the chemical mechanical polishing, etc. is continued even after the surface of the copper film 7 filled in the contact hole 3 and the interconnect trench 4 becomes flush with the surface of the insulating film 2a to thereby further remove the barrier layer 5, the seed layer 6 and the copper film 7 in the interconnect trench 4, and the removal operation is terminated when the recess 4a for filling being formed in the upper portion of the interconnect trench 4 reaches the predetermined depth.

Alternatively, it is possible to remove first the barrier layer 5, the seed layer 6 and the copper film 7 on the insulating film 2a by the chemical mechanical polishing (CMP) or electrolytic processing until the surface of the copper film 7 filled in the contact hole 3 and the interconnect trench 4 becomes flush with the surface of the insulating film 2a, and then remove the barrier layer 5, the seed layer 6 and the copper film 7 in the interconnect trench 4 by chemical etching.

As shown in FIG. 15E, in the recess 4a for filling thus formed in the substrate W, a protective film 9, for example a multi-layer laminated film comprised of a thermal diffusion preventing layer 9a and an oxidation preventing layer 9b, is selectively formed, thereby covering and protecting the exposed surface of interconnects 8 with the protective film 9. More specifically, after water-washing the substrate W, a first-step electroless plating is carried out to the surface of the substrate W to form the thermal diffusion preventing layer 9a, composed of e.g. a Co alloy, selectively on the surface of interconnects 8. Next, after water-washing the substrate, a second-step electroless plating is carried out to form the oxidation preventing layer 9b, composed of e.g. a Ni alloy, selectively on the surface of the thermal diffusion preventing layer 9a. The thickness of the protective film 9 is made equal approximately to the depth of the recess 4a for filling, i.e. the surface of the protective layer 9 is made flush with the surface of the insulating film 2b.

Then, after water-washing the substrate W followed by drying, an insulating film 2b, such as SiO₂ or SiOF, is superimposed on the surface of the substrate W, as shown in FIG. 15F. By making the surface of the protective film 9 flush with the surface of the insulating film 2b, the protective film 9 can be prevented from protruding the flattened surface. This can secure a sufficient surface flatness of the insulating film 2b later deposited on the substrate surface, thus eliminating the need for an additional process of flattening the surface of the insulating film 2b.

By thus selectively covering the exposed surface of interconnects 8 and protecting the interconnects 8 with the protective film 9, the multi-layer laminated film comprised of the thermal diffusion preventing layer 9a, composed of e.g. a Co alloy, which can effectively prevent thermal diffusion of the interconnects 8, and the oxidation preventing layer 9b, composed of e.g. a Ni alloy, which can effectively prevent oxidation of the interconnects 8, both of the oxidation and the thermal diffusion of the interconnects 8 can be effectively prevented. In this regard, protection of the interconnects solely with a Co or Co alloy layer cannot effectively prevent oxidation of the interconnects, while protection of the interconnects solely with a Ni or Ni alloy layer cannot effectively prevent thermal diffusion of the interconnects. The combination of the two layers can overcome the drawbacks.

Further, by superimposing the oxidation preventing layer 9b on the surface of the thermal diffusion preventing layer 9a, oxidation of the interconnects, for example, upon deposition of the insulating film 2b in an oxidizing atmosphere for the formation of a semiconductor device having a multi-layer interconnect structure, can be prevented without lowing of the oxidation preventing effect.

Though in this embodiment the two-layer laminated film, comprised of the thermal diffusion preventing layer 9a and the oxidation preventing layer 9b, is employed as the protective film 9, it is of course possible to use a protective film of a single layer or of three or more layers.

According to this embodiment, a Co—W—B alloy may be used for the thermal diffusion preventing layer 9a. The thermal diffusion preventing layer 9a of a Co—W—B alloy can be formed by using a plating solution containing Co ions, a complexing agent, a pH buffer, a pH adjusting agent, an alkylamine borane as a reducing agent, and a tungsten-containing compound, and immersing the surface of the substrate W in the plating solution.

If desired, the plating solution may further contain at least one of a stabilizer selected from one or more kinds of heavy metal compounds and sulfur compounds, and a surfactant. Further, the plating solution is adjusted to within the pH range of preferably 5-14, more preferably 6-10, by using a pH adjusting agent such as ammonia water or ammonium hydroxide. The temperature of the plating solution is generally in the range of 30-90° C., preferably 40-80° C. The cobalt ions in the plating solution may be supplied from a cobalt salt, for example, cobalt sulfate, cobalt chloride or cobalt acetate. The amount of the cobalt ions is generally in the range of 0.001-1.0 mol/L, preferably 0.01-0.3 mol/L.

Specific examples of the complexing agent may include carboxylic acids, such as acetic acid, or their salts; oxycarboxylic acids, such as tartaric acid and citric acid, and their salts; and aminocarboxylic acids, such as glycine, and their salts. These compounds may be used either singly or as a mixture of two or more. The total amount of the complexing agent is generally 0.001-1.5 mol/L, preferably 0.01-1.0 mol/L. Specific examples of the pH buffer may include ammonium sulfate, ammonium chloride and boric acid. The pH buffer is used generally in an amount of 0.01-1.5 mol/L, preferably 0.1-1 mol/L. Examples of the pH adjusting agent may include ammonia water and tetramethylammonium hydroxide (TMAH). By using the pH adjusting agent, the pH of the plating solution is adjusted generally to 5-14, preferably 6-10.

The alkylamine borane as a reducing agent may specifically be dimethylamine borane (DMAB) or diethylamine borane. The reducing agent is used generally in an amount of 0.01-1.0 mol/L, preferably 0.01-0.5 mol/L.

Examples of the tungsten-containing compound may include tungstic acid or its salts, and heteropoly acids, such as tangstophosphoric acids (e.g. H₃(PW₁₂P₄₀).nH₂O), and their salts. The tungsten-containing compound is used generally in an amount of 0.001-1.0 mol/L, preferably 0.01-0.1 mol/L.

Besides the above-described components, other known additives may be added to the plating solution. Examples of usable additives include a bath stabilizer, which may be a heavy metal compound such as a lead compound, a sulfur compound such as a thiocyanate, or a mixture thereof, and a surfactant of an anionic, cationic or nonionic type.

The use of an alkylamine borone, which is free from sodium, as the reducing agent makes it possible to apply an oxidizing current to copper, a copper alloy, silver, or a silver alloy to thereby avoid the need for imparting a palladium catalyst, thus enabling a direct electroless plating by immersing the surface of the substrate W in the plating solution.

Though this example uses a Co—W—B alloy for the thermal diffusion preventing layer 9a, it is also possible to use Co as a single substance, a Co—W—P alloy, a Co—P alloy, a Co—B alloy, etc. for thermal diffusion preventing layer 9a.

According to the embodiment, a Ni—B alloy may be used for the oxidation preventing layer 9b. The oxidation preventing layer (Ni—B alloy layer) 9b may be formed by using an electroless plating solution containing nickel ions, a complexing agent for nickel ions, an alkylamine borane or a borohydride compound as a reducing agent for nickel ions, and ammonia ions, the pH of the plating solution being adjusted to e.g. 8-12, and immersing the surface of the substrate W in the plating solution. The temperature of the plating solution is generally 50 to 90° C., preferably 55 to 75° C.

Examples of the complexing agent for the nickel ions may include malic acid and glycine. NaBH₄, for example, may be used as the horohydride compound. As described above, the use of an alkylamine borone as the reducing agent makes it possible to avoid the need for imparting a palladium catalyst, and to perform electroless plating by immersing the surface of the substrate W in the plating solution. The use of the common reducing agent with the electroless plating solution for forming the Co—W—B alloy layer, as described above, it is possible to perform the electroless plating continuously.

Though this example uses a Ni—B alloy for the oxidation preventing layer 9b, it is also possible to use Ni as a single substance, a Ni—P alloy or a Ni—W—P alloy, etc. for the oxidation preventing layer 9b. Further, though this example uses copper as interconnects material, it is possible to use instead a copper alloy, silver or a silver alloy.

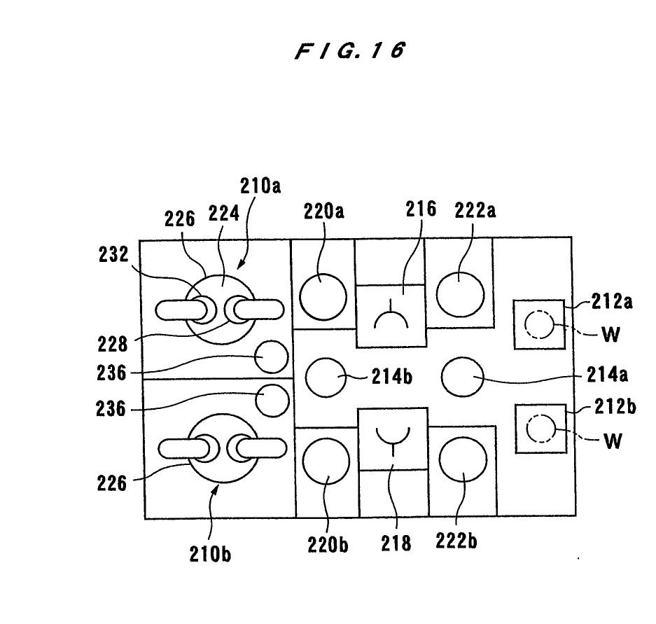

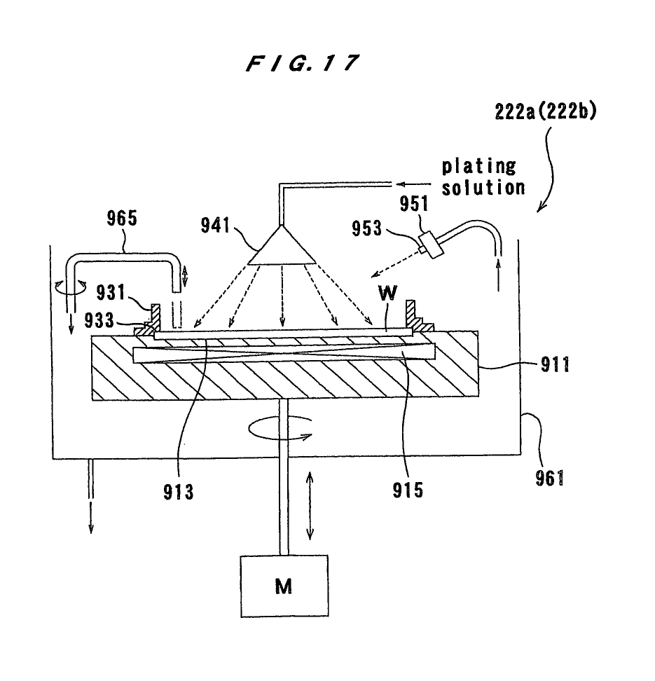

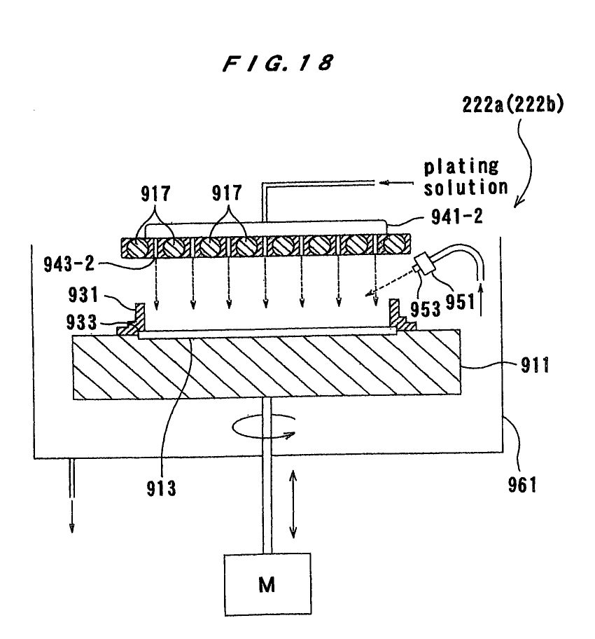

FIG. 16 is a plan view schematically showing the construction of a substrate processing apparatus that carries out the substrate processing illustrated in FIGS. 15A through 15F. The substrate processing apparatus includes a pair of chemical mechanical polishing (CMP) units 210a, 210b disposed side-by-side at one end of the space on a rectangular floor, and a pair of loading/unloading sections for placing thereon cassettes 212a, 212b each housing substrates W, such as semiconductor wafers, disposed at the other end of the space. Two transfer robots 214a, 214b are disposed on a line connecting the CMP units 210a, 210b and the loading/unloading sections. Reversing machines 216, 218 are disposed on both sides of the transfer line. Cleaning units 220a, 220b and electroless plating units 222a, 222b are disposed on both sides of the reversing machines 216, 218. Further, vertically movable pushers 236 are provided in the CMP units 210a, 210b on the transfer line side for transfer of the substrate W between the pushers 236 and the CMP units 210a, 210b.

FIG. 17 is a view schematically showing the construction of the electroless plating units 222a, 222b. In this example, one electroless plating units 222a is adapted to carry out above-described first-step electroless plating, for example, to form the thermal diffusion preventing layer 9a on the surface of interconnects 8, the other electroless plating unit 222b is adapted to carry out above-described second-step electroless plating, for example, to form the oxidation preventing layer 9b on the surface of the thermal diffusion preventing layer 9a. These electroless plating units 222a, 222b has the same construction, except for plating solution to be used in these electroless plating units.

Each of the electroless plating units 222a, 222b comprises holding means 911 for holding a substrate W on its upper surface, a dam member 931 for contacting a peripheral edge portion of a surface to be plated (upper surface) of the substrate W held by the holding means 911 to seal the peripheral edge portion, and a shower head 941 for supplying a plating solution to the plating surface of the substrate W having the peripheral edge portion sealed with the dam member 931. Each of the electroless plating units 222a and 222b further comprises cleaning liquid supply means 951 disposed near an upper outer periphery of the holding means 911 for supplying a cleaning liquid to the plating surface of the substrate W, a recovery vessel 961 for recovering a cleaning liquid or the like (plating waste liquid) discharged, a plating solution recovery nozzle 965 for sucking in and recovering the plating solution held on the substrate W, and a motor M for rotationally driving the holding means 911.

The holding means 911 has a substrate placing portion 913 on its upper surface for placing and holding the substrate W. The substrate placing portion 913 is adapted to place and fix the substrate W. Specifically, the substrate placing portion 913 has a vacuum attracting mechanism (not shown) for attracting the substrate W on a backside thereof by vacuum suction. A backside heater 915, which is planar and heats the plating surface of the substrate W from underside to keep it warm, is installed on the backside of the substrate placing portion 913. The backside heater 915 is composed of, for example, a rubber heater. This holding means 911 is adapted to be rotated by the motor M and is movable vertically by lifting means (not shown).

The dam member 931 is cylindrical, has a seal portion 933 provided in a lower portion thereof for sealing the outer peripheral edge of the substrate W, and is installed so as not to move vertically from the illustrated position.

The shower head 941 is of a structure having many nozzles provided at the front end for scattering the supplied plating solution in a shower form and supplying it substantially uniformly to the plating surface of the substrate W. The cleaning liquid supply means 951 has a structure for ejecting a cleaning liquid from a nozzle 953.

The plating solution recovery nozzle 965 is adapted to be movable upward and downward and swingable, and the front end of the plating solution recovery nozzle 965 is adapted to be lowered inwardly of the dam member 931 located on the upper surface peripheral edge portion of the substrate W and to suck in the plating solution on the substrate W.

Next, the operation of each of the electroless plating units 222a and 222b will be described. First, the holding means 911 is lowered from the illustrated state to provide a gap of a predetermined dimension between the holding means 911 and the dam member 931, and the substrate W is placed on and fixed to the substrate placing portion 913. An 8-inch wafer, for example, is used as the semiconductor substrate W.

Then, the holding means 911 is raised to bring its upper surface into contact with the lower surface of the dam member 931 as illustrated in FIG. 17, and the outer periphery of the substrate W is sealed with the seal portion 933 of the dam member 931. At this time, the surface of the substrate W is in an open state.

Then, the substrate W itself is directly heated by the backside heater 915, while the plating solution heated at 50° C., for example, is ejected from the shower head 941 to pour the plating solution over substantially the entire surface of the substrate W. Since the surface of the substrate W is surrounded by the dam member 931, the poured plating solution is all held on the surface of the substrate W. The amount of the supplied plating solution may be a small amount which will become a 1 mm thickness (about 30 ml) on the surface of the substrate W. The depth of the plating solution held on the surface to be plated may be 10 mm or less, and may be even 1 mm as in this embodiment. If a small amount of the supplied plating solution is sufficient, the heating apparatus for heating the plating solution may be of a small size.

If the substrate W itself is adapted to be heated, the temperature of the plating solution requiring great power consumption for heating need not be raised so high. This is preferred, because power consumption can be decreased, and a change in the property of the plating solution can be prevented. Power consumption for heating of the substrate W itself may be small, and the amount of the plating solution stored on the substrate W is also small. Thus, heat retention of the substrate W by the backside heater 915 can be performed easily, and the capacity of the backside heater 915 may be small, and the apparatus can be made compact. If means for directly cooling the substrate W itself is used, switching between heating and cooling may be performed during plating to change the plating conditions. Since the plating solution held on the substrate is in a small amount, temperature control can be performed with good sensitivity.

The substrate W is instantaneously rotated by the motor M to perform uniform liquid wetting of the surface to be plated, and then plating of the surface to be plated is performed in such a state that the substrate W is in a stationary state. Specifically, the substrate W is rotated at 100 rpm or less for only 1 second to uniformly wet the surface, to be plated, of the substrate W with the plating solution. Then, the substrate W is kept stationary, and electroless plating is performed for 1 minute. The instantaneous rotating time is 10 seconds or less at the longest.

After completion of the plating treatment, the front end of the plating solution recovery nozzle 965 is lowered to an area near the inside of the dam member 931 on the peripheral edge portion of the substrate W to suck in the plating solution. At this time, if the substrate W is rotated at a rotational speed of, for example, 100 rpm or less, the plating solution remaining on the substrate W can be gathered in the portion of the dam member 931 on the peripheral edge portion of the substrate W under centrifugal force, so that recovery of the plating solution can be performed with a good efficiency and a high recovery rate. The holding means 911 is lowered to separate the substrate W from the dam member 931. The substrate W is started to be rotated, and the cleaning liquid (ultrapure water) is jetted at the plated surface of the substrate W from the nozzle 953 of the cleaning liquid supply means 951 to cool the plated surface, and simultaneously perform dilution and cleaning, thereby stopping the electroless plating reaction. At this time, the cleaning liquid jetted from the nozzle 953 may be supplied to the dam member 931 to perform cleaning of the dam member 931 at the same time. The plating waste solution at this time is recovered into the recovery vessel 961 and discarded.

The plating solution once used is not reused, but thrown away. As described above, the amount of the plating solution used in this apparatus can be made very small, compared with that in the prior art. Thus, the amount of the plating solution which is discarded is small, even without reuse. In some cases, the plating solution recovery nozzle 965 may not be installed, and the plating solution which has been used may be recovered as a plating waste solution into the recovery vessel 961, together with the cleaning liquid.

Then, the substrate W is rotated at a high speed by the motor M for spin-drying, and then the substrate W is removed from the holding means 911.

FIG. 18 is a schematic constitution drawing of another electroless plating units 222a and 222b. The example of FIG. 18 is different from the aforementioned elecroless plating apparatus shown in FIG. 17 in that instead of providing the backside heater 915 in the holding means 911, lamp heaters 917 are disposed above the holding means 911, and the lamp heaters 917 and a shower head 941-2 are integrated. For example, a plurality of ring-shaped lamp heaters 917 having different radii are provided concentrically, and many nozzles 943-2 of the shower head 941-2 are open in a ring form from the gaps between the lamp heaters 917. The lamp heaters 917 may be composed of a single spiral lamp heater, or may be composed of other lamp heaters of various structures and arrangements.

Even with this constitution, the plating solution can be supplied from each nozzle 943-2 to the surface, to be plated, of the substrate W substantially uniformly in a shower form. Further, heating and heat retention of the substrate W can be performed by the lamp heaters 917 directly uniformly. The lamp heaters 917 heat not only the substrate W and the plating solution, but also ambient air, thus exhibiting a heat retention effect on the substrate W.

Direct heating of the substrate W by the lamp heaters 917 requires the lamp heaters 917 with relatively large power consumption. In place of such lamp heaters 917, lamp heaters 917 with relatively small power consumption and the backside heater 915 shown in FIG. 17 may be used in combination to heat the substrate W mainly with the backside heater 915 and to perform heat retention of the plating solution and ambient air mainly by the lamp heaters 917. In the same manner as in the aforementioned embodiment, means for directly or indirectly cooling the substrate W may be provided to perform temperature control.

According to the above-described substrate processing apparatus shown in FIG. 16, the copper film 7 (see FIG. 15B) deposited on the surface of the substrate W is polished away with the CMP units 210a, 210b. Instead of the CMP units 210a, 210b, an electrolytic processing unit may be employed for removing the copper film 7 or the like by electrolytic processing. The construction of the CMP unit 210a, 210b is the same as shown in FIG. 13, for example, and the description will be omitted.

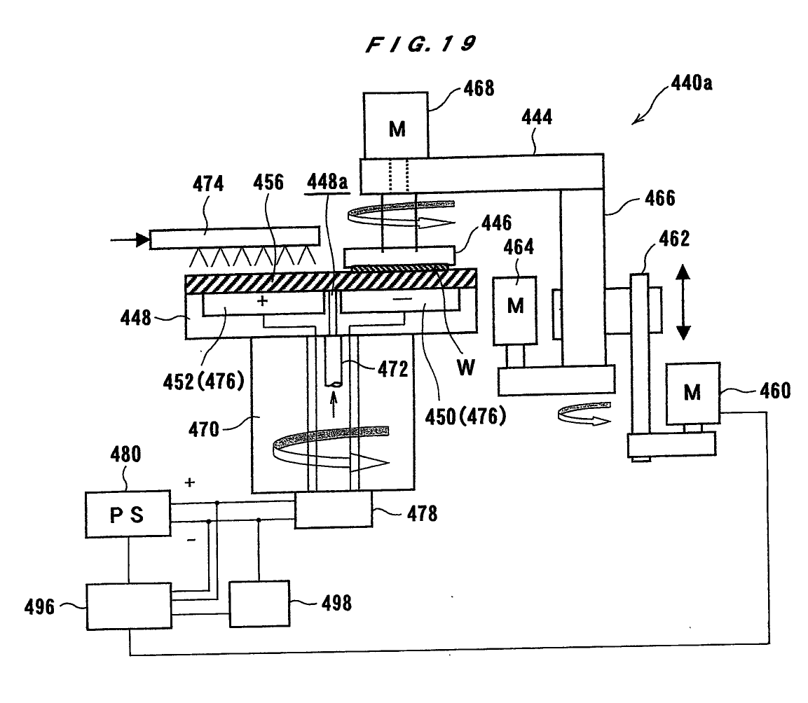

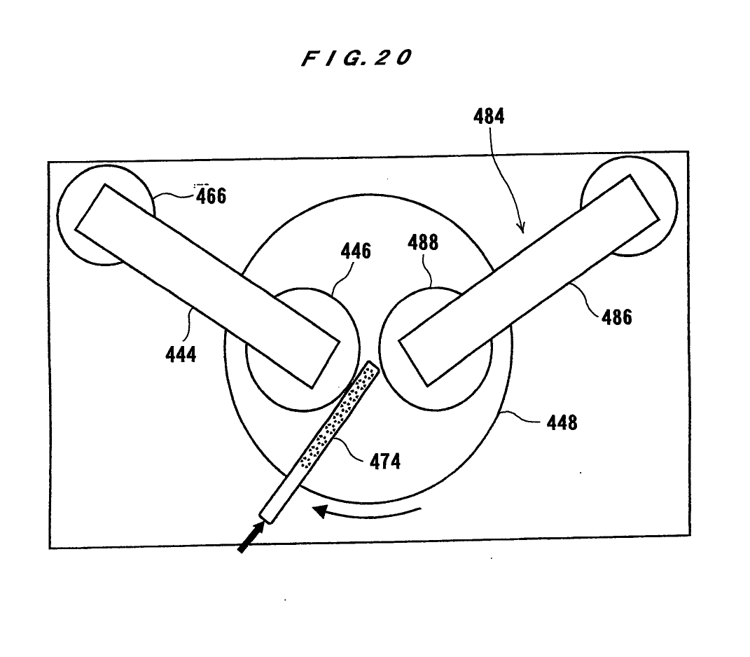

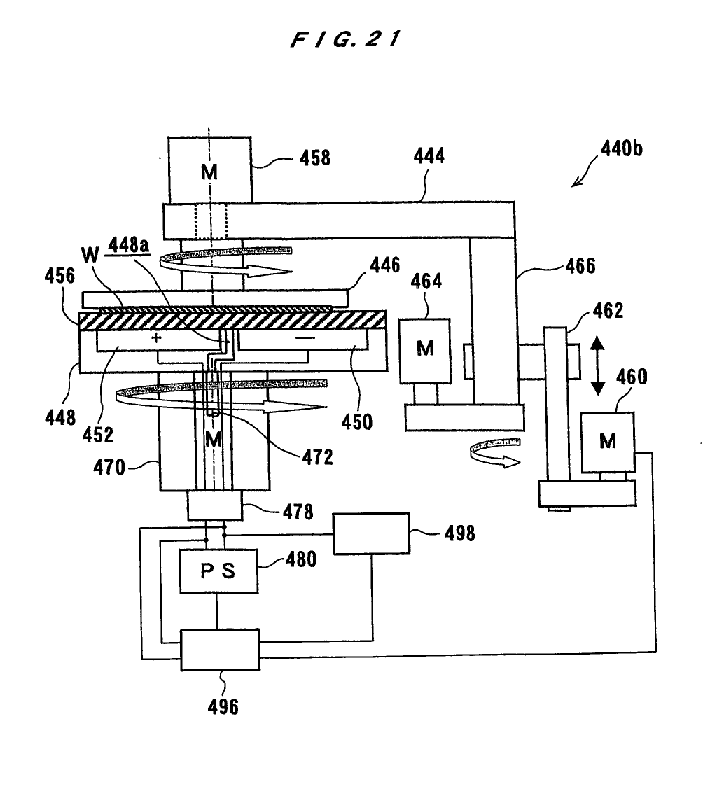

FIGS. 19 and 20 show an electrolytic processing unit. This electrolytic processing unit 440a includes a substrate holder 446, supported at the free end of a pivot arm 444 that can pivot horizontally, for attracting and holding the substrate W with its front surface facing downward (so-called “face-down” manner), and, positioned beneath the substrate holder 446, a disc-shaped electrode section 448 made of an insulating material. The electrode section 448 has, embedded therein, fan-shaped processing electrodes 450 and feeding electrodes 452 that are disposed alternately with their surfaces (upper faces) exposed. A ion exchanger 456 is mounted on the upper surface of the electrode section 448 so as to cover the surfaces of the processing electrodes 450 and the feeding electrodes 452.

This embodiment uses, merely as an example of the electrode section 448 having the processing electrodes 450 and the feeding electrodes 452, such one that has a diameter more than twice than that of the substrate W so that the entire surface of the substrate W may undergo electrolytic processing.

The pivot arm 444, which moves up and down via a ball screw 462 by the actuation of a motor 460 for vertical movement, is connected to the upper end of a pivot shaft 466 that rotates by the actuation of a pivot motor 464. The substrate holder 446 is connected to a rotation motor 468 that is mounted on the free end of the pivot arm 444, and is allowed to rotate by the actuation of the rotation motor 468.

The electrode section 448 is connected directly to a hollow motor 470, and is allowed to rotate by the actuation of the hollow motor 470. A through-hole 448a as a pure water supply section for supplying pure water, preferably ultrapure water, is formed in the central portion of the electrode section 448. The through-hole 448a is connected to a pure water supply pipe 472 that vertically extends inside the hollow motor 470. Pure water or ultrapure water is supplied through the through-hole 448a, and via the ion exchanger 456, is supplied to the entire processing surface of the substrate W. A plurality of through-holes 448a, each connected to the pure water supply pipe 472, may be provided to facilitate the processing liquid reaching over the entire processing surface of the substrate W.

Further, a pure water nozzle 474 as a pure water supply section for supplying pure water or ultrapure water, extending in the radial direction of the electrode section 448 and having a plurality of supply ports, is disposed above the electrode section 448. Pure water or ultrapure water is thus supplied to the surface of the substrate W from above and beneath the substrate W. Pure water herein refers to a water having an electric conductivity of not more than 10 μS/cm, and ultrapure water refers to a water having an electric conductivity of not more than 0.1 μS/cm. Instead of pure water, a liquid having an electric conductivity of not more than 500 μS/cm or any electrolytic solution may be used. By supplying electrolytic solution during processing, the instability factors of processing, such as process products and dissolved gases, can be removed, and processing can be effected uniformly with good reproducibility.

According to this embodiment, a plurality of fan-shaped electrode plates 476 are disposed in the electrode section 448 in the circumference direction, and the cathode and anode of a power source 480 are alternately connected, via a slip ring 478, to the electrode plates 476. The electrode plates 476 connected to the cathode of the power source 480 become the processing electrodes 450 and the electrode plates 476 connected to the anode of the power source 480 become the feeding electrodes 452. This applies to processing of e.g. copper, because electrolytic processing of copper proceeds on the cathode side. Depending upon a material to be processed, the cathode side can be a feeding electrode and the anode side can be a processing electrode. More specifically, when the material to be processed is copper, molybdenum, iron or the like, electrolytic processing proceeds on the cathode side, and therefore the electrode plates 476 connected to the cathode of the power source 480 should be the processing electrodes 450 and the electrode plates 476 connected to the anode should be the feeding electrodes 452. In the case of aluminum, silicon or the like, on the other hand, electrolytic processing proceeds on the anode side. Accordingly, the electrode plates connected to the anode of the power source should be the processing electrodes and the electrode plates connected to the cathode should be the feeding electrodes.

By thus disposing the processing electrodes 450 and the feeding electrodes 452 separately and alternately in the circumferential direction of the electrode section 448, fixed feeding portions to supply electricity to a conductive film (portion to be processed) of the substrate is not needed, and processing can be effected to the entire surface of the substrate.

The electrolytic processing unit 440a is provided with a controller 496 that controls the power source 480 so as to allow the power source 480 to arbitrarily control at least one of the voltage and the electric current supplied from the power source 480 to between the processing electrodes 450 and the feeding electrodes 452. The electrolytic processing unit 440a is also provided with an electricity amount integrator (coulomb meter) 498 which is connected to a wire extending from the cathode of the power source 480 to detect the current value, determines the amount of electricity by the product of the current value and the processing time, and integrates the amount of electricity to thereby determine the total amount of electricity used. An output signal from the electricity amount integrator 498 is inputted to the controller 496, and an output signal from the controller 496 is inputted to the power source 480.

Further, as shown in FIG. 20, a regeneration section 484 for regenerating the ion exchanger 456 is provided. The regeneration section 484 comprises a pivot arm 486 having a structure substantially similar to the pivot arm 444 that holds the substrate holder 446 and positioned at the opposite side to the pivot arm 444 across the electrode section 448, and a regeneration head 488 held by the pivot arm 486 at the free end thereof. In operation, the reverse electric potential to that for processing is given to the ion exchanger 456 from the power source 480 (see FIG. 19), thereby promoting dissolution of extraneous matter such as copper adhering to the ion exchanger 456. The regeneration of the ion exchanger 456 during processing can thus be effected. The regenerated ion exchanger 456 is rinsed by pure water or ultrapure water supplied to the upper surface of the electrode section 448.

Next, electrolytic processing by the electrolytic processing unit 440a will be described.

First, a substrate W, e.g. a substrate W as shown in FIG. 15B which has in its surface a copper film 7 as a conductor film (portion to be processed), is attracted and held by the substrate holder 446 of the electrolytic processing unit 440a, and the substrate holder 446 is moved by the pivot arm 444 to a processing position right above the electrode section 448. The substrate holder 446 is then lowered by the actuation of the motor 460 for vertical movement, so that the substrate W held by the substrate holder 446 contacts or gets close to the surface of the ion exchanger 456 mounted on the upper surface of the electrode section 448.

Next, a given voltage or electric current is applied from the power source 480 between the processing electrodes 450 and the feeding electrodes 452, while the substrate holder 446 and the electrode section 448 are rotated. At the same time, pure water or ultrapure water is supplied, through the through-hole 448a, from beneath the electrode section 448 to the upper surface thereof, and simultaneously, pure water or ultrapure water is supplied, through the pure water nozzle 474, from above the electrode section 448 to the upper surface thereof, thereby filling pure water or ultrapure water into the space between the processing electrodes 450, the feeding electrodes 452 and the substrate W. Thereby, electrolytic processing of the conductor film (copper film 7) formed on the substrate W is effected by hydrogen ions or hydroxide ions produced in the ion exchanger 456. According to the above electrolytic processing unit 440a, a large amount of hydrogen ions or hydroxide ions can be produced by allowing pure water or ultrapure water to flow within the ion exchanger 456, and the large amount of such ions can be supplied to the surface of the substrate W, whereby the electrolytic processing can be conducted efficiently.

More specifically, by allowing pure water or ultrapure water to flow within the ion exchanger 456, a sufficient amount of water can be supplied to a functional group (sulfonic acid group in the case of an ion exchanger carrying a strongly acidic cation-exchange group) thereby to increase the amount of dissociated water molecules, and the process product (including a gas) formed by the reaction between the conductor film (copper film 7) and hydroxide ions (or OH radicals) can be removed by the flow of water, whereby the processing efficiency can be enhanced. The flow of pure water or ultrapure water is thus necessary, and the flow of water should desirably be constant and uniform. The constancy and uniformity of the flow of water leads to constancy and uniformity in the supply of ions and the removal of the process product, which in turn leads to constancy and uniformity in the processing.

After completion of the electrolytic processing, the power source 480 is disconnected from the processing electrodes 450 and feeding electrodes 452, the rotations of the substrate holder 446 and of the electrode section 448 are stopped. Thereafter, the substrate holder 446 is raised, and processed substrate W is transferred to next process.

In this embodiment, pure water or ultrapure water is supplied to between the electrode section 448 and the substrate W. It is also possible to use, instead of pure water or ultrapure water, a liquid obtained by adding a surfactant or the like to pure water or ultrapure water, and having an electric conductivity of not more than 500 μS/cm, preferably not more than 50 μS/cm, more preferably not more than 0.1 μS/cm (resistivity of not less than 10 MΩ cm), as described above.

According to the embodiment, the processing rate can be considerably enhanced by interposing the ion exchanger 456 between the substrate W and the processing electrodes 450, the feeding electrodes 452. In this regard, electrochemical processing using ultrapure water is effected by a chemical interaction between hydroxide ions in ultrapure water and a material to be processed. However, the amount of the hydroxide ions acting as reactant in ultrapure water is as small as 10⁻⁷ mol/L under normal temperature and pressure conditions, so that the removal processing efficiency can decrease due to reactions (such as an oxide film-forming reaction) other than the reaction for removal processing. It is therefore necessary to increase hydroxide ions in order to conduct removal processing efficiently. A method for increasing hydroxide ions is to promote the dissociation reaction of ultrapure water by using a catalytic material, and an ion exchanger can be effectively used as such a catalytic material. More specifically, the activation energy relating to water-molecule dissociation reaction is lowered by the interaction between functional groups in an ion exchanger and water molecules, whereby the dissociation of water is promoted to thereby enhance the processing rate.

Further, according to this embodiment, the ion exchanger 456 is brought into contact with or close to the substrate W upon electrolytic processing. When the ion exchanger 456 is positioned close to the substrate W, though depending on the distance therebetween, the electric resistance is large to some degree and, therefore, a somewhat large voltage is necessary to provide a requisite electric current density. However, on the other hand, because of the non-contact relation, it is easy to form flow of pure water or ultrapure water along the surface of the substrate W, whereby the reaction product produced on the substrate surface can be efficiently removed. In the case where the ion exchanger 456 is brought into contact with the substrate W, the electric resistance becomes very small and therefore only a small voltage needs to be applied, whereby the power consumption can be reduced.

If a voltage is raised to increase the current density in order to enhance the processing rate, an electric discharge can occur when the electric resistance between the electrode and the substrate (workpiece to be processed) is large. The occurrence of electric discharge causes pitching on the surface of the substrate, thus failing to form an even and flat processed surface. To the contrary, since the electric resistance is very small when the ion exchanger 456 is in contact with the substrate W, the occurrence of an electric discharge can be avoided.

When electrolytic processing of copper is conducted by using, as the ion exchanger 456, an ion exchanger having a cation-exchange group, the ion-exchange group of the ion exchanger (cation exchanger) 456 is saturated with copper after the processing, whereby the processing efficiency of the next processing is lowered. When electrolytic processing of copper is conducted by using, as the ion exchanger 456, an ion exchanger having an anion-exchange group, fine particles of a copper oxide can be produced and adhere to the surface of the ion exchanger (anion exchanger) 456, whereby the processing speed is effected to thereby harm the uniformity of the processing speed of the surface of the substrate to be processed, and particles can contaminate the surface of a next substrate to be processed.

In operation, in order to obviate such drawbacks, the reverse electric potential to that for processing is given to the ion exchanger 456 from the power source 480, thereby promoting dissolution of extraneous matter such as copper adhering to the ion exchanger 456 via regeneration head 488. The regeneration of the ion exchanger 456 during processing can thus be effected. The regenerated ion exchanger 456 is rinsed by pure water or ultrapure water supplied to the upper surface of the electrode section 448.

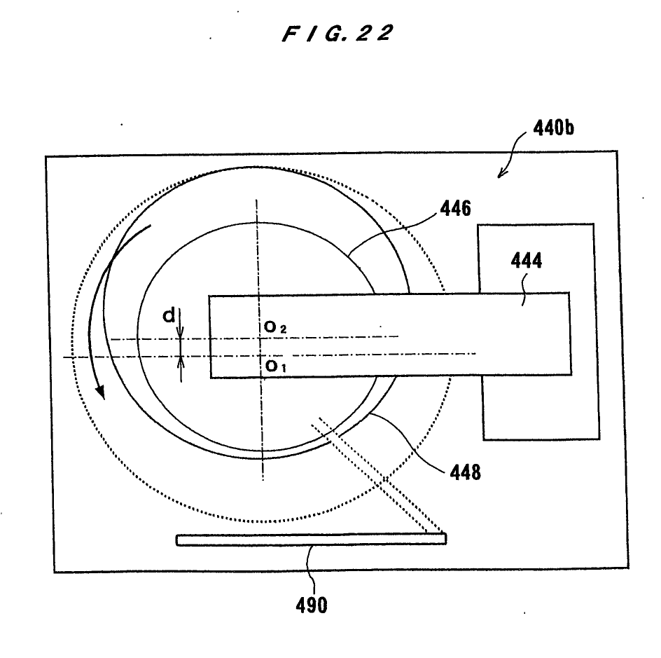

FIGS. 21 and 22 show another electrolytic processing unit 440b. In this electrolytic processing unit 440b, the rotational center O₁ of the electrode section 448 is distant from the rotational center O₂ of the substrate holder 446 by a distance d; and the electrode section 448 rotates about the rotational center O₁ and the substrate holder 446 rotates about the rotational center O₂. Further, the processing electrodes 450 and the feeding electrodes 452 are connected electrically to the power source 480 via the slip ring 478. Further according to this example, the electrode section 448 is designed to have a diameter which is larger than the diameter of the substrate holder 446 to such a degree that when the electrode section 448 rotates about the rotational center O₁ and the substrate holder rotates about the rotational center O₂, the electrode section 448 covers the entire surface of the substrate W held by the substrate holder 446.

According to the electrolytic processing unit 440b, electrolytic processing of the surface of the substrate W is carried out by rotating the substrate W via the substrate holder 446 and, at the same, rotating the electrode section 448 by the actuation of the hollow motor 470, while supplying pure water or ultrapure water to the upper surface of the electrode section 448 and applying a given voltage between the processing electrodes 450 and the feeding electrodes 452.

The electrode section 448 or substrate holder 446 may be made orbit movement such as scroll movement or reciprocation instead of rotation.

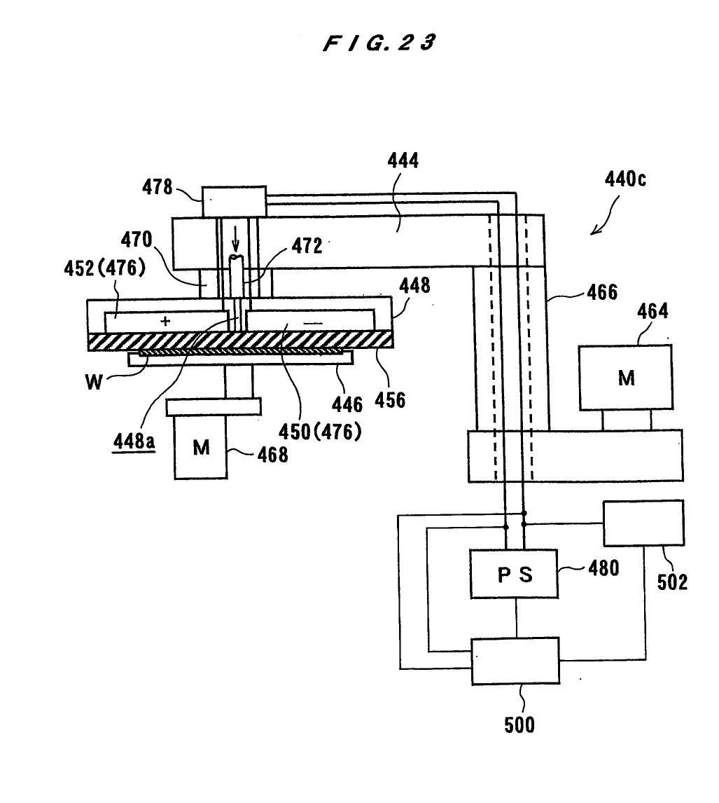

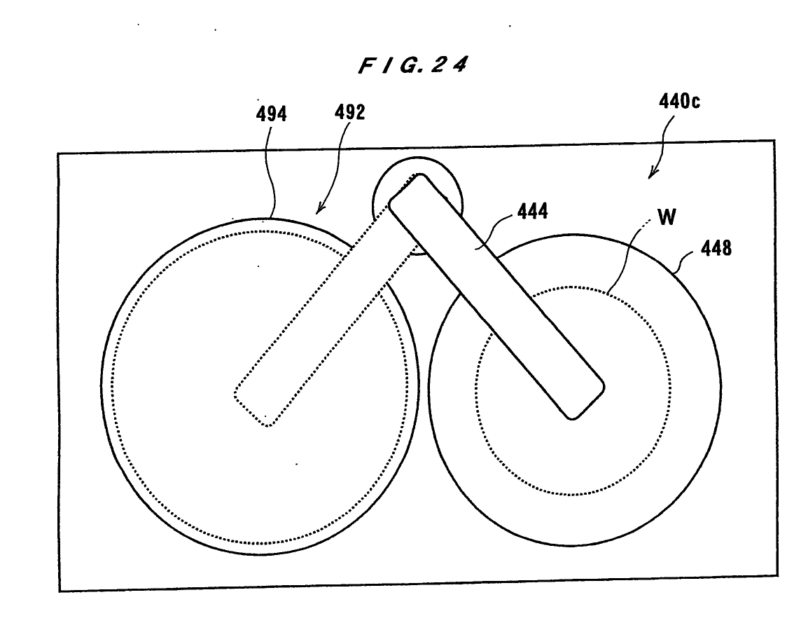

FIGS. 23 and 24 show still another electrolytic processing unit 440c. In this electrolytic processing unit 440c, the positional relationship between the substrate holder 446 and the electrode section 448 in the preceding example, shown in FIGS. 21 and 22, is reversed, and the substrate W is held with its front surface facing upward (so-called “face-up” manner) so that electrolytic processing is conducted to the surface (upper surface) of the substrate. Thus, the substrate holder 446 is disposed beneath the electrode section 448, holds the substrate W with its front surface facing upward, and rotates about its own axis by the actuation of the motor 468 for rotation. On the other hand, the electrode section 448, which has the processing electrodes 450 and the feeding electrodes 452 that are covered with the ion exchanger 456 is disposed above the substrate holder 446, is held with its front surface facing downward by the pivot arm 444 at the free end thereof, and rotates about its own axis by the actuation of the hollow motor 470. Further, wires extending from the power source 480 pass through a hollow portion formed in the pivot shaft 466 and reach the slip ring 478, and further pass through the hollow portion of the hollow motor 470 and reach the processing electrodes 450 and the feeding electrodes 452 to apply a voltage therebetween.

Pure water or ultrapure water is supplied from the pure water supply pipe 472, via the through-hole 448a formed in the central portion of the electrode section 448, to the front surface (upper surface) of the substrate W from above the substrate W.

A regeneration section 492 for regenerating the ion exchanger 456 mounted on the electrode section 448 is disposed beside the substrate holder 446. The regeneration section 492 includes a regeneration tank 494 filled with e.g. a dilute acid solution. In operation, the electrode section 448 is moved by the pivot arm 444 to a position right above the regeneration tank 494, and is then lowered so that at least the ion exchanger 456 of the electrode section 448 is immersed in the acid solution in the regeneration tank 494. Thereafter, the reverse electric potential to that for processing is given to the electrode plates 476, i.e. by connecting the processing electrodes 450 to the anode of the power source 480 and connecting the feeding electrodes 452 to the cathode of the power source 480, thereby promoting dissolution of extraneous matter such as copper adhering to the ion exchanger 456 to thereby regenerate the ion exchanger 456. The regenerated ion exchanger 456 is rinsed by e.g. ultrapure water.

Further according to this embodiment, the electrode section 448 is designed to have a sufficiently larger diameter than that of the substrate W held by the substrate holder 446. Electrolytic processing of the surface of the substrate W is conducted by lowering the electrode section 448 so that the ion exchanger 456 contacts or gets close to the substrate W held by the substrate holder 446, then rotating the substrate holder 446 and the electrode section 448 and, at the same time, pivoting the pivot arm 444 to move the electrode section 448 along the upper surface of the substrate W, while supplying pure water or ultrapure water to the upper surface of the substrate and applying a given voltage between the processing electrodes 450 and the feeding electrodes 452.

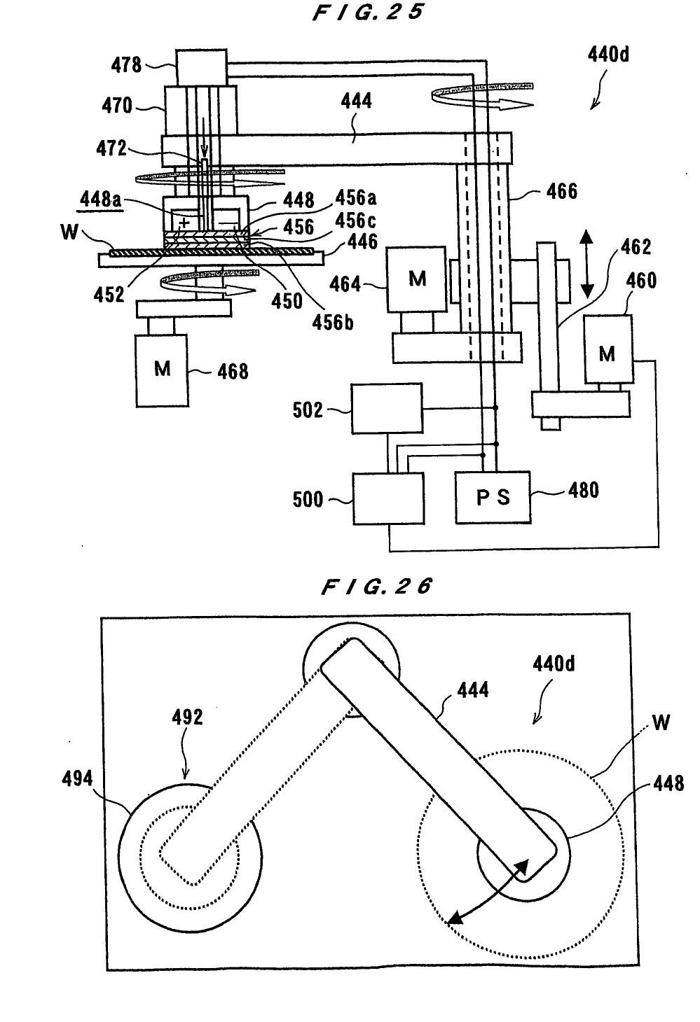

FIGS. 25 and 26 show still another electrolytic processing unit 440d. This electrolytic processing unit 440d employs, as the electrode section 448, such one that has a sufficiently smaller diameter than that of the substrate W held by the substrate holder 446 so that the surface of the substrate W may not be entirely covered with the electrode section 448. In this example, the ion exchanger 456 is of a three-layer structure (lamination) consisting of a pair of strongly acidic cation-exchange fibers 456a, 456b and a strongly acidic cation-exchange membrane 456c interposed between the strongly acidic cation-exchange fibers 456a, 456b. The ion exchanger (lamination) 456 has a good water permeability and a high hardness and, in addition, the exposed surface (lower surface) to be opposed to the substrate W has a good smoothness. Other construction is the same as shown in FIGS. 23 and 24.

By making the ion exchanger 456 a multi-layer structure consisting of laminated layers of ion-exchange materials, such as a nonwoven fabric, a woven fabric and a porous membrane, it is possible to increase the total ion exchange capacity of the ion exchanger 456, whereby formation of an oxide, for example, in removal (polishing) processing of copper, can be restrained to thereby avoid the oxide adversely affecting the processing rate. In this regard, when the total ion exchange capacity of an ion exchanger 456 is smaller than the amount of copper ions taken in the ion exchanger 456 during removal processing, the oxide should inevitably be formed on the surface or in the inside of the ion exchanger 456, which adversely affects the processing rate. Thus, the formation of the oxide is governed by the ion exchange capacity of an ion exchanger, and copper ions exceeding the capacity should become the oxide. The formation of an oxide can thus be effectively restrained by using, as the ion exchanger 456, a multi-layer ion exchanger composed of laminated layers of ion-exchange materials which has enhanced total ion exchange capacity.

As described hereinabove, according to the substrate processing method illustrated in FIGS. 15A through 15F, when the protective film is formed selectively in the recesses for filling to protect the surface of the interconnects, the surface of the protective film can be made flush with the surface of a non-interconnect area, e.g. an insulating film. This can prevent protrusion of the protective film from the flattened surface, thereby securing a sufficient surface flatness of an insulating film, etc. that is later deposited on the substrate surface. Thus, a process of polishing the surface of the insulating film, etc. can be eliminated, leading to lowering of the semiconductor device production cost.

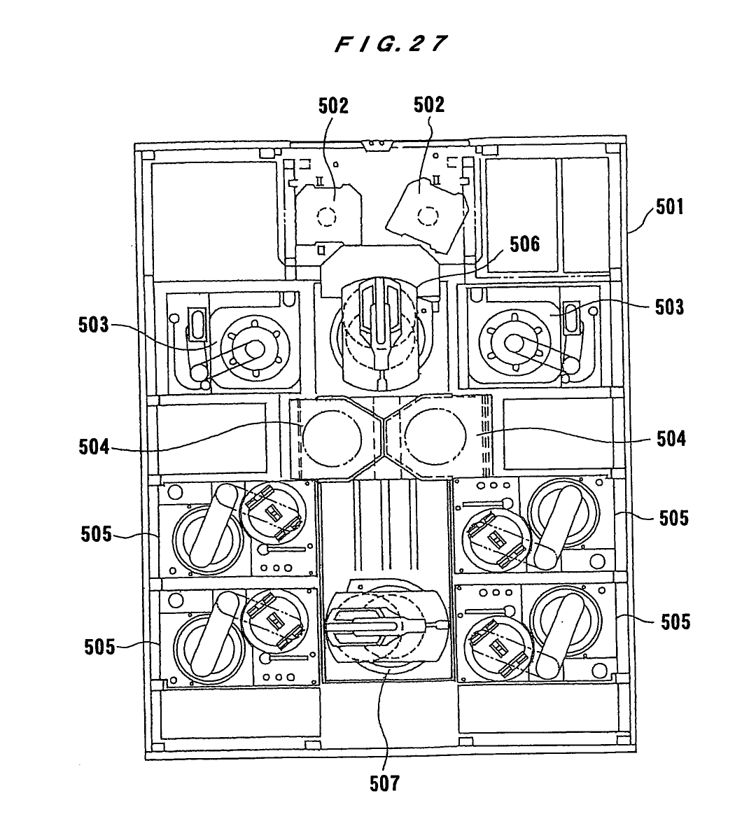

FIG. 27 is a plan view schematically showing the construction of a substrate processing apparatus according to another embodiment of the present invention. As shown in FIG. 27, the substrate processing apparatus is housed in a rectangular housing 501. Plating and electrolytic processing of a substrate are carried out successively within the housing 501. The substrate processing apparatus includes a pair of loading/unloading units 502 for carrying in and out a cassette housing a plurality of substrates, a pair of bevel-etching/cleaning units 503 for cleaning the substrate with a chemical liquid, a pair of substrate stages 504 for placing and holding the substrate thereon and reversing the substrate, and four substrate processing units 505 for carrying out plating and electrolytic processing of the substrate. Further, a first transfer robot 506 for transferring the substrate between the loading/unloading units 502, the bevel-etching/cleaning units 503 and the substrate stages 504, and a second transfer robot 507 for transferring the substrate between the substrate stages 504 and the substrate processing units 505 are disposed in the housing 501.

The substrate is housed, with its front surface (device surface, to-be-processed surface) facing upward, in a cassette that is placed on the loading/unloading unit 502. The first transfer robot 506 takes the substrate out of the cassette, and transfers the substrate to the substrate stage 504 and places the substrate on the substrate stage 504. The substrate is reversed by the reversing machine of the substrate stage 504 so that the front surface faces downward, and is then taken by the second transfer robot 507. The substrate W is placed and held at its peripheral portion on the hand of the second transport robot 507 so that the surface of the substrate does not touch the hand. The second transfer robot 507 transfers the substrate to the below-described head section 541 of the substrate processing unit 505, and the substrate is subjected to plating and electrolytic processing in the substrate processing unit 505.

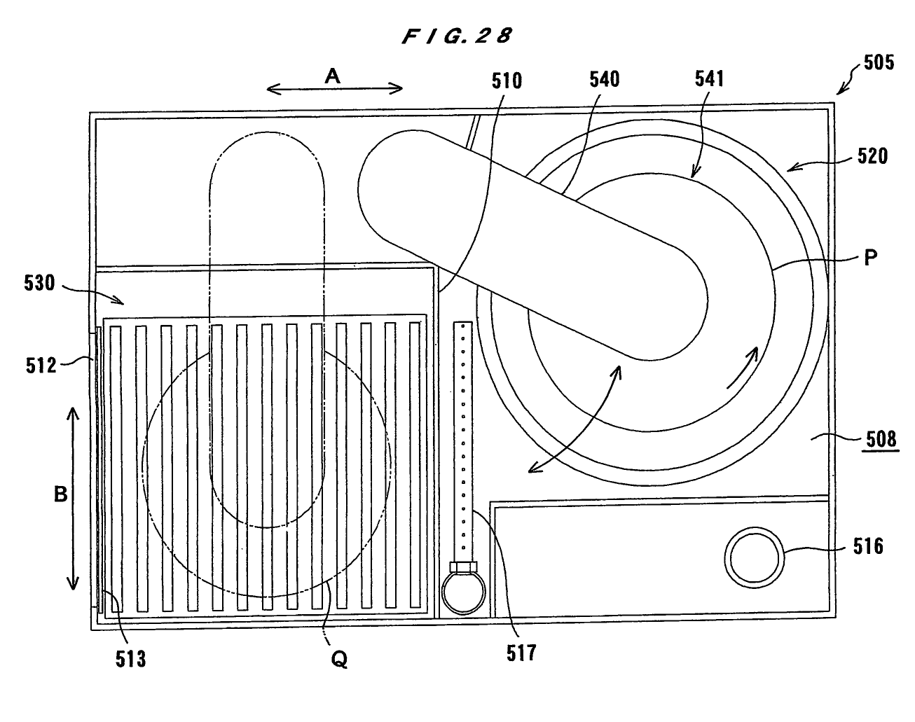

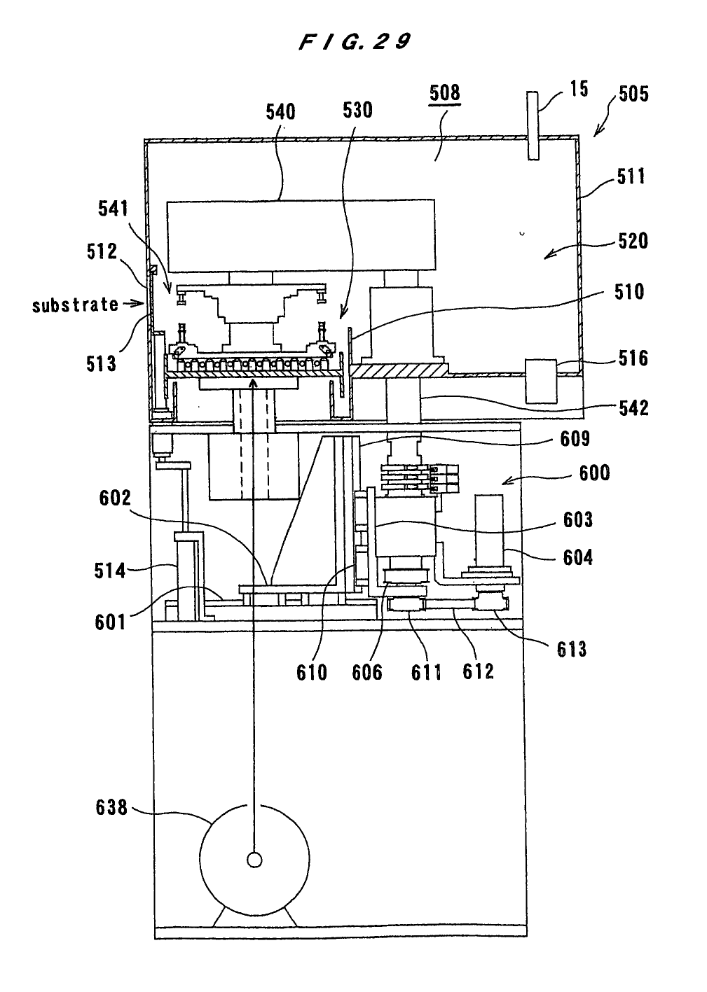

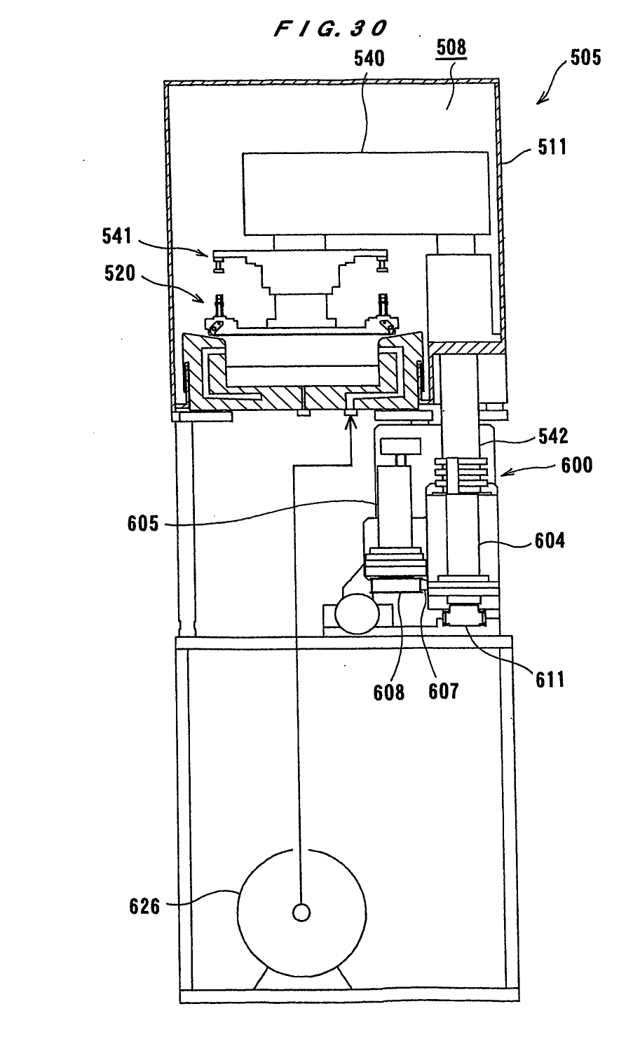

The substrate processing unit 505, installed in the substrate processing apparatus of this embodiment, will now be described in detail. FIG. 28 is a plan view of the substrate processing unit 505, FIG. 29 is a vertical sectional front view of FIG. 28, and FIG. 30 is a vertical sectional side view of FIG. 28. As shown in FIGS. 28 and 29, the substrate processing unit 505 is divided by a partition wall 510 into two substrate processing sections, i.e. a plating section 520 for carrying out plating of the substrate and an electrolytic processing section 530 for carrying out electrolytic processing of the substrate. The plating section 520 and the electrolytic processing section 530 are enveloped in a cover 511, defining a processing space 508. As shown in FIGS. 28 and 29, an opening 512 for carrying in and out the substrate is formed in the sidewall on the electrolytic processing section 530 side of the cover 511, and the opening 512 is provided with an openable/closable shutter 513. The shutter 513 is connected to a shutter opening/closing air cylinder 514. By the actuation of the shutter opening/closing air cylinder 514, the shutter 513 moves up and down so as to open and close the opening 512. By thus hermetically closing the processing space 508 of the substrate processing unit 505, housing the plating section 520 and the electrolytic processing section 530, with the cover 511 and the shutter 513, a mist or the like generated in the plating is prevented from scattering out of the processing space 508 of the substrate processing unit 505.

Further, as shown in FIG. 29, an inert gas (purging gas) supply port 515 is provided in the upper portion of the cover 511, and an inert gas (purging gas), such as N₂ gas, is supplied from the inert gas supply port 515 into the processing space 508. A cylindrical ventilation duct 516 is provided at the bottom of the cover 511, and the gas in the processing space 508 is discharged out through the ventilation duct 516.

As shown in FIG. 28, an arm-shaped cleaning nozzle 517, as a cleaning section for cleaning the substrate that has been plated in the plating section 520, is disposed between the plating section 520 and the electrolytic section 530 in the processing space 508. The cleaning nozzle 517 is connected to a not-shown cleaning liquid supply source, and a cleaning liquid (e.g. pure water) is jetted from the cleaning nozzle 517 toward the lower surface of the substrate W. The cleaning nozzle 517 is rotatable, and carries out cleaning of the substrate after plating or electrolytic processing as necessary.

As shown in FIGS. 28 through 30, a pivot arm 540, which is pivotable between the plating section 520 and the electrolytic processing section 530, is installed in the substrate processing unit 505. A head section 541 for holding the substrate is mounted vertically to the free end side of the pivot arm 540. By pivoting the pivot arm 540, as shown in FIG. 28, the head section 541 can be moved between a plating position P at which plating of the substrate is carried out in the plating section 520 and an electrolytic processing position Q at which electrolytic processing of the substrate is carried out in the electrolytic processing section 530. The movement of the head section 541 between the plating position P and the electrolytic processing position Q may not be effected solely by the pivoting of the pivot arm 540. Thus, the movement of the head section 541 may also be effected by, for example, translating of the head section 541.

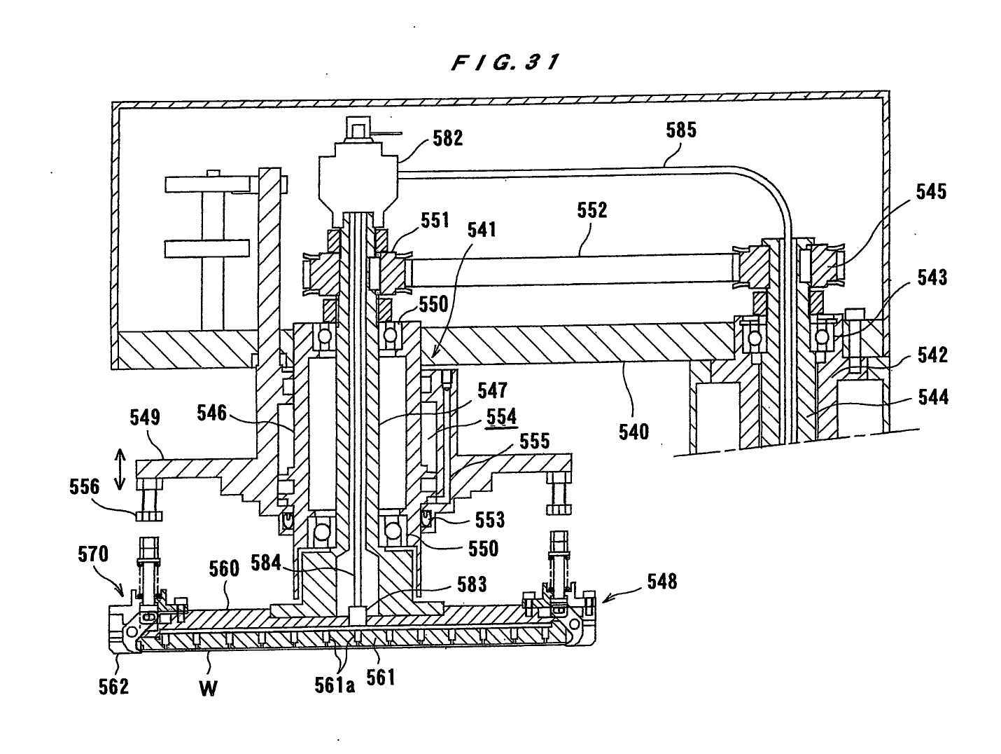

FIG. 31 is a vertical sectional view showing the main portion of the pivot arm 540 and the head section 541. As shown in FIG. 31, the pivot arm 540 is fixed on the upper end of a rotatable hollow support post 542, and pivots horizontally by the rotation of the support post 542. A rotating shaft 544, which is supported by a bearing 543, passes through the hollow portion of the support post 542 and is rotatable relative to the support post 542. Further, a driving pulley 545 is mounted to the upper end of the rotating shaft 544.

The head section 541 is coupled to the pivot arm 540 and, as shown in FIG. 31, is comprised mainly of an outer casing 546 fixed to the pivot arm 540, a rotating shaft 547 vertically penetrating the outer casing 546, a substrate holder 548 for holding the substrate W on its lower surface, and a movable member 549 that is vertically movable relative to the outer casing 546. The substrate holder 548 is coupled to the lower end of the rotating shaft 547.

The rotating shaft 547 is supported by a bearing 550, and is rotatable relative to the outer casing 546. A driven pulley 551 is mounted to the upper portion of the rotating shaft 547, and a timing belt 552 is stretched between the above-described driving pulley 545 and the driven pulley 551. Thus, the rotating shaft 547 rotates with the rotation of the rotating shaft 544 in the support post 542, and the substrate holder 548 rotates together with the rotating shaft 547.

A hermetically sealed space 554 is formed with a sealing material 553 between the movable member 549 and the outer casing 546, and an air supply passage 555 communicates with the hermetically sealed space 554. By supplying and discharging air through the air supply passage 555 into and out of the hermetically sealed space 554, the movable member 549 can be moved vertically relative to the outer casing 546. Further, downwardly extending pressure rods 556 are provided at the periphery of the movable member 549.

As shown in FIG. 31, the substrate holder 548 includes a flange portion 560 coupled to the lower end of the rotating shaft 547, an attracting plate 561 for attracting the substrate W onto the lower surface of the attracting plate 561 by vacuum attraction, and a guide ring 562 that surrounds the circumference of the attracting plate 561. The attracting plate 561 is formed of e.g. a ceramic or a reinforced resin, and a plurality of suction holes 561a are formed in the attracting plate 561.

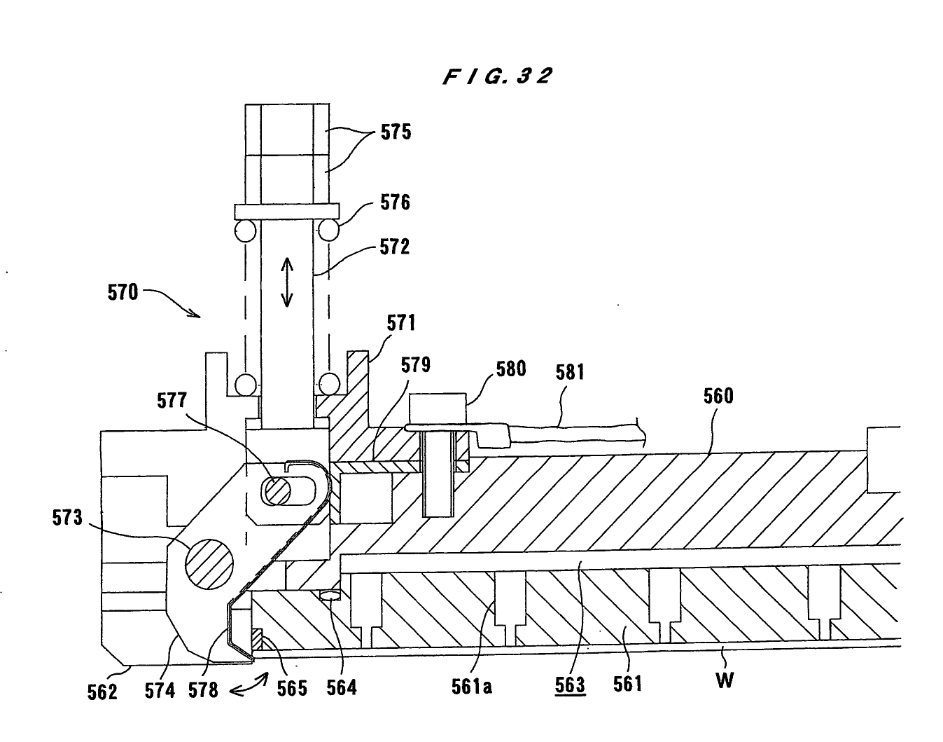

FIG. 32 is an enlarged view of a portion of FIG. 31. As shown in FIG. 32, a space 563, communicating with the suction holes 561a of the attracting plate 561, is formed between the flange portion 560 and the attracting plate 561. An O-ring 564 is disposed between the flange portion 560 and the attracting plate 561. The space 563 is hermetically sealed with the O-ring 564. Further, a soft seal ring 565 is disposed in the circumferential surface of the attracting plate 561, i.e., between the attracting plate 561 and the guide ring 562. The seal ring 565 contacts the peripheral portion of the back surface of the substrate W when it is attracted and held on the attracting plate 561.

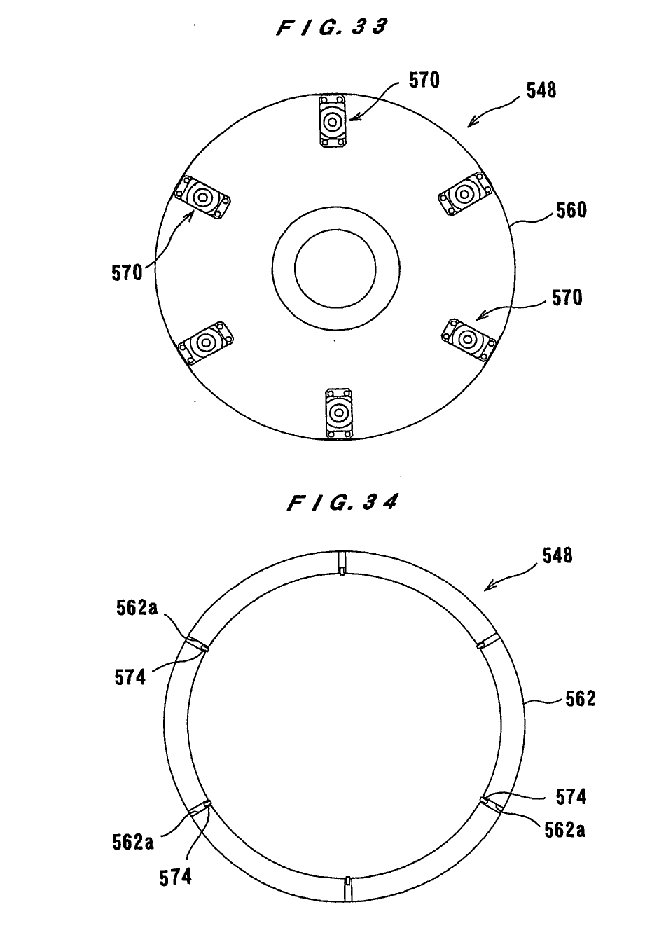

FIG. 33 is a plan view of the substrate holder 548. As shown in FIGS. 32 and 33, six chuck mechanisms 570 are provided in the substrate holder 548 at regular intervals in the circumferential direction. As shown in FIG. 32, each chuck mechanism 570 includes a pedestal 571 mounted on the upper surface of the flange portion 560, a vertically movable rod 572, and a feeding contact member 574 which is rotatable about a support shaft 573. A nut 575 is mounted on the upper end of the rod 572, and a helical compression spring 576 is interposed between the nut 575 and the pedestal 571.

As shown in FIG. 32, the feeding contact member 574 and the rod 572 are coupled via a horizontally movable pin 577. The feeding contact member 574 is so designed that as the rod 572 moves upward, the feeding contact member 574 rotates about the support shaft 573 and closes inwardly, while as the rod 572 moves downwardly, the feeding contact member 574 rotates about the support shaft 573 and opens outwardly. Thus, when the movable member 549 (see FIG. 31) is moved downwardly so that the pressure rods 556 contact the nuts 575 and press the rods 572 downwardly, the rods 572 move downwardly against the pressing force of the helical compression springs 576, whereby the feeding contact members 574 rotate about the supports 573 and opens outwardly. On the other hand, when the movable members 549 are moved upwardly, the rods 572 move up by the elastic force of the helical compression springs 576, whereby the feeding contact members 574 rotate about the support shafts 573 and close inwardly. By the chuck mechanisms 570 provided at six locations, the substrate W is positioned and held at its peripheral portions by the feeding contact members, and is held stably on the lower surface of the substrate holder 548.

FIG. 34 is a bottom plan view of the substrate holder 548. As shown in FIG. 34, radially extending grooves 562a are formed in the lower surface of the guide ring 562 at the locations where the feeding contact members 574 are mounted. Upon the opening and closing of the feeding contact members 574, the feeding contact members 574 move in the grooves 562a of the guide ring 562.

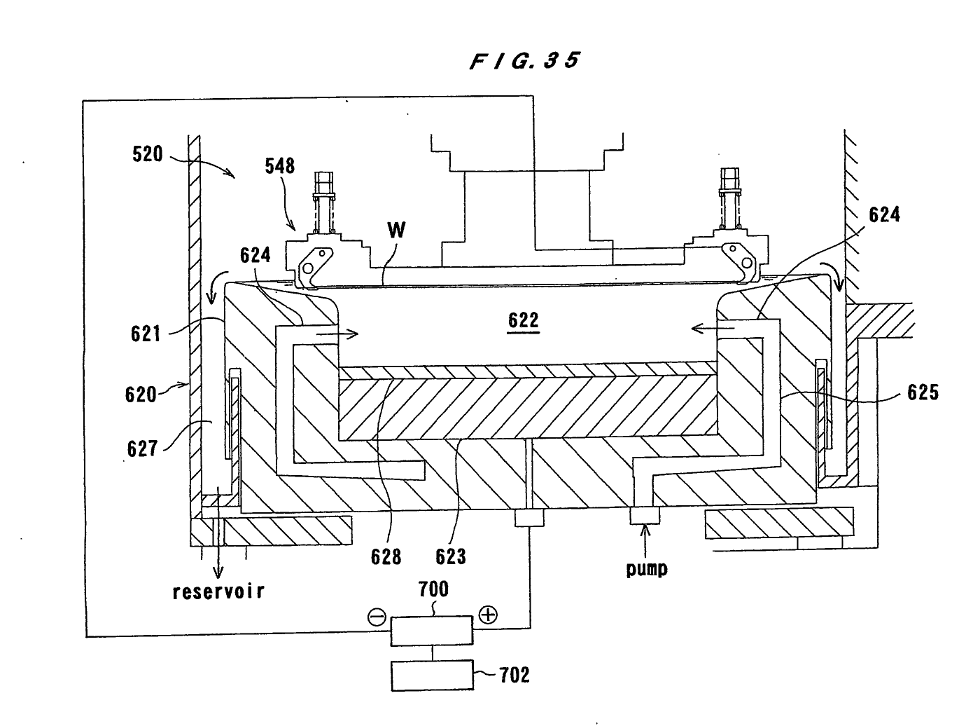

As shown in FIG. 32, a conductive feeding member 578 is mounted on the inner surface of each feeding contact member 574. The feeding members 578 contact conductive feeding plates 579. The feeding plates 579 are electrically connected to power cables 581 via bolts 580, and the power cables 581 are connected to a power source 702 (see FIG. 35). When the feeding contact members 574 close inwardly and hold peripheral portions of the substrate W, the feeding members 578 of the feeding contact members 574 contact the peripheral portions of the substrate W and feed electricity to the copper film 7 (see FIGS. 1B and 15B) of the substrate W. It is preferred that the feeding members 578 be formed of a metal which is noble to the metal to be processed on the substrate W.

As shown in FIG. 31, a rotary joint 582 is provided at the upper end of each rotating shaft 547, and a tube 584, extending from a connector 583 provided in the substrate holder 548, is connected via the rotary joint 582 to a tube 585 extending from the power source 702 and from a vacuum pump (not shown) in the apparatus. The above-described power cables 581 are housed in the tubes 584, 585 so that the feeding members 578 of the feeding contact members 574 are electrically connected to the power source 702 in the apparatus. Further, a pipe, communicating with each space 563 for substrate attraction, is also housed in the tubes 584, 585 so that by the actuation of the vacuum pump, the substrate W can be attracted onto the lower surface of the attracting plate 561.

A driving device for effecting the vertical and horizontal movements, pivoting movement, and rotation of the head section 541 will now be described with reference to FIGS. 29 and 30. The driving device 600 is disposed outside of the processing space 508, defined by the cover 511, of the substrate processing unit 505. Accordingly, particles, etc. from the driving device 600 are prevented from entering into the plating section 520, etc. Further, the influence of a mist, etc., generated in the plating, on the driving device 600 can be reduced, whereby the durability of the driving device 600 can be improved.

The driving device 600 is basically comprised of a rail 601 provided in the frame of the substrate processing unit 505, a sliding base 602 provided on the rail 601, and an elevating base 603 mounted to the sliding base 602 and vertically movable relative to the sliding base 602. The above-described support post 542 is rotatably supported on the elevating base 603. Accordingly, as the elevating base 603 slides on the rail 601, the head section 541 moves horizontally (in the A direction shown in FIG. 28). The elevating base 603 is provided with a rotating motor 604 and a pivoting motor 605, and the sliding base 602 is provided with an elevating motor (not shown).

A driven pulley 606 is mounted to the lower end of the support post 542 which is supported on the elevating base 603, and rotates together with the support post 542. A timing belt 607 is stretched between the driven pulley 606 and a driving pulley 608 which is mounted to the shaft of the pivoting motor 605. Thus, the support post 542 is rotated by the actuation of the pivoting motor 605, whereby the arm 540 fixed to the support post 542 is pivoted.

The elevating base 603 is provided with a slider 610 which is guided vertically by a slider support 609 provided in the sliding base 602. While the slider 610 of the elevating base 603 is thus guided by the slider support 609 of the sliding base 602, the elevating base 603 is moved vertically by a not-showing elevating mechanism.

A driven pulley 611, which rotates together with the rotating shaft 544, is mounted to the lower end of the rotating shaft 544 inserted in the support post 542, and a timing belt 612 is stretched between the driven pulley 611 and a driving pulley 613 which is mounted to the shaft of the rotating motor 604. The rotating shaft 544 is thus rotated by the actuation of the rotating motor 604 and, via the timing belt 552 stretched between the driving pulley 545 mounted to the rotating shaft 544 and the driven pulley 551 mounted to the rotating shaft 547 of the head section 541, the rotating shaft 547 is rotated.

The plating section 520 in the substrate processing unit 505 will now be described. FIG. 35 is a vertical sectional view showing the main portion of the plating section 520. As shown in FIG. 35, a generally cylindrical plating bath 620 that holds a plating solution is provided in the plating section 520. A weir member 621 is provided in the plating bath 620, and an upwardly open plating chamber 622 is defined by the weir member 621. An anode 623, which is connected via a power source selector switch 700 to the power source 702 in the apparatus, is disposed at the bottom of the plating chamber 622. The anode 623 is preferably formed of a phosphorus-containing copper containing e.g. 0.03 to 0.05% by weight of phosphorus. Such a phosphorus-containing copper is used to form a so-called black film on the surface of the anode 623 during plating. The black film can suppress the formation of slime.

In the inner circumferential wall of the weir member 621, a plurality of plating solution jet orifices (plating solution supply section) 624 for jetting a plating solution toward the center of the plating chamber 622, are provided at regular intervals along the circumferential direction. The plating solution jet orifices 624 communicate with plating solution supply passages 625 that extend vertically in the weir member 621. The plating solution supply passages 625 are connected to a plating solution supply pump 626 (see FIG. 30), so that by the actuation of the pump 626, a predetermined amount of plating solution is supplied from the plating solution jet orifices 624 into the plating chamber 622. On the outer side of the weir member 621, there is formed a plating solution discharge channel 627 for discharging the plating solution that has overflowed the weir member 621. The plating solution, which has overflowed the weir member 621, flows through the plating solution discharge passage 627 into a reservoir (not shown).

According to this embodiment, an ion exchanger (ion exchange membrane) 628 is disposed so that it covers the surface of the anode 623. The ion exchange membrane 628 is provided to prevent the jet flows from the plating solution jet orifices 624 directly hitting on the surface of the anode 623, thereby preventing the black film formed on the surface of the anode 623 from being curled up by the plating solution and flowing out. It is noted that the structure of the plating section is not limited to this embodiment.

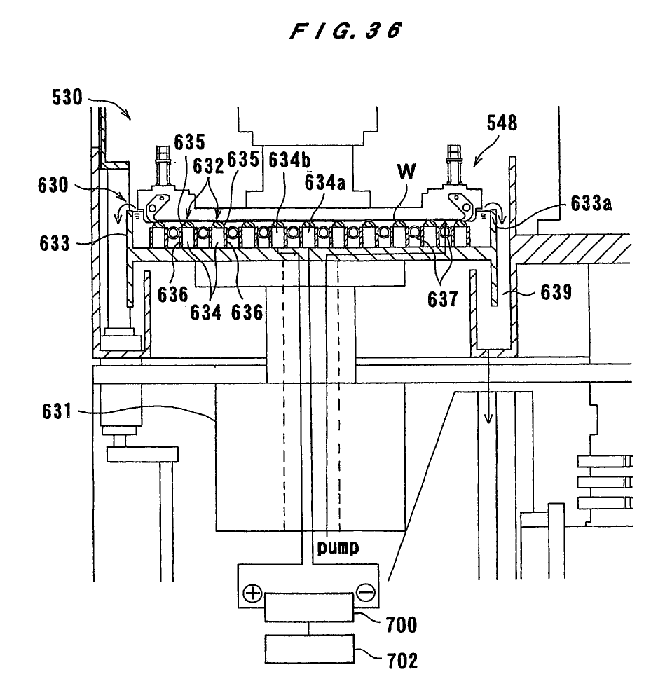

The electrolytic processing section 530 in the substrate processing unit 505 will now be described. FIG. 36 is a vertical sectional view showing the main portion of the electrolytic processing section 530. As shown in FIG. 36, the electrolytic processing section 530 includes a rectangular electrode section 630 and a hollow scroll motor 631 connected to the electrode section 630. By the actuation of the hollow scroll motor 631, the electrode section 630 makes a circular movement without rotation, a so-called scroll movement (translatory rotary movement).

The electrode section 630 includes a plurality of electrode members 632 extending in the B direction (see FIG. 28) and an upwardly open vessel 633. The plurality of electrode members 632 are disposed in parallel at an even pitch in the vessel 633. Each electrode member 632 comprises an electrode 634 to be connected to the power source 702 in the apparatus via the power source selector switch 700, and an ion exchanger (ion exchange membrane) 635 covering the surface of the electrode 634 integrally. The ion exchanger 635 is mounted to the electrode 634 by holding plates 636 disposed on both sides of the electrode 634.

According to this embodiment, the electrodes 634 of the electrode members 632 are connected alternately to the cathode and to the anode of the power source 702. For example, as shown in FIG. 36, processing electrodes 634a are connected to the cathode of the power source 702 and feeding electrodes 634b are connected to the anode via the power source selector switch 700. When processing copper, for example, the electrolytic processing action occurs on the cathode side, and therefore the electrodes 634 connected to the cathode become processing electrodes 634a, and the electrodes 634 connected to the anode become feeding electrodes 634b. Thus, according to this embodiment, the processing electrodes 634a and the feeding electrodes 634b are disposed in parallel and alternately. Depending upon the material to be processed, the electrode connected to the cathode of the power source may serve as a feeding electrode and the electrode connected to the anode may serve as a processing electrode, as described above.

By thus providing the processing electrodes 634a and the feeding electrodes 634b alternately in a direction perpendicular to the long direction of the electrode members 632, provision of a feeding section for feeding electricity to the conductive film (to-be-processed material) of the substrate W is no longer necessary, and processing of the entire surface of the substrate W becomes possible. Further, by allowing the substrate held by the substrate holder 548 to scan, during the processing, in a direction perpendicular to the long direction for a distance corresponding to an integral multiple of the pitch between adjacent processing electrodes 634a, a uniform processing can be effected. Furthermore, by changing the positive and negative of the voltage applied between the electrodes 634 in a pulse form, it becomes possible to dissolve the electrolysis products, and improve the flatness of the processed surface through the multiplicity of repetition of processing.

As shown in FIG. 36, on both sides of each electrode member 632, there are provided pure water supply nozzles 637 for supplying pure water or ultrapure water to between the substrate W and the ion exchanger 635 of the electrode member 632. The pure water supply nozzles 637 are connected to a pure water supply pump 638 (see FIG. 29), so that by the actuation of the pump 638, a predetermined amount of pure water or ultrapure water is supplied from the pure water supply nozzles 637 to between the substrate W and the ion exchanger 635.

According to this embodiment, the vessel 633 is filled with the liquid supplied from the pure water supply nozzles 637, and electrolytic processing is carried out while the substrate W is immersed in the liquid. On the outer side of the vessel 633, there is provided a liquid discharge channel 639 for discharging the liquid that has overflowed the circumferential wall 633a of the vessel 633. The liquid, which has overflowed the circumferential wall 633a, flows through the liquid discharge channel 639 into a waste liquid tank (not shown).

According to this embodiment, the power source 702 is switched by the power source selector switch 700 such that when carrying out plating in the plating section 520, the feeding members 578 of the feeding contact members 574 are connected to the cathode of the power source 702 and the anode 623 is connected to the anode of the power source 702, and, when carrying out electrolytic processing in the electrolytic processing section 530, the electrodes 634 of the electrode members 632 are connected alternately to the cathode and to the anode of the power source 702.

It is possible to effect electricity feeding to the substrate exclusively by the feeding members 578 of the feeding contact members 574 and utilize all of the electrodes 634 shown in FIG. 36 as processing electrodes. Since in this case electricity is fed to the substrate directly and solely by the chuck mechanisms 570, the portion of the substrate in contact with the feeding electrodes (feeding members 574) is small, that is, gas bubble-generation area is decreased. In addition, the number of processing electrodes is doubled, that is, the number of processing electrodes which pass over the substrate during electrolytic processing is increased, whereby the processing uniformity over the entire substrate surface and the processing rate are improved.

Further, though in this embodiment the power source 702 is switched between the plating section 520 and the electrolytic processing section 530 by the power source selector switch 700, it is possible to provide the plating section 520 and the electrolytic processing section 530 with individual power sources.

A description will now be given of a series of process steps for processing a substrate, such as a semiconductor substrate, using the substrate processing apparatus shown in FIG. 27. First, substrates are set, with their front surfaces (device surfaces, to-be-processed surfaces) facing upward, in a cassette in advance, and the cassette is placed on the loading/unloading unit 502. The first transfer robot 506 takes one substrate out of the cassette placed on the loading/unloading unit 502, and transfers the substrate to the substrate stage 504 and places the substrate on the substrate stage 504. The substrate on the substrate stage 504 is reversed by the reversing machine of the substrate stage 504, and is then taken by the second transfer robot 507. The shutter opening/closing air cylinder 514 of the substrate processing unit 505 is driven to open the shutter 513, and the substrate W is inserted by the second transfer robot 507 from the opening 512 formed in the cover 511 into the substrate processing unit 505.

In advance of transfer of the substrate to the substrate processing unit 505, the pivoting motor 605 of the driving device 600 is driven to rotate the support post 542 through a predetermined angle so as to move the head section 541 to the electrolytic processing position Q (see FIG. 28) above the electrolytic processing section 530. Further, the movable member 549 is lowered to bring the pressure rods 556 into contact with the nuts 575 of the chuck mechanisms 570, thereby pressing down the rods 572 against the pressing force of the helical compression springs 576 to open the feeding contact members 574 outwardly.

The hand of the second transfer robot 507, which has been inserted into the substrate processing unit 505, is raised to bring the upper surface (back surface) of the substrate W into contact with the lower surface of the attracting plate 561 of the substrate holder 548. Thereafter, the movable member 549 is raised to close the feeding contact members 574 of the chuck mechanisms 570 inwardly. The substrate W is thus positioned and held by the feeding contact members 574. The feeding members 578 of the feeding contact members 574 are in contact with the peripheral portion of the substrate W, that is, feeding from the power source 702 to the substrate W is now possible. The vacuum pump is driven to evacuate air from the space 563, thereby attracting the substrate W onto the lower surface of the attracting plate 561. Thereafter, the hand of the second transfer robot 507 is withdrawn from the substrate processing unit 505, and the shutter 513 is closed.

Next, the pivoting motor 605 of the driving device 600 is driven to rotate the support post 542 through a predetermined angle so as to move the head section 541 holding the substrate W to the plating position P above the plating section 520. Thereafter, the elevating motor of the driving device 600 is driven to lower the support post 542 for a predetermined distance, thereby immersing the substrate W, held on the lower surface of the substrate holder 548, in the plating solution in the plating bath 620. Thereafter, the rotating motor 604 of the driving device 600 is driven to rotate the rotating shaft 547 of the head section 541 via the rotating shaft 544 in the support post 542, thereby rotating the substrate W at a medium rotational speed (several tens revolutions per minute). An electric current is then passed between the anode 623 and the substrate W to form a copper film (plated film) 7 (see FIG. 15B) on the surface of the substrate W. In the plating, it is possible to apply such a pulse voltage between the anode 623 and the substrate W that the electric potential turns periodically to 0 or a reverse potential.

After completion of the plating, the rotation of the substrate W is stopped, and the elevating motor of the driving device 600 is driven to raise the support post 542 and the head section 541 for a predetermined distance. Next, the pivoting motor 605 of the driving device 600 is driven to rotate the support post 542 through a predetermined angle, thereby moving the head section 541 holding the substrate W to a position above the cleaning nozzle 517 (shower). Thereafter, the elevating motor of the driving device 600 is driven to lower the support post 542 for a predetermined distance. Next, the rotating motor 604 of the driving device 600 is driven to rotate the substrate holder 548 at a speed of e.g. 100 min⁻¹, while a cleaning liquid (pure water) is jetted from the cleaning nozzle 517 toward the lower surface of the substrate W to clean the substrate W after plating and the feeding contact members 574, etc., and replace the plating solution with pure water.

After completion of the cleaning, the pivoting motor 605 of the driving device 600 is driven to rotate the support post 542 through a predetermined angle, thereby moving the head section 541 to the electrolytic processing position Q above the electrolytic processing section 530. Thereafter, the elevating motor of the driving device 600 is driven to lower the support post 542 for a predetermined distance so as to bring the substrate W, held on the lower surface of the substrate holder 548, close to or into contact with the surface of the ion exchanger 635 of the electrode section 630. Thereafter, the hollow scroll motor 631 is driven to allow the electrode section 630 to make a scroll movement, and a sliding motor is driven to allow the substrate W to scan for a distance corresponding to an integral multiple of the pitch between adjacent processing electrodes 634a, while pure water or ultrapure water is supplied from the pure water supply nozzles 637 to between the substrate W and the electrode members 632 so as to immerse the substrate W in the liquid in the vessel 633.

The above scanning operation of the substrate W is carried out repeatedly during electrolytic processing. Further, after each scanning operation, the substrate W is rotated through a predetermined angle, e.g. 20 degrees or 30 degrees. This can reduce unevenness of the processed surface due to the shapes and arrangement of the electrodes, the operational conditions, etc.

The power source selector switch 700 is switched to connect the electrodes 634 of the electrode members 632 alternately to the cathode and to the anode of the power source 702, so that a voltage is applied with the electrodes 634 connected to the cathode of the power source 702 as processing electrodes 634a and the electrodes 634 connected to the anode as feeding electrodes 634b. In case all of the electrodes 634 shown in FIG. 36 are made processing electrodes, the feeding members 578 of the feeding contact members 574 are connected to the anode of the power source 702 and the electrodes 634 are connected to the cathode.

Electrolytic processing of the conduction film (copper film 7) in the surface of the substrate W is effected at the processing electrodes (cathodes) 634a through the action of hydrogen ions and hydroxide ions produced by the ion exchanger 635. During the electrolytic processing, it is possible to apply such a pulse voltage between the processing electrodes 634a and the feeding electrodes 634b that the electric potential turns periodically to 0 or a reverse potential.

In the case of using a liquid like ultrapure water, which itself has a large resistivity, in the electrolytic processing, it is preferred to bring the ion exchanger 635 into contact with the substrate W. This can lower the electric resistance, and hence lower the voltage applied and reduce the power consumption. The “contact” does not imply “press” for giving a physical energy (stress) to a workpiece as in CMP. Accordingly, the electrolytic processing section 530 of this embodiment is not provided with such a pressing mechanism, as used in a CMP apparatus, for example, that presses a polishing member against a substrate. In the case of CMP, a polishing surface is brought into contact with a substrate generally at a pressure of about 20-50 kPa. According to the electrolytic processing unit of this embodiment, on the other hand, the ion exchanger 635 may be brought into contact with the substrate W at a pressure of e.g. not mote than 20 kPa. A sufficient removal processing effect can be achieved even with a pressure of not more than 10 kPa.

It is possible to use, instead of pure water or ultrapure water, any electrolyte solution obtained by adding an electrolyte to e.g. pure water or ultrapure water. The use of an electrolyte solution can lower the electric resistance and reduce the power consumption. A solution of a neutral salt such as NaCl or Na₂SO₄, a solution of an acid such as HCl, H₂SO₄ or phosphoric acid, or a solution of an alkali such as ammonia, may be used as the electrolyte solution, and may appropriately be selected depending upon the properties of the material to be processed.

In the case of using an electrolyte solution as a processing liquid, it is preferred to provide, instead of the ion exchanger 635, a contact member which comes into contact with the conductive film (copper film 7) on the surface of the substrate W and scrubs away the conductive film. It is preferred that the contact member be liquid-permeable pre se or made liquid-permeable by providing a large number of fine apertures, and also elastic so that it may keep tight contact with the substrate and may not damage the substrate. It is further preferred that the contact member be electrically conductive or ion-exchangeable. Specific examples of such contact members include porous polymers such as a foamed polyurethane, fibrous materials such as a nonwoven fabric, various pads, and scrub cleaning members.

In this case, it is possible to anodize the surface of the copper film 7 (see FIG. 15B) as an interconnect material by using as a processing liquid an electrolyte solution containing an electrolyte, such as copper sulfate or ammonium sulfate, and scrub away the copper film with the contact member. It is also possible to add a chelating agent to an electrolyte solution so as to chelate the surface of the copper film 7 (see FIG. 15B), thereby making the surface fragile to facilitate scrubbing-away of the copper film 7.

Further, it is possible to carry out a composite processing, which is a combination of electrolytic processing and mechanical polishing with abrasive grains, for example, by adding abrasive grains to a processing liquid of an electrolyte solution or of pure water, or supplying a processing liquid and a slurry containing abrasive grains simultaneously.

As the processing liquid, an acid solution of about 0.01 to about 0.1 wt. %, for example, such as dilute sulfate acid solution or dilute phosphoric acid solution may be used.

It is also possible to use, instead of pure water or ultrapure water, a liquid obtained by adding a surfactant to pure water or ultrapure water, and having an electric conductivity, which is adjusted by the addition of the surfactant, of not more than 500 μS/cm, preferably not more than 50 μS/cm, more preferably not more than 0.1 μS/cm (resistivity of not less than 10 MΩ·cm). Owing to the presence of a surfactant, the liquid can form a layer, which functions to inhibit ion migration evenly, at the interface between the substrate W and the ion exchanger 635, thereby moderating concentration of ion exchange (metal dissolution) to enhance the flatness of the processed surface. The surfactant concentration of the liquid is preferably not more than 100 ppm. When the electric conductivity of the liquid is too high, the current efficiency is lowered and the processing rate is decreased. The use of the liquid having an electric conductivity of not more than 500 μS/cm, preferably not more than 50 μS/cm, more preferably not more than 0.1 μS/cm, can attain a desired processing rate.

When it is desired to selectively remove only the raised portions of the plated film on the substrate with an increased selectivity, it is preferred to adjust the electric conductivity to not more than 50 μS/cm, more preferably not more than 2.5 μS/cm.

After completion of the electrolytic processing, the power source 702 is disconnected, and the scroll movement of the electrode section 630 is stopped. Thereafter, the elevating motor of the driving device 600 is driven to raise the support post 542 and the head section 541 for a predetermined distance. Thereafter, the shutter 513 provided in the substrate processing unit 505 is opened, and the second transport robot 507 is inserted from the opening 512 formed in the cover 511 into the substrate processing unit 505. The hand of the second transfer robot 507 is then raised to a position at which it can receive the substrate W. Thereafter, the movable member 549 is lowered to bring the pressure rods 556 into contact with the nuts 575 of the chuck mechanisms 570, thereby pressing down the rods 572 against the pressing force of the helical compression springs 576 to open the feeding contact members 574 outwardly, whereby the substrate W is released, and placed on the hand of the second transfer robot 507. The hand of the second transfer robot 507, on which the substrate W is placed, is then withdrawn from the substrate processing unit 505, and the shutter 513 is closed.

The second transfer robot 507, which has received the substrate W after the plating and the electrolytic processing, moves the substrate W to the substrate stage 504 and places the substrate W on the substrate stage 504. The substrate on the substrate stage 504 is taken by the first transfer robot 506, and the first transfer robot 506 transfers the substrate W to the bevel-etching/cleaning unit 503. In the bevel-etching/cleaning unit 503, the substrate W after plating and electrolytic processing is cleaned with a chemical liquid and, at the same time, a copper film formed thinly in the bevel portion of the substrate W, etc. is etched away. In addition, the substrate W is water-washed and dried. After the cleaning in the bevel-etching/cleaning unit 503, the substrate W is returned by the first transfer robot 506 to the cassette of the loading/unloading unit 502. The series of processings is thus completed.

Processing of a substrate was actually carried out by using the substrate pressing apparatus of this embodiment and using liquids with electric conductivities of 2.5 μS/cm, 50 μS/cm and 500 μS/cm in the electrolytic processing section 530. As a result, it was confirmed that a liquid having a lower electric conductivity is preferred in the light of selective removal of raised portions and flatness of the processed substrate. The best flatness was obtained with the liquid having an electric conductivity of 2.5 μS/cm, which is the level of common pure water.

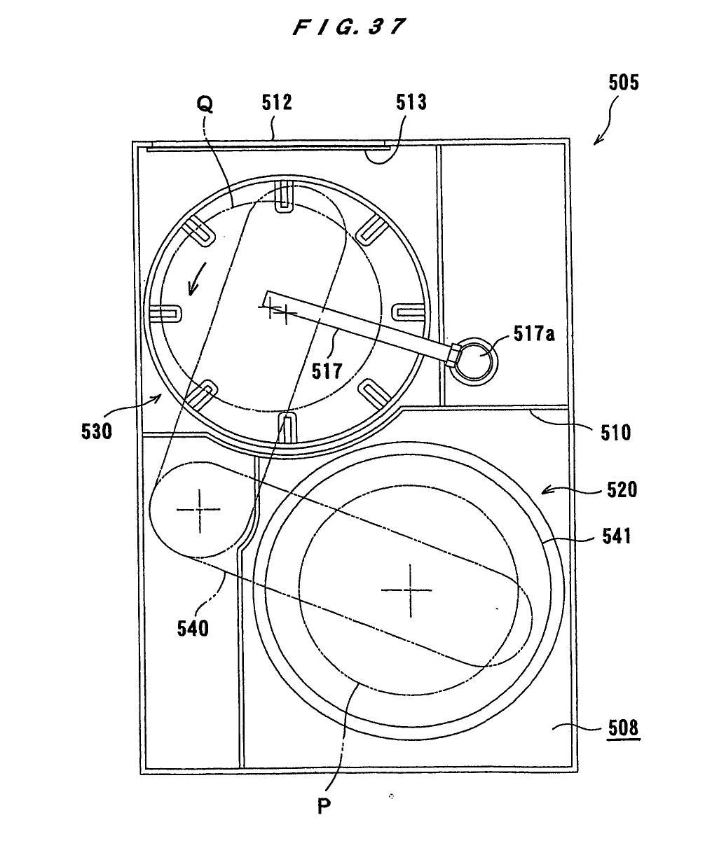

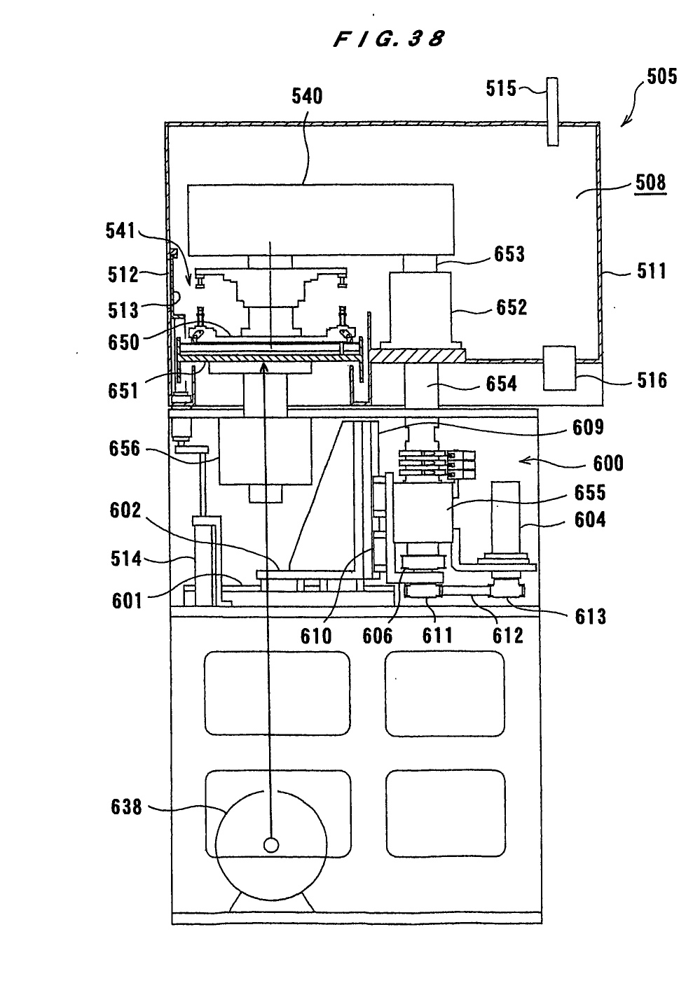

A substrate processing unit in a substrate processing apparatus according to yet another embodiment of the present invention will now be described in detail with reference to FIGS. 37 and 38. In the following description, the same members or elements as those used in the substrate processing unit of the above-described embodiment, having the same operation or function, are given the same reference numerals and a redundant description will be omitted.

FIG. 37 is a plan view of the substrate processing unit 505, FIG. 38 is a vertical sectional front view of FIG. 37. As shown in FIGS. 37 and 38, the substrate processing unit 505 is divided by a partition wall 510 into two substrate processing sections, i.e. a plating section 520 for carrying out plating of the substrate and an electrolytic processing section 530 for carrying out electrolytic processing of the substrate. The plating section 520 and the electrolytic processing section 530 are enveloped in a cover 511, defining a processing space 508. A cleaning nozzle 517, which is rotatable about a shaft 517a, is disposed in the processing space 508. The substrate after plating and electrolytic processing is cleaned with e.g. pure water jetted from the cleaning nozzle 517.

An opening 512 for carrying in and out the substrate is formed in the sidewall on the electrolytic processing section 530 side of the cover 511, and the opening 512 is provided with an openable/closable shutter 513. The shutter 513 is connected to a shutter opening/closing air cylinder 514. By the actuation of the shutter opening/closing air cylinder 514, the shutter 513 moves up and down so as to open and close the opening 512. By thus hermetically closing the substrate processing unit 505, a mist or the like generated in the plating is prevented from scattering out of the substrate processing unit 505.

As shown in FIG. 38, an inert gas (purging gas) supply port 515 is provided in the upper portion of the cover 511, and an inert gas (purging gas), such as N₂ gas, is supplied from the inert gas supply port 515 into the substrate processing unit 505. A cylindrical ventilation duct 516 is provided at the bottom of the cover 511, and the gas in the processing space 508 is discharged out through the ventilation duct 516.

As shown in FIG. 37, an arm-shaped cleaning nozzle 517, as a cleaning section for cleaning the substrate that has been plated in the plating section 520 and a cleaning section for cleaning the substrate that has been electrolytic processed in the electrolytic processing section 530, is disposed between the plating section 520 and the electrolytic section 530. The cleaning nozzle 517 is connected to a not-shown cleaning liquid supply source, and a cleaning liquid (e.g. pure water) is jetted from the cleaning nozzle 517 toward the lower surface of the substrate W. The cleaning nozzle 517 is rotatable about the shaft 517a, and retreated from the position shown in FIG. 37 during electrolytic processing.

A pivot arm 540, which is pivotable between the plating section 520 and the electrolytic processing section 530, is installed in the substrate processing unit 505. A head section 541 for holding the substrate is mounted vertically to the free end side of the pivot arm 540. By pivoting the pivot arm 540, as shown in FIG. 37, the head section 541 can be moved between a plating position P at which plating of the substrate is carried out in the plating section 520 and an electrolytic processing position Q at which electrolytic processing of the substrate is carried out in the electrolytic processing section 530.

The electrolytic processing section 530 comprises a disk-shaped electrode section 651 disposed beneath a head section 541, and a power source 704 to be connected to the electrode section 651.

The pivot arm 540, which is allowed to pivot horizontally by the actuation of a pivot motor 652, is mounted on the upper portion of the pivot shaft 653 coupled to the pivot motor 652. The pivot shaft 653 is connected to a ball screw 654 extending vertically to be moved vertically with the pivot arm 540 by the actuation of the motor 655 for the vertical movement to which the ball screw 654 is coupled.

FIG. 31 is a vertical sectional view showing the main portion of the pivot arm 540 and the head section 541. As shown in FIG. 31, the pivot arm 540 is fixed on the upper end of a rotatable hollow support post 542, and pivots horizontally by the rotation of the support post 542. A rotating shaft 544, which is supported by a bearing 543, passes through the hollow portion of the support post 542 and is rotatable relative to the support post 542. Further, a driving pulley 545 is mounted to the upper end of the rotating shaft 544.

The head section 541 is coupled to the pivot arm 540 and, as shown in FIG. 31, is comprised mainly of an outer casing 546 fixed to the pivot arm 540, a rotating shaft 547 vertically penetrating the outer casing 546, a substrate holder 548 for holding the substrate W on its lower surface, and a movable member 549 that is vertically movable relative to the outer casing 546. The substrate holder 548 is coupled to the lower end of the rotating shaft 547.

The head section 541, which is allowed to rotate by the actuation of the a rotation motor, is connected to the rotating motor (first drive element) for making a relative movement between the substrate W held by the head section 541 and the electrode section 651. As described above, the pivot arm 540 is adapted to move vertically and to pivot vertically. The head section 541 moves vertically and pivots vertically with the pivot arm 540.

A hollow motor 656 (second drive element) for making a relative movement between the substrate W and the electrode section 651 is disposed beneath the electrode section 651. A drive end is formed at the upper end portion of the main shaft of the hollow motor 656 and arranged eccentrically position to the center of the main shaft, so that the electrode section 651 makes a scroll movement (translatory rotary movement).

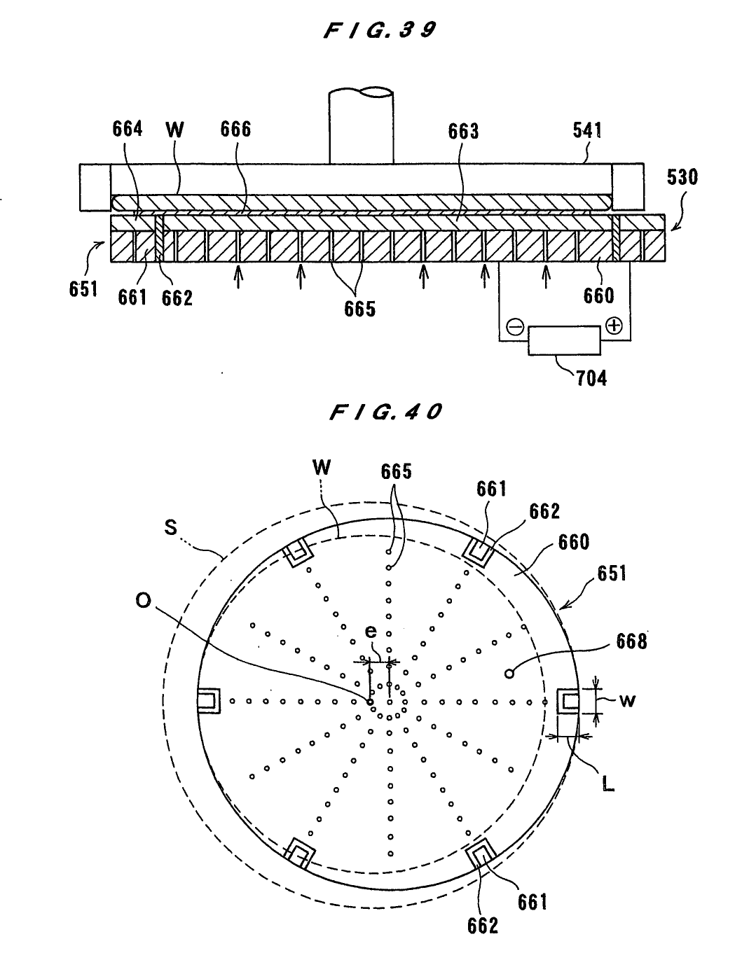

FIG. 39 is a vertical sectional view schematically showing the head section 541 and the electrolytic processing section 530, and FIG. 40 is a plan view showing the relationship between the substrate W and the electrode section 651 of the electrolytic processing section 530. In FIG. 40, the substrate W is shown with a broken line. As shown in FIGS. 39 and 40, the electrode section 651 includes a substantially disk-shaped processing electrode 660 having a diameter larger than that of the substrate W, a plurality of feeding electrodes 661 disposed in a peripheral portion of the processing electrode 660, and insulators 662 that separate the processing electrode 660 and the feeding electrodes 661. As shown in FIG. 39, the upper surface of the processing electrode 660 is covered with an ion exchanger 663, and the upper surfaces of the feeding electrodes 661 are covered with ion exchangers 664. The ion exchangers 663 and 664 may be formed integrally. The ion exchangers 663, 664 are not shown in FIG. 40.

According to this embodiment, it is not possible to supply pure water or ultrapure water to the upper surface of the electrode section 651 from above the electrode section 651 during electrolytic processing due to the relationship of the size between the electrode section 651 and the head section 541. Thus, as shown in FIGS. 39 and 40, liquid supply holes 665, for supplying pure water or ultrapure water to the upper surface of the processing electrode 660, are formed in the processing electrode 660. According to this embodiment, a number of fluid supply holes 665 are disposed radially from the center of the processing electrode 660. The fluid supply holes 665 are connected to a pure water supply pipe that extends through the hollow portion of the hollow motor 656, so that pure water or ultrapure water is supplied through the fluid supply holes 665 to the upper surface of the electrode section 651.

In this embodiment, the processing electrode 660 is connected to the cathode of the power source 704, and the feeding electrodes 661 are connected to the anode of the power source 704. Depending upon the material to be processed, the electrode connected to the cathode of the power source may serve as a feeding electrode and the electrode connected to the anode may serve as a processing electrode, as described above.

During electrolytic processing, the rotating motor is driven to rotate the substrate W and, at the same, the hollow motor 656 is driven to allow the electrode section 651 to make a scroll movement about a scroll center “O” (see FIG. 40). By thus allowing the substrate W held by the head section 541 and the processing electrode 660 to make a relative movement within a scroll region S, processing of the whole surface of the substrate W (copper film 7) is effected. The electrode section 651 of the electrolytic processing section 530 is so designed that during the relative movement, the center of movement (center “O” of scroll movement according to this embodiment) always lies within the range of substrate W. By thus making the diameter of the processing electrode 660 larger than the diameter of the substrate W and making the center of movement of the processing electrode 660 always lie within the range of the substrate W, it becomes possible to best equalize the presence frequency of the processing electrode 660 over the surface of the substrate W. It also becomes possible to considerably reduce the size of the electrode section 651, leading to a remarkable downsizing and weight saving of the whole apparatus. It is preferred that the diameter of the processing electrode 660 be larger than the sum of the distance of relative movement of the substrate W and the processing electrode 660 (scroll radius “e” according to this embodiment) and the diameter of the substrate W, and be smaller than twice the diameter of the substrate W.

Since the substrate W cannot be processed with the region where the feeding electrodes 661 are present, the processing rate is low with the peripheral portion in which the feeding electrodes 661 are disposed, compared to the other region. It is therefore preferable to make the area (region) occupied by the feeding electrodes 661 smaller in order to reduce the influence of the feeding electrodes 661 upon the processing rate. From this viewpoint, according to this embodiment, a plurality of feeding electrodes 661 having a small area are disposed in a peripheral portion of the processing electrode 660, and at least one of the feeding electrodes 661 is allowed to come close to or into contact with the substrate W during the relative movement. This makes it possible to reduce an unprocessible region as compared to the case of disposing a ring-shaped feeding electrode in the peripheral portion of the processing electrode 660, thereby preventing a peripheral portion of the substrate W from remaining unprocessed.

Next, substrate processing (electrolytic processing) by the substrate processing apparatus according to the present invention will be described. A given voltage is applied from the power source 704 to between the processing electrode 660 and the feeding electrodes 661 to carry out electrolytic processing of the conductive film (copper film 7) in the surface of the substrate W at the processing electrode (cathode) 660 through the action of hydrogen ions or hydroxide ions generated with the aid of the ion exchangers 663, 664. The processing progresses at the portion of the substrate W facing the processing electrode 660. As described above, by allowing the substrate W and the processing electrode 660 to make the relative movement, the entire surface of the substrate W can be processed. Also as described above, by making the diameter of the processing electrode 660 larger than the diameter of the substrate W and making the center “O” of movement of the processing electrode 660 always lie within the range of the substrate W, it becomes possible to best equalize the presence frequency of the processing electrode 660 over the surface of the substrate W. It also becomes possible to considerably reduce the size of the electrode section 651, leading to a remarkable downsizing and weight saving of the whole apparatus.

A substrate processing process, which comprises a repetition of plating, cleaning and electrolytic processing, will now be described with reference to FIG. 41. As shown in FIGS. 28 and 37, the pivot arm 540, which is pivotable between the plating section 520 and the electrolytic processing section 530, is installed in the substrate processing unit 505. The head section 541 for holding the substrate is mounted vertically to the free end side of the pivot arm 540. By pivoting the pivot arm 540, the substrate held by the head section 541 can be moved between the plating position 520 to carry out plating of the substrate and the electrolytic processing section 530 to carry out electrolytic processing (electrolytic polishing) of the substrate. Further, the cleaning nozzle 517 is provided in the substrate processing unit 505, so that the substrate after plating and electrolytic processing can be cleaned.

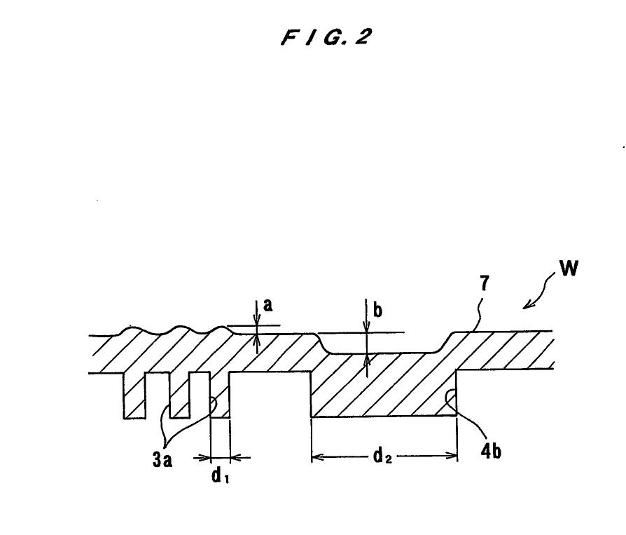

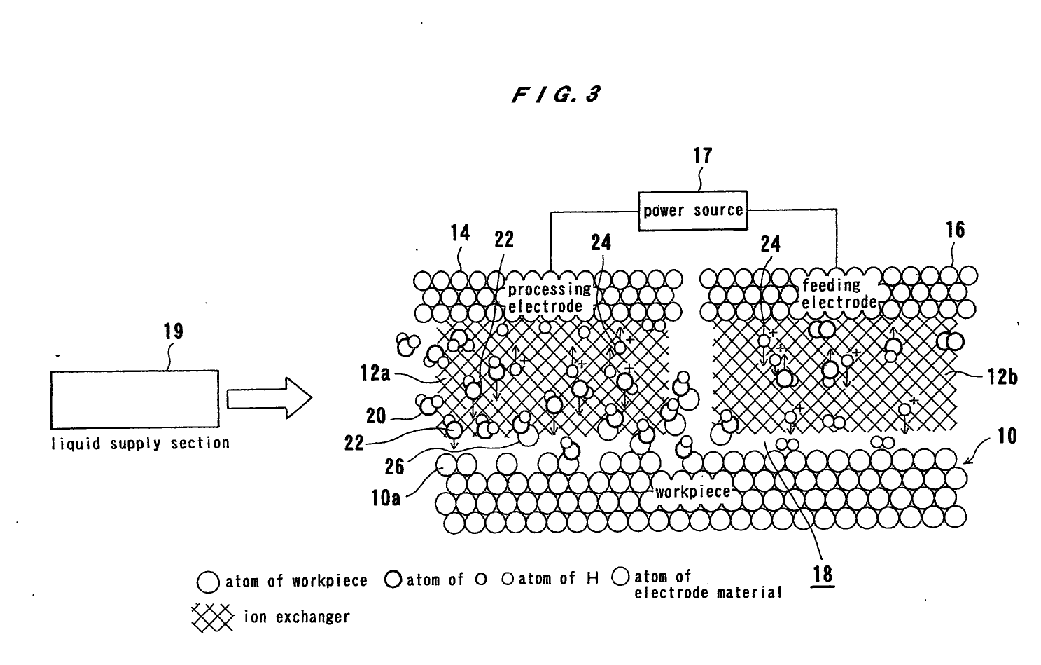

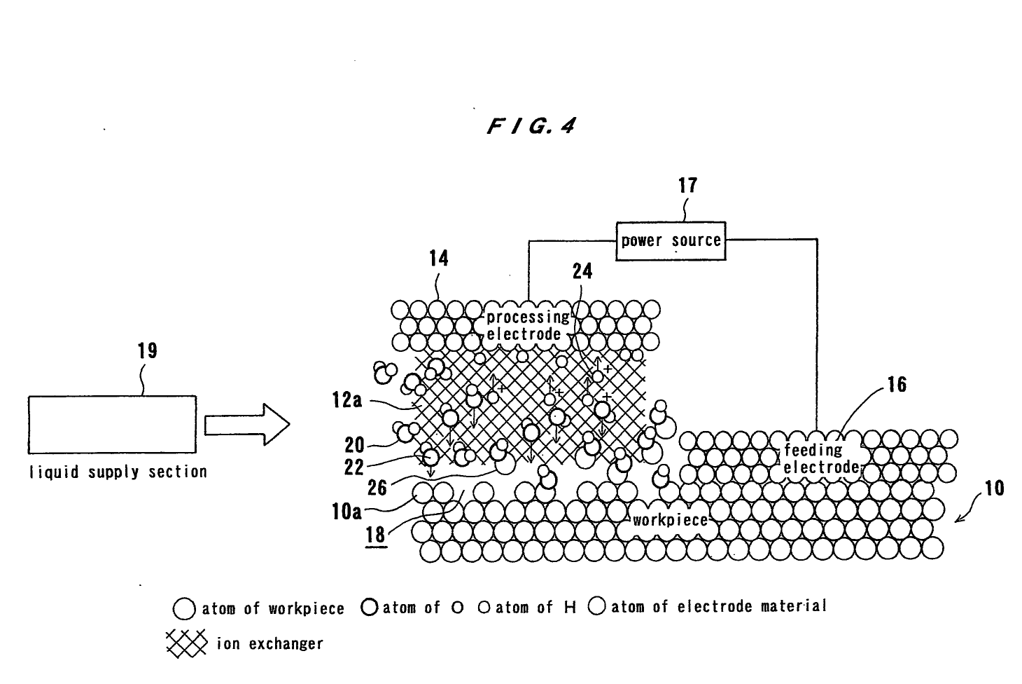

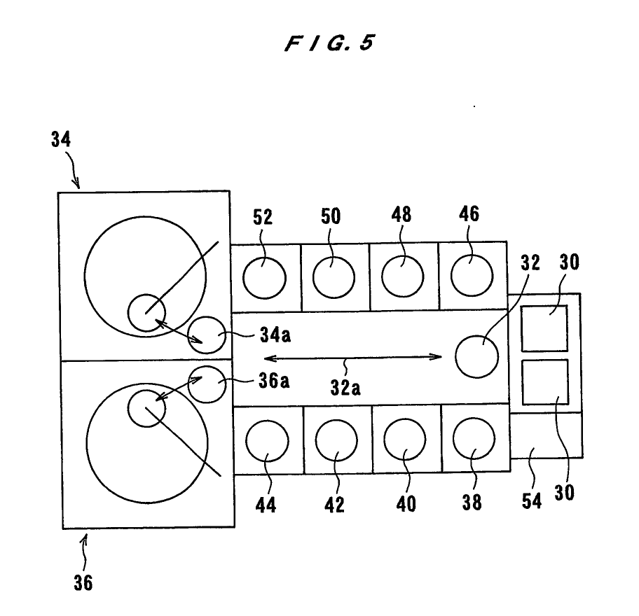

As described above with reference to FIG. 2, when copper plating is carried out to form a copper film 7 on the surface of a substrate W in which fine holes 3a and broad trenches 4b are co-present, the growth of plating is promoted in and over the fine holes 3a, and therefore the copper film 7 tends to rise over the fine holes 3a, resulting in the formation of raised portions. On the other hand, growth of plating with an enhanced leveling property is not possible within the broad trenches 4b. As a result, a difference in level corresponding the sum of the height of a raised portion over a fine hole 3a and the depth of a depressed portion in a broad trench 4b, is formed in the copper film 7 deposited on the substrate W. In order to reduce the formation of such the difference in level, it is preferred to carry out plating and electrolytic processing (electrolytic polishing) repeatedly.

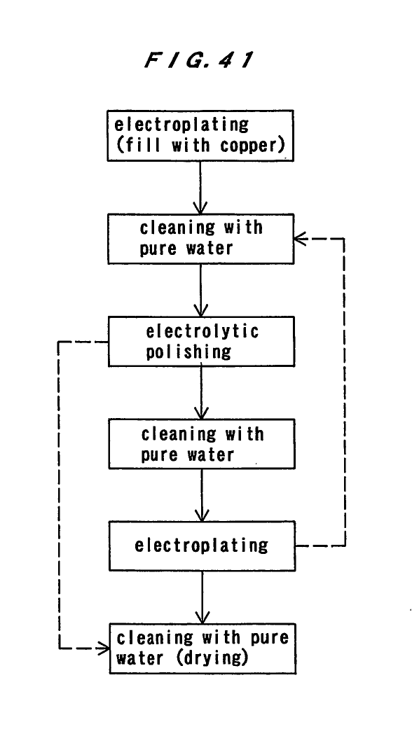

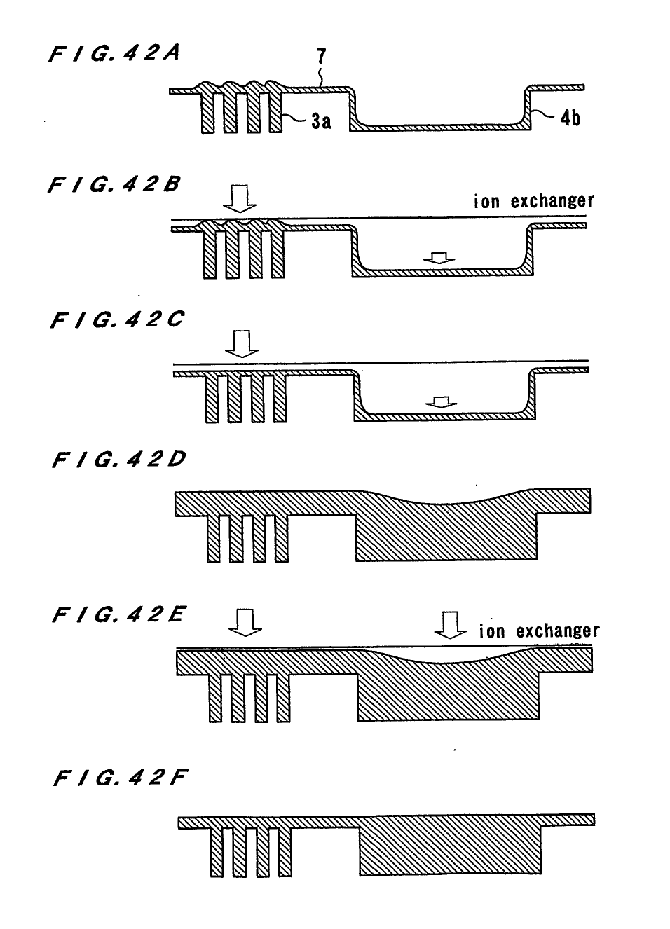

FIGS. 42A through 42F are diagrams illustrating a substrate processing process which carries out plating and electrolytic polishing repeatedly two times. First, electrolytic copper plating of the above substrate W is carried out in the plating section 520 to embed copper mainly into the fine holes 3a. At this stage, raised portions have been formed locally over the fine holes 3a, whereas the broad trenches 4b are not filled with copper yet (see FIG. 42A). This is because a region with a high pattern density has a large surface area and an additive, as a plating promoter, in a plating solution concentrates in the narrow holes, whereby the growth of plating is promoted in the region where the fine holes 3a are present. After the plating, the substrate W is cleaned with pure water, thereby removing the plating solution from the surface of the substrate W. Thereafter, electrolytic processing is carried out in the electrolytic processing section 530 to remove the raised portions locally formed over the fine holes 3a (see FIGS. 42B and 42C). The first series of plating, cleaning and electrolytic processing is thus completed.

Next, after cleaning the substrate with pure water, electrolytic plating is again carried out in the plating section 520. The electrolytic plating is terminated when the broad trenches 4b become fully filled with copper. At this stage, the broad trenches 4b are completely filled with copper, while a copper film (plated film) 7 is also formed in and on the fine holes 3a (see FIG. 42D). After washing the substrate with pure water, electrolytic processing is again carried out in the electrolytic processing section 530. By the second electrolytic plating, the surface of copper film 7 is almost flattened, leaving a copper film 7 having a desired thickness with which the fine holes 3a and the broad trenches 4b are filled (see FIGS. 42E and 42F). The copper film (plated film) 7, having a good surface flatness, for example, a film thickness of about 50-100 nm, can be obtained. The substrate after the electrolytic processing is cleaned with pure water, followed by drying, thereby terminating the second series of plating, cleaning, and electrolytic processing.

Though the case of carrying out plating and electrolytic processing repeatedly two times has been described, it is of course possible to carry out the series of processings repeatedly three times or more. Further, it is possible to completely remove the portion of copper film unnecessary for the formation of device interconnects in the substrate surface and leave only the copper film in the pattern. By thus carrying out plating and electrolytic processing repeatedly a plurality of times, as compared to the case of flattening the larger difference in level in a single electrolytic processing step, a flatter processed surface can be obtained in a shorter time. The repetition of the plating and the electrolytic processing using a liquid having a low electric conductivity can prevent an excessive formation of raised portions in a fine-hole region, and can provide a processed substrate, in which a copper film is embedded flatly both in fine holes and in broad trenches, with an increased efficiency.

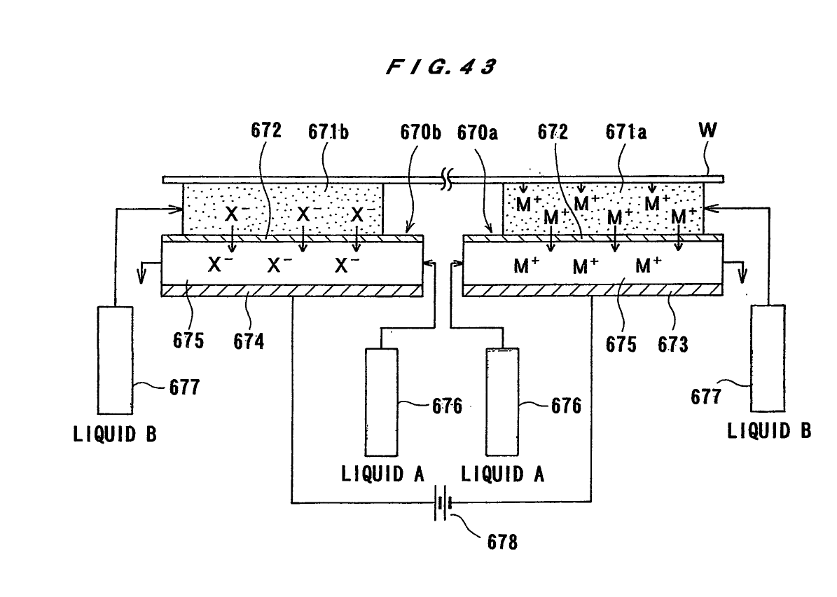

FIG. 43 shows a diagram of a variation of the electrolytic processing section. The electrolytic processing section is provided with regeneration sections 670a, 670b for regenerating an ion exchanger (cation exchanger 671a and/or anion exchanger 671b).

The regeneration sections 670a, 670b each comprise a partition 672 disposed closed to or in contact with the ion exchanger (cation exchanger 671a and/or anion exchanger 671b), a discharge portion 675 formed between the processing electrode 673 or the feeding electrode 674 and the partition 672, and a discharging liquid supply section 676 for supplying to the discharge portion 675 a discharging liquid A for discharging contaminants. When a workpiece, such as a substrate W, is close to or in contact with the ion exchanger (cation exchanger 671a and/or anion exchanger 671b), the discharging A for discharging contaminants is supplied from the discharging liquid supply section 676 to the discharge portion 675 and a processing liquid B for electrolytic processing is supplied from an electrolytic processing liquid supply section 677 to between the partition 672 and the ion exchanger (cation exchanger 671a and/or anion exchanger 671b), while a voltage is applied from a processing power source 678 to between the processing electrode 673 as a cathode and the feeding electrode 674 as an anode, thereby carrying out electrolytic processing.

During the electrolytic processing, in the cation exchanger 671a, ions such as dissolved ions M⁺ of a to-be-processed material, which are being taken in the cation exchanger, move toward the processing electrode (cathode) 673 and pass through the partition 672. The ions M⁺ that have passed the partition 672 are discharged out of the system by the flow of the discharging liquid A supplied between the partition 672 and the processing electrode 673. The cation exchanger 671a is thus regenerated. When a cation exchanger is used as the partition 672, the partition (cation exchanger) 672 can permit permeation therethrough of only ions M+coming from the cation exchanger 671a. In the anion exchanger 671b, on the other hand, ions X⁻ in the anion exchanger 671b move toward the feeding electrode (anode) 674 and pass through the partition 672. The ions X⁻ that have passed the partition 672 are discharged out of the system by the flow of the discharging liquid A supplied between the partition 672 and the feeding electrode 674. The anion exchanger 671b is thus regenerated. When an anion exchanger is used as the partition 672, the partition (anion exchanger) 672 can permit permeation therethrough of only ions X⁻ coming from the anion exchanger 671b.

A liquid having a low electric conductivity such as pure water or ultrapure water is preferably used as the processing liquid, thereby enhancing the efficiency of the electrolytic processing. A liquid having a high electric conductivity (electrolytic solution) is preferably supplied as a discharging liquid that flows between the partition 672 and the processing electrode 673 or the feeding electrode 674. An aqueous solution of a neutral salt such as NaCl or Na₂SO₄, an acid such as HCl or H₂SO₄, or an alkali such as ammonia may be used as the electrolytic solution, and may be properly selected according to the properties of a workpiece. This can enhance the regeneration efficiency of the ion exchanger.

As shown in FIG. 40, the electrode section is preferably provided with a sensor 668 for detecting the thickness of a metal film (copper film 7), the object of electrolytic processing, on a substrate. An optical sensor, comprising e.g. a light source unit and a photo detector, may be used as the sensor 668. The optical sensor can detect the thickness of the metal film (copper film 7) by emitting a light from the light source unit toward the surface of the metal film and detecting the reflected light from the metal film. A laser light or a LED light may be used as the light to be emitted from the light source unit.

Alternatively, it is possible to dispose an eddy current sensor near the metal film (copper film 7). The eddy current sensor generates an eddy current in the metal film and detects the intensity of the eddy current. The film thickness can be detected based on the detected intensity of eddy current. It is also possible to dispose a temperature sensor near the metal film, the object of electrolytic processing. A change in the film thickness can be detected from a change in the exothermic heat, utilizing the fact that the exothermic heat changes with a change in the film thickness during electrolytic processing of the metal film. The current value inputted to a driving motor for rotating the head section or the electrolytic processing section changes with a change in the thickness of the metal film, the object of electrolytic processing. It is therefore possible to detect a change in the film thickness from the change in the current value. With the provision of such a means for detecting the thickness of the metal film, it becomes possible to precisely determine the film thickness during electrolytic processing, which makes it possible to carry out the processing with high precision.

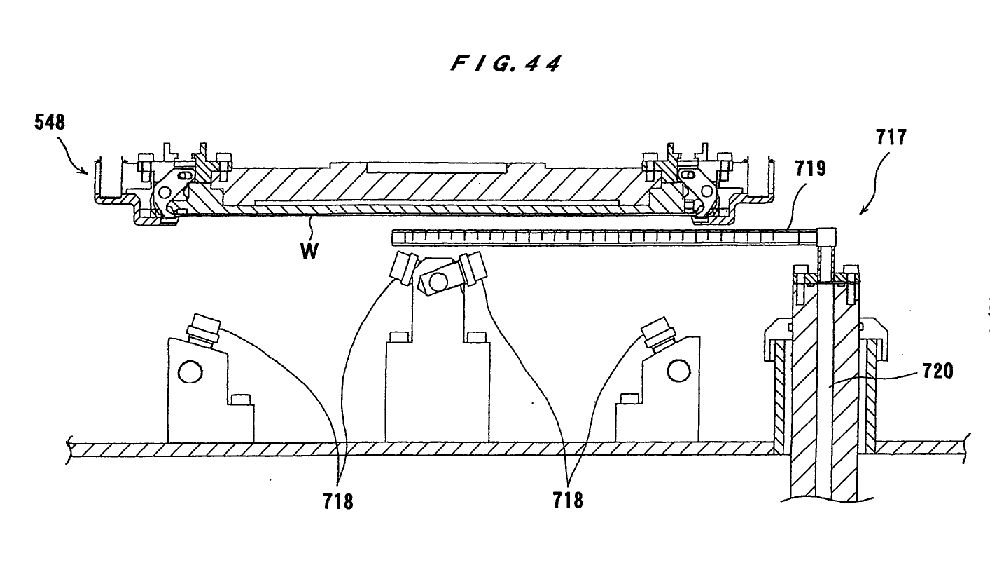

FIG. 44 is a vertical sectional view showing a cleaning section which is provided in the substrate processing unit 505. As shown in FIG. 44, the cleaning section 717 includes a plurality of cleaning nozzles 718 for jetting a cleaning liquid toward the peripheral portion of the substrate W and cleaning the substrate, and an arm-shaped air blower 719 for drying the substrate W after the cleaning. The cleaning nozzles 718 are connected to a not-shown cleaning liquid supply source, and a cleaning liquid (e.g. pure water) is jetted from the cleaning nozzles 718 toward the lower surface of the substrate W. The air blower 719 is connected, via an air supply passage 720, to a not-shown gas supply source, and a dry gas (e.g. air or N₂ gas) is jetted from the air blower 719 toward the lower surface of the substrate W. The air blower 719 is designed to be rotatable.

According to the cleaning section 717, after jetting a cleaning liquid from the cleaning nozzles 718 toward the lower surface of the substrate W, the rotational speed of the substrate holder 548 is raised to e.g. 300 min⁻¹ for drying. At the same time, air is blown from the air blower 719 to the substrate W also for drying the substrate. It is necessary with a usual spin-drying to rotate the substrate generally at a speed of about 2000 min⁻¹. According to this embodiment, which also employs the air-blowing, such a high rotational speed is not necessary.

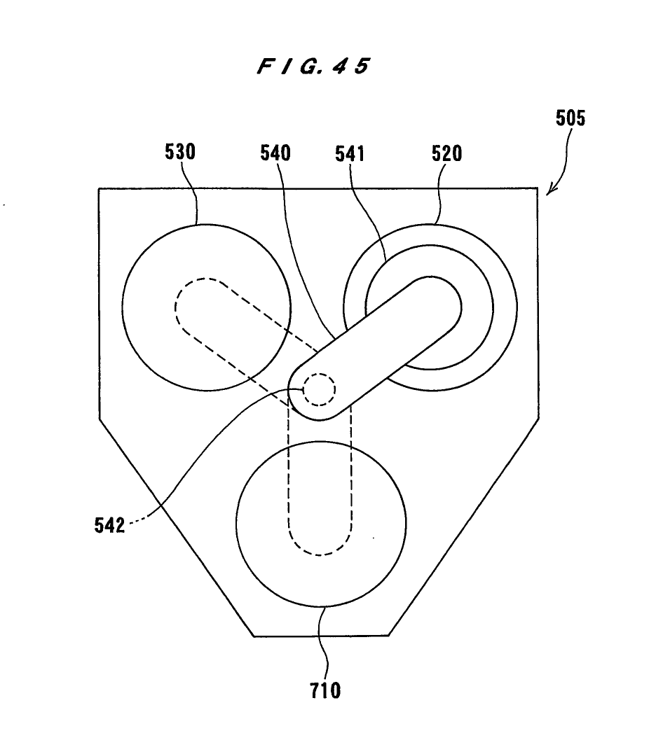

The construction of the substrate processing unit is not limited to the above-described one. For instance, as shown in FIG. 45, it is possible to provide a plurality of substrate processing sections about the support post 542 to which the pivot arm 540 is fixed. According to the embodiment shown in FIG. 45, the plating section 520, the cleaning section 710 and the electrolytic processing section 530 are disposed about the support post 542, so that by the rotation of the support post 542, the head section 541 can move between the plating section 520, the cleaning section 710 and the electrolytic processing section 530. This facilitates the series of substrate processings: plating of a substrate; cleaning of the substrate after plating; electrolytic processing of the substrate after cleaning; and cleaning of the substrate after electrolytic processing. The electrolytic processing is carried out by supplying a liquid, having an electric conductivity of not more than 500 μS/cm, between the plated substrate and an ion exchanger mounted to the electrode, whereby good processing can be effected with an enhanced effect of removing the raised portions of the plated metal film. By repeating the series of process steps, i.e. plating, cleaning, electrolytic processing and cleaning, the raised portions of the plated metal film formed excessively over the fine holes in the substrate surface can be removed by electrolytic processing and embedding of copper can be effected with a good surface flatness to the substrate in which the fine holes and the broad trenches are co-present.

As described hereinabove, according to the present invention, by carrying out electrolytic processing, after the plating of a substrate, by supplying a liquid having an electric conductivity of not more than 500 μS/cm between the plated substrate and the electrode, the raised portions of the substrate formed in the plating can be effectively removed whereby the flatness of the substrate can be improved. Thus, the liquid having an electric conductivity of not more than 500 μS/cm is not fully dissociated electrolytically and, due to a difference in the electric resistance, the ion current concentrates at the raised portions of the substrate which are close to or in contact with an ion exchanger, and the ions act on the metal film (raised portions) on the substrate. Accordingly, the raised portions closed to or in contact with the ion exchanger can be removed effectively, whereby the flatness of the substrate can be improved.

The present invention can provide a processed metal film or embedded interconnects with excellent surface smoothness. Further, the present invention can decrease the thickness of plated film necessary for obtaining the flat processed metal film or embedded interconnects, and is therefore advantageous also from an economical point of view.

### INDUSTRIAL APPLICABILITY

The present invention relates to a substrate processing apparatus and a substrate processing method useful for processing a conductive material formed in the surface of a substrate, especially a semiconductor wafer.

1. A substrate processing apparatus, comprising:
a loading/unloading section for carrying in and carrying out a substrate;
an electrolytic processing unit for electrolytically removing a surface of the substrate having a to-be-processed film formed therein, said electrolytic processing unit including a feeding section that comes into contact with the surface of the substrate;
an etching unit for etching away the to-be-processed film remaining unprocessed at the portion of the substrate that has been in contact with the feeding section in the electrolytic processing unit;
a chemical mechanical polishing unit for chemically and mechanically polishing the surface of the substrate from which the to-be-processed film has been etched away; and
a transfer device for transferring the substrate within the substrate processing apparatus.

2. The substrate processing apparatus according to claim 1, wherein the electrolytic processing unit comprises:
a processing electrode that can come close to or into contact with the substrate;
a feeding electrode as the feeding section for feeding electricity to the substrate;
an ion exchanger disposed between the substrate and at least one of the processing electrode and the feeding electrode;
a power source for applying a voltage between the processing electrode and the feeding electrode; and
a fluid supply section for supplying a fluid between the substrate and at least one of the processing electrode and the feeding electrode in which the ion exchanger is disposed.

3. The substrate processing apparatus according to claim 1, further comprising a film-forming unit for forming the to-be-processed film on the surface of the substrate.

4. The substrate processing apparatus according to claim 3, wherein the film-forming unit is a plating unit for plating the surface of the substrate.

5. The substrate processing apparatus according to claim 3, further comprising an annealing unit for annealing the substrate after the processing in the film-forming unit.

6. The substrate processing apparatus according to claim 1, further comprising a cleaning unit for cleaning the substrate.

7. A substrate processing apparatus, comprising:
a loading/unloading section for carrying in and carrying out a substrate;
an electrolytic processing unit for electrolytically removing a surface of the substrate having a to-be-processed film formed therein, said electrolytic processing unit including a feeding section that comes into contact with the surface of the substrate;
an etching unit for etching away the to-be-processed film remaining unprocessed at the portion of the substrate that has been in contact with the feeding section in the electrolytic processing unit; and
a transfer device for transferring the substrate within the substrate processing apparatus, wherein the electrolytic processing unit comprises:
(i) a processing electrode that can come close to or into contact with the substrate;
(ii) a feeding electrode as the feeding section for feeding electricity to the substrate;
(iii) an ion exchanger disposed between the substrate and at least one of the processing electrode and the feeding electrode;
(iv) a power source for applying a voltage between the processing electrode and the feeding electrode; and
(v) a fluid supply section for supplying pure water or a liquid having an electric conductivity of not more than 500 μS/cm between the substrate and at least one of the processing electrode and the feeding electrode in which the ion exchanger is disposed.

8. The substrate processing apparatus according to claim 7, further comprising a chemical mechanical polishing unit for chemically and mechanically polishing the surface of the substrate from which the to-be-processed film has been etched away.

9. The substrate processing apparatus according to claim 7, further comprising a film-forming unit for forming the to-be-processed film on the surface of the substrate.

10. The substrate processing apparatus according to claim 9, wherein the film-forming unit is a plating unit for plating the surface of the substrate.

11. The substrate processing apparatus according to claim 9, further comprising an annealing unit for annealing the substrate after the processing in the film-forming unit.

12. The substrate processing apparatus according to claim 7, further comprising a cleaning unit for cleaning the substrate.

13. A substrate processing method, comprising:
electrolytically processing a surface of a substrate having a to-be-processed film formed therein while allowing a feeding member to be in contact with the surface of the substrate;
etching away the to-be-processed film remaining unprocessed at the portion of the substrate that has been in contact with the feeding member; and
chemically and mechanically polishing the surface of the substrate after the etching.

14. The substrate processing method according to claim 13, wherein the electrolytic processing comprises:
allowing a processing electrode to be close to or in contact with the substrate while feeding electricity to the substrate by a feeding electrode as the feeding member;
disposing an ion exchanger between the substrate and at least one of the processing electrode and the feeding electrode;
supplying a fluid between the substrate and at least one of the processing electrode and the feeding electrode in which the ion exchanger is disposed; and
applying a voltage between the processing electrode and the feeding electrode.

15. The substrate processing method according to claim 13, further comprising forming the to-be-processed film on the surface of the substrate prior to the electrolytic processing.

16. A substrate processing method, comprising:
electrolytically processing a surface of a substrate having a to-be-processed film formed therein; and
etching away the to-be-processed film remaining unprocessed at the portion of the substrate that has been in contact with the feeding member, wherein the electrolytic processing comprises:
allowing a processing electrode to be close to or in contact with the substrate while feeding electricity to the substrate by a feeding electrode as a feeding member;
disposing an ion exchanger between the substrate and at least one of the processing electrode and the feeding electrode;
supplying pure water or a liquid having an electric conductivity of not more than 500 μS/cm between the substrate and at least one of the processing electrode and the feeding electrode in which the ion exchanger is disposed; and
applying a voltage between the processing electrode and the feeding electrode.

17. The substrate processing method according to claim 16, further comprising chemically and mechanically polishing the surface of the substrate after the etching.

18. The substrate processing method according to claim 16, further comprising forming the to-be-processed film on the surface of the substrate prior to the electrolytic processing.

19. A substrate processing method, comprising:
embedding an interconnect material into fine trenches for interconnects formed in a surface of a substrate;
removing an unnecessary interconnect material and flattening the surface of the substrate;
further removing the interconnect material by electrolytic processing to thereby form recesses for filling in an upper portion of said fine trenches; and
forming a protective film selectively in the recesses for filling.

20. The substrate processing method according to claim 19, wherein the protective film is a multi-layer laminated film.

21. The substrate processing method according to claim 19, wherein the protective film is formed by electroless plating.

22. (canceled)

23. (canceled)

24. (canceled)

25. The substrate processing method according to claim 19 wherein the electrolytic processing comprises:
allowing a processing electrode to be close to or in contact with the substrate while feeding electricity to the substrate by a feeding electrode;
disposing an ion exchanger between the substrate and at least one of the processing electrode and the feeding electrode;
supplying a fluid between the substrate and at least one of the processing electrode and the feeding electrode in which the ion exchanger is disposed; and
applying a voltage between the processing electrode and the feeding electrode.

26. The substrate processing method according to claim 25, wherein the liquid is pure water or a liquid having an electric conductivity of not more than 500 μS/cm.

27. The substrate processing method according to claim 19 wherein the electrolytic processing comprises:
allowing a processing electrode to be close to or in contact with the substrate while feeding electricity to the substrate by means of a feeding electrode;
supplying pure water or a liquid having an electric conductivity of not more than 500 μS/cm between the substrate and the processing electrode; and
applying a voltage between the processing electrode and the feeding electrode.

28. A semiconductor device comprising a substrate having fine trenches for interconnects formed in the surface, said fine trenches being filled with an interconnect material and with a protective film comprising a multi-layer laminated film formed on the surface of the interconnect material.

29. The semiconductor device according to claim 28, wherein the protective film is a multi layer laminated film said multi-layer laminated film comprises a thermal diffusion preventing layer and an oxidation preventing layer.

30. A substrate processing apparatus, comprising:
a head section for holding a substrate;
a plating section for electroplating the surface of the substrate to form a plated metal film;
a cleaning section for cleaning the substrate after the plating; and
an electrolytic processing section for carrying out electrolytic removal processing of at least said metal film on the substrate by allowing an ion exchanger to be present between the substrate after the cleaning and an electrode, and applying a voltage between the substrate and the electrode in the presence of a liquid;
wherein the head section is capable of moving between the plating section, the cleaning section and the electrolytic section while holding the substrate.

31. The substrate processing apparatus according to claim 30, wherein the cleaning section is disposed between the plating section and the electrolytic processing section.

32. The substrate processing apparatus according to claim 30, wherein the cleaning section includes a cleaning liquid jet nozzle.

33. The substrate processing apparatus according to claim 30, wherein the cleaning section includes a drying mechanism for drying the substrate after the cleaning.

34. The substrate processing apparatus according to claim 30, wherein the electrolytic processing section carries out the electrolytic processing by supplying pure water, ultrapure water or a liquid having an electric conductivity of not more than 500 μS/cm between the substrate after the plating and the electrode.

35. The substrate processing apparatus according to claim 30, wherein the plating in the plating section and the electrolytic removal processing in the electrolytic processing section are carried out repeatedly at least two times.

36. The substrate processing apparatus according to claim 30, wherein the plating section comprises:
an anode;
an ion exchanger disposed between the anode and the substrate; and
a plating solution supply section for supplying a plating solution between the ion exchanger and the substrate.

37. The substrate processing apparatus according to claim 30, wherein the head section includes an openable/closable feeding contact member for holding a peripheral portion of the substrate held on the lower surface of the head section and feeding electricity to the substrate.

38. The substrate processing apparatus according to claim 37, wherein the feeding contact member is comprised of a plurality of members disposed at regular intervals along the circumferential direction of the head section.

39. The substrate processing apparatus according to claim 37, wherein the feeding contact member is provided with a feeding member formed of a metal which is noble to the metal film on the substrate.

40. The substrate processing apparatus according to claim 30, wherein the electrolytic processing section is provided with a sensor for detecting the thickness of the metal film on the substrate.

41. The substrate processing apparatus according to claim 30, wherein the plating section and the electrolytic plating section each have a power source.

42. The substrate processing apparatus according to claim 30, wherein the head section, the plating section, the cleaning section and the electrolytic processing section are installed in one processing unit.

43. The substrate processing apparatus according to claim 42, wherein the processing unit is provided with an inert gas supply section for supplying an inert gas into the processing unit.

44. The substrate processing apparatus according to claim 30, wherein the electrolytic processing section and the plating section are connected to a mutual power source, and the power source is switchably connected to the electrolytic processing section or to the plating section by a power source selector switch.

45. A substrate processing apparatus, comprising:
a head section for holding a substrate;
a plating section for electroplating the surface of the substrate to form a plated metal film;
a cleaning section for cleaning the substrate after the plating; and
an electrolytic processing section, which has a processing electrode, for carrying out electrolytic removal processing of at least said metal film on the substrate by applying a voltage between the substrate after the cleaning and the processing electrode in the presence of a liquid;
wherein the head section is capable of moving between the plating section, the cleaning section and the electrolytic section while holding the substrate.

46. The substrate processing apparatus according to claim 45, wherein the cleaning section is disposed between the plating section and the electrolytic processing section.

47. The substrate processing apparatus according to claim 45, wherein the cleaning section includes a cleaning liquid jet nozzle.

48. The substrate processing apparatus according to claim 45, wherein the cleaning section includes a drying mechanism for drying the substrate after the cleaning.

49. The substrate processing apparatus according to claim 45, wherein the electrolytic processing section carries out the electrolytic processing by supplying pure water, ultrapure water or a liquid having an electric conductivity of not more than 500 μS/cm between the substrate after the plating and the processing electrode.

50. The substrate processing apparatus according to claim 45, wherein the plating in the plating section and the electrolytic removal processing in the electrolytic processing section are carried out repeatedly at least two times.

51. The substrate processing apparatus according to claim 45, wherein the plating section comprises:
an anode;
an ion exchanger disposed between the anode and the substrate; and
a plating solution supply section for supplying a plating solution between the ion exchanger and the substrate.

52. The substrate processing apparatus according to claim 45, wherein the head section includes an openable/closable feeding contact member for holding a peripheral portion of the substrate held on the lower surface of the head section and feeding electricity to the substrate.

53. The substrate processing apparatus according to claim 52, wherein the feeding contact member is comprised of a plurality of members disposed at regular intervals along the circumferential direction of the head section.

54. The substrate processing apparatus according to claim 53, wherein the feeding contact member is provided with a feeding member formed of a metal which is noble to the metal film on the substrate.

55. The substrate processing apparatus according to claim 45, wherein the electrolytic processing section is provided with a sensor for detecting the thickness of the metal film on the substrate.

56. The substrate processing apparatus according to claim 45, wherein the plating section and the electrolytic plating section each have a power source.

57. The substrate processing apparatus according to claim 45, wherein the head section, the plating section, the cleaning section and the electrolytic processing section are installed in one processing unit.

58. The substrate processing apparatus according to claim 57, wherein the processing unit is provided with an inert gas supply section for supplying an inert gas into the processing unit.

59. The substrate processing apparatus according to claim 45, wherein the electrolytic processing section and the plating section are connected to a mutual power source, and the power source is switchably connected to the electrolytic processing section or to the plating section by a power source selector switch.

60. The substrate processing apparatus according to claim 45, wherein the electrolytic processing section carries out the electrolytic processing by supplying an acid solution between the substrate after the plating and the processing electrode.

61. A substrate processing method, comprising;
plating a surface of a substrate;
cleaning the substrate after the plating; and
carrying out electrolytic removal processing by allowing an ion exchanger to be present between the substrate after the cleaning and an electrode, and supplying a liquid having an electric conductivity of not more than 500 μS/cm between the substrate and the electrode;
wherein the plating, the cleaning and the electrolytic processing are carried out repeatedly at least two times.

62. A substrate processing method, comprising:
plating a surface of a substrate;
cleaning the surface of the substrate after the plating; and
electrolytically processing the surface of the substrate after the cleaning by applying a voltage between the substrate and a processing electrode in the presence of a liquid;
wherein the plating, the cleaning and the electrolytic processing are carried out repeatedly at lease two times.

63. The substrate processing method according to claim 62, wherein an ion exchanger is allowed to be present between the substrate and the processing electrode.

64. The substrate processing method according to claim 62, wherein said liquid is pure water, ultrapure water or a liquid having an electric conductivity of not more than 500 μS/cm or an electrolyte solution.

65. The substrate processing method according to claim 62, wherein said liquid is an acid solution.

66. A substrate processing method, comprising:
embedding an interconnect material into fine trenches for interconnects formed in a surface of a substrate;
removing an unnecessary interconnect material and flattening the surface of the substrate;
further removing the interconnect material by chemical mechanical polishing to thereby form recesses for filling in an upper portion of said fine trenches; and
forming a protective film selectively in the recesses for filling.

67. The substrate processing method according to claim 66, wherein the protective film is a multi-layer laminated film.

68. The substrate processing method according to claim 66, wherein the protective film is formed by electroless plating.
